(19) United States
(12) Patent Application Publication
(10) Pub. No.: US 2026/0143914 A1
(43) Pub. Date: May 21, 2026

(54) Display Substrate and Display Apparatus

(71) Applicants: Hefei BOE Joint Technology Co.,Ltd., Hefei, Anhui (CN); BOE Technology Group Co., Ltd., Beijing (CN); Beijing BOE Technology Development Co., Ltd., Beijing (CN)

(72) Inventors: Liu WU, Beijing (CN); Can YUAN, Beijing (CN); Yongchao HUANG, Beijing (CN); Xiuting LIU, Beijing (CN)

(21) Appl. No.: 18/696,989

(22) PCT Filed: Aug. 15, 2023
(86) PCT No.: PCT/CN2023/113078

§ 371 Date: Mar. 28, 2024

(51) Int. Cl. H10K 59/121; H10K 59/124

(52) U.S. Cl. CPC H10K 59/1213; H10K 59/124

(57) ABSTRACT

Disclosed is a display substrate and a display apparatus, wherein the display substrate is provided with a plurality of sub-pixels arranged in an array, at least one sub-pixel includes a pixel drive circuit, the display substrate includes a base substrate and a drive structure layer disposed on the base substrate, the pixel drive circuit is disposed on the drive structure layer; the drive structure layer at least includes a first insulation layer, a semiconductor layer, a second insulation layer, a first conductive layer, a third insulation layer, a second conductive layer, a fourth insulation layer, a third conductive layer, a first planarization layer, a fifth insulation layer, and a fourth conductive layer which are stacked on the base substrate sequentially; a plurality of vias are disposed on the fifth insulation layer, and at least one via on the fifth insulation layer exposes the first planarization layer.

### CROSS-REFERENCE TO RELATED APPLICATION

The present application is a U.S. National Phase Entry of International Application No. PCT/CN2023/113078 having an international filing date of Aug. 15, 2023, contents of the above-identified application should be regarded as being incorporated herein by reference.

### TECHNICAL FIELD

The present disclosure relates to, but is not limited to, the field of display technologies, and more particularly, to a display substrate and a display apparatus.

### BACKGROUND

An Organic Light Emitting Diode (OLED for short) and a Quantum dot Light Emitting Diode (QLED for short) are active light emitting display devices and have advantages such as self-luminescence, a wide viewing angle, a high contrast ratio, low power consumption, an extremely high response speed, lightness and thinness, flexibility, and a low cost. With constant development of display technologies, a flexible display apparatus (Flexible Display) in which an OLED or a QLED is used as a light emitting device and signal control is performed through a Thin Film Transistor (TFT) has become a mainstream product in the field of display at present.

### SUMMARY

The following is a summary of subject matters described in the present disclosure in detail. The summary is not intended to limit the scope of protection of claims.

In a first aspect, the present disclosure provides a display substrate provided with a plurality of sub-pixels arranged in an array, at least one sub-pixel includes a pixel drive circuit, wherein the display substrate includes a base substrate and a drive structure layer disposed on the base substrate, and the pixel drive circuit is disposed on the drive structure layer; the drive structure layer at least includes a first insulation layer, a semiconductor layer, a second insulation layer, a first conductive layer, a third insulation layer, a second conductive layer, a fourth insulation layer, a third conductive layer, a first planarization layer, a fifth insulation layer, and a fourth conductive layer which are stacked on the base substrate sequentially; the fifth insulation layer is provided with a plurality of vias, and at least one via on the fifth insulation layer exposes the first planarization layer; and a thickness of the first planarization layer is greater than a thickness of the fifth insulation layer.

In an exemplary implementation mode, the pixel drive circuit includes a first transistor to a fifth transistor, and the drive structure layer further includes a first scan signal line, a second scan signal line, a third scan signal line, an initial signal line, a data signal line, a light emitting signal line, a reference signal line, and a first power supply line, wherein the first transistor is electrically connected with the third scan signal line and the initial signal line respectively, the second transistor is electrically connected with the second scan signal line and the reference signal line respectively, the fourth transistor is electrically connected with the first scan signal line and the data signal line respectively, and the fifth transistor is electrically connected with the light emitting signal line and the first power supply line respectively; any one of the first scan signal line, the second scan signal line, the third scan signal line, the initial signal line, the light emitting signal line, the reference signal line, and the first power supply line at least partially extends along a first direction, and the data signal line at least partially extends along a second direction, wherein the first direction intersects with the second direction; a reference signal line, a second scan signal line, a first scan signal line, a light emitting signal line, a first power supply line, a third scan signal line, and an initial signal line which are connected with any sub-pixel are arranged sequentially along the second direction; the first planarization layer is provided with a first via to a fourth via, wherein an orthographic projection of the first via on the base substrate is within a range of an orthographic projection of a second electrode of the third transistor on the base substrate and a surface of the second electrode of the third transistor is exposed, an orthographic projection of the second via on the base substrate is within a range of an orthographic projection of a first electrode of the fourth transistor on the base substrate and a surface of the first electrode of the fourth transistor is exposed, an orthographic projection of the third via on the base substrate is within a range of an orthographic projection of a reference signal line on the base substrate and a surface of the reference signal line is exposed, and an orthographic projection of the fourth via on the base substrate is within a range of an orthographic projection of a first power supply line on the base substrate and a surface of the first power supply line is exposed; and the third via is located on a centerline of two adjacent fourth vias extending along the second direction.

In an exemplary implementation mode, the fifth insulation layer is provided with a fifth via to an eighth via, wherein an orthographic projection of the fifth via on the base substrate is within a range of orthographic projections of the first via and the first planarization layer on the base substrate, an orthographic projection of the sixth via on the base substrate is within a range of orthographic projections of the second via and the first planarization layer on the base substrate, an orthographic projection of the seventh via on the base substrate is within a range of orthographic projections of the third via and the first planarization layer on the base substrate, and an orthographic projection of the eighth via on the base substrate is within a range of orthographic projections of the fourth via and the first planarization layer on the base substrate.

In an exemplary implementation mode, a length of the fifth via along the first direction is less than a length of the first via along the first direction, and a length of the fifth via along the second direction is less than a length of the first via along the second direction; a length of the sixth via along the first direction is less than a length of the second via along the first direction, and a length of the sixth via along the second direction is less than a length of the second via along the second direction; a length of the seventh via along the first direction is less than a length of the third via along the first direction, and a length of the seventh via along the second direction is less than a length of the third via along the second direction; and a length of the eighth via along the first direction is less than a length of the fourth via along the first direction, and a length of the eighth via along the second direction is less than a length of the fourth via along the second direction.

In an exemplary implementation mode, within any sub-pixel, boundaries of a via include a first boundary, a second boundary, a third boundary, and a fourth boundary, wherein the first boundary of the via is a boundary of the via close to a first signal line, the second boundary of the via is a boundary of the via away from the first signal line, the third boundary of the via is a boundary located on one side of a first centerline, and the fourth boundary of the via is a boundary located on the other side of the first centerline; the via includes a first via and a fifth via; the first signal line is one of a light emitting signal line, a first power supply line, a third scan signal line, and an initial signal line which are connected with the sub-pixel; the first centerline is a centerline of the first via extending along the second direction, a third boundary of the first via and a third boundary of the fifth via are located on a same side of the first centerline, and a fourth boundary of the first via and a fourth boundary of the fifth via are located on a same side of the first centerline; a distance between an orthographic projection of a first boundary of the first via on the base substrate and an orthographic projection of the first signal line on the base substrate is greater than a distance between an orthographic projection of a first boundary of the fifth via on the base substrate and the orthographic projection of the first signal line on the base substrate, a distance between an orthographic projection of a second boundary of the first via on the base substrate and the orthographic projection of the first signal line on the base substrate is greater than a distance between an orthographic projection of a second boundary of the fifth via on the base substrate and the orthographic projection of the first signal line on the base substrate, a distance between the third boundary of the first via and the first centerline is greater than a distance between an orthographic projection of the third boundary of the fifth via on the base substrate and an orthographic projection of the first centerline on the base substrate, and a distance between the fourth boundary of the first via and the first centerline is greater than a distance between an orthographic projection of the fourth boundary of the fifth via on the base substrate and the orthographic projection of the first centerline on the base substrate.

In an exemplary implementation mode, within any sub-pixel, a distance between the orthographic projection of the first boundary of the first via on the base substrate and the orthographic projection of the first boundary of the fifth via on the base substrate is greater than a distance between an orthographic projection of the third boundary of the first via on the base substrate and the orthographic projection of the third boundary of the fifth via on the base substrate, and is less than a distance between the orthographic projection of the second boundary of the first via on the base substrate and the orthographic projection of the second boundary of the fifth via on the base substrate; and the distance between the orthographic projection of the first boundary of the first via on the base substrate and the orthographic projection of the first boundary of the fifth via on the base substrate is about 1 micron to 2 microns.

In an exemplary implementation mode, within any sub-pixel, boundaries of a via include a first boundary, a second boundary, a third boundary, and a fourth boundary, wherein the first boundary of the via is a boundary of the via close to a first signal line, the second boundary of the via is a boundary of the via away from the first signal line, the third boundary of the via is a boundary located on one side of a second centerline, and the fourth boundary of the via is a boundary located on the other side of the second centerline; the via includes a second via and a sixth via; the first signal line is one of a light emitting signal line, a first power supply line, a third scan signal line, and an initial signal line which are connected with the sub-pixel; the second centerline is a centerline of the second via extending along the second direction, a third boundary of the second via and a third boundary of the sixth via are located on a same side of the second centerline, and a fourth boundary of the second via and a fourth boundary of the sixth via are located on a same side of the second centerline; a distance between an orthographic projection of a first boundary of the second via on the base substrate and an orthographic projection of the first signal line on the base substrate is greater than a distance between an orthographic projection of a first boundary of the sixth via on the base substrate and the orthographic projection of the first signal line on the base substrate, a distance between an orthographic projection of a second boundary of the second via on the base substrate and the orthographic projection of the first signal line on the base substrate is greater than a distance between an orthographic projection of a second boundary of the sixth via on the base substrate and the orthographic projection of the first signal line on the base substrate, a distance between the third boundary of the second via and the second centerline is greater than a distance between an orthographic projection of the third boundary of the sixth via on the base substrate and an orthographic projection of the second centerline on the base substrate, and a distance between the fourth boundary of the second via and the second centerline is greater than a distance between an orthographic projection of the fourth boundary of the sixth via on the base substrate and the orthographic projection of the second centerline on the base substrate.

In an exemplary implementation mode, within any sub-pixel, a distance between the in orthographic projection of the first boundary of the second via on the base substrate and the orthographic projection of the first boundary of the sixth via on the base substrate is greater than a distance between an orthographic projection of the third boundary of the second via on the base substrate and the orthographic projection of the third boundary of the sixth via on the base substrate, and is less than a distance between the orthographic projection of the second boundary of the second via on the base substrate and the orthographic projection of the second boundary of the sixth via on the base substrate; and the distance between the orthographic projection of the first boundary of the second via on the base substrate and the orthographic projection of the first boundary of the sixth via on the base substrate is about 1 micron to 2 microns.

In an exemplary implementation mode, boundaries of a via include: a first boundary, a second boundary, a third boundary, and a fourth boundary, wherein the first boundary of the via is a boundary of the via close to a second signal line, the second boundary of the via is a boundary of the via away from the second signal line, the third boundary of the via is a boundary located on one side of a third centerline, and the fourth boundary of the via is a boundary located on the other side of the third centerline; the via includes a third via and a seventh via; the second signal line is one of a light emitting signal line, a first power supply line, a first scan signal line, a second scan signal line, a third scan signal line, an initial signal line, and a light emitting signal line which are connected with a sub-pixel connected with a reference signal line exposed by the third via; the third centerline is a centerline of the third via extending along the second direction, a third boundary of the third via and a third boundary of the seventh via are located on a same side of the third centerline, and a fourth boundary of the third via and a fourth boundary of the seventh via are located on a same side of the third centerline; and a distance between an orthographic projection of a first boundary of the third via on the base substrate and an orthographic projection of the second signal line on the base substrate is greater than a distance between an orthographic projection of a first boundary of the seventh via on the base substrate and the orthographic projection of the second signal line on the base substrate, a distance between an orthographic projection of a second boundary of the third via on the base substrate and the orthographic projection of the second signal line on the base substrate is greater than a distance between an orthographic projection of a second boundary of the seventh via on the base substrate and the orthographic projection of the second signal line on the base substrate, a distance between the third boundary of the third via and the third centerline is greater than a distance between an orthographic projection of the third boundary of the seventh via on the base substrate and an orthographic projection of the third centerline on the base substrate, and a distance between the fourth boundary of the third via and the third centerline is greater than a distance between an orthographic projection of the fourth boundary of the seventh via on the base substrate and the orthographic projection of the third centerline on the base substrate.

In an exemplary implementation mode, a distance between the orthographic projection of the first boundary of the third via on the base substrate and the orthographic projection of the first boundary of the seventh via on the base substrate is greater than a distance between an orthographic projection of the third boundary of the third via on the base substrate and the orthographic projection of the third boundary of the seventh via on the base substrate, and is less than a distance between the orthographic projection of the second boundary of the third via on the base substrate and the orthographic projection of the second boundary of the seventh via on the base substrate; and the distance between the orthographic projection of the first boundary of the third via on the base substrate and the orthographic projection of the first boundary of the seventh via on the base substrate is about 1 micron to 2 microns.

In an exemplary implementation mode, boundaries of a via include: a first boundary, a second boundary, a third boundary, and a fourth boundary, wherein the first boundary of the via is a boundary of the via close to a third signal line, the second boundary of the via is a boundary of the via away from the third signal line, the third boundary of the via is a boundary located on one side of a fourth centerline, and the fourth boundary of the via is a boundary located on the other side of the fourth centerline; the via includes a fourth via and an eighth via; the third signal line is any one of a third scan signal line and an initial signal line which are connected with a sub-pixel connected with a first power supply line exposed by the fourth via; the fourth centerline is a centerline of the fourth via extending along the second direction, a third boundary of the fourth via and a third boundary of the eighth via are located on a same side of the fourth centerline, and a fourth boundary of the fourth via and a fourth boundary of the eighth via are located on a same side of the fourth centerline; and a distance between an orthographic projection of a first boundary of the fourth via on the base substrate and an orthographic projection of the third signal line on the base substrate is greater than a distance between an orthographic projection of a first boundary of the eighth via on the base substrate and the orthographic projection of the third signal line on the base substrate, a distance between an orthographic projection of a second boundary of the fourth via on the base substrate and the orthographic projection of the third signal line on the base substrate is greater than a distance between an orthographic projection of a second boundary of the eighth via on the base substrate and the orthographic projection of the third signal line on the base substrate, a distance between the third boundary of the fourth via and the fourth centerline is greater than a distance between an orthographic projection of the third boundary of the eighth via on the base substrate and an orthographic projection of the fourth centerline on the base substrate, and a distance between the fourth boundary of the fourth via and the fourth centerline is greater than a distance between an orthographic projection of the fourth boundary of the eighth via on the base substrate and the orthographic projection of the fourth centerline on the base substrate.

In an exemplary implementation mode, a distance between the orthographic projection of the first boundary of the fourth via on the base substrate and the orthographic projection of the first boundary of the eighth via on the base substrate is greater than a distance between an orthographic projection of the third boundary of the fourth via on the base substrate and the orthographic projection of the third boundary of the eighth via on the base substrate, and is less than a distance between the orthographic projection of the second boundary of the fourth via on the base substrate and the orthographic projection of the second boundary of the eighth via on the base substrate; and the distance between the orthographic projection of the first boundary of the fourth via on the base substrate and the orthographic projection of the first boundary of the eighth via on the base substrate is about 1 micron to 2 microns.

In an exemplary implementation mode, the fifth insulation layer is provided with a fifth via to an eighth via, wherein an orthographic projection of the fifth via on the base substrate is within a range of the orthographic projection of the first via on the base substrate, an orthographic projection of the sixth via on the base substrate is within a range of the orthographic projection of the second via on the base substrate, an orthographic projection of the seventh via on the base substrate is within a range of the orthographic projection of the third via on the base substrate, and an orthographic projection of the eighth via on the base substrate is within a range of the orthographic projection of the fourth via on the base substrate.

In an exemplary implementation mode, the fifth insulation layer is further provided with any one of a first vent hole and a second vent hole; orthographic projections of the first vent hole and the second vent hole on the base substrate are partially overlapped with an orthographic projection of the first planarization layer on the base substrate and the first planarization layer is exposed; and there is no overlapping region between the orthographic projections of the first vent hole and the second vent hole on the base substrate and orthographic projections of an active pattern, a gate electrode, a first electrode, and a second electrode of any transistor, and a reference signal line, a first scan signal line, a second scan signal line, a third scan signal line, an initial signal line, a first power supply line, and a light emitting signal line on the base substrate.

In an exemplary implementation mode, a length of the first vent hole along the first direction is greater than a length of a boundary of the second electrode of the third transistor close to the first scan signal line, and a length of the first vent hole along the second direction is greater than a length of the fifth via along the second direction; an orthographic projection of the first vent hole on the base substrate is at least disposed surrounding at least one side of the orthographic projection of the first via on the base substrate; and a distance between the orthographic projection of the first vent hole on the base substrate and the orthographic projection of the fifth via on the base substrate is smaller than a distance between an orthographic projection of the first scan signal line on the base substrate and the orthographic projection of the fifth via on the base substrate.

In an exemplary implementation mode, a length of the second vent hole along the second direction is greater than a length of the sixth via along the second direction, and a length of the second vent hole along the first direction is less than a length of the sixth via along the first direction; and the second vent hole and the sixth via are arranged along the second direction, and a distance between the orthographic projection of the sixth via on the base substrate and an orthographic projection of the first scan signal line on the base substrate is larger than a distance between the second vent hole and the sixth via.

In an exemplary implementation mode, the fifth insulation layer is further provided with a third vent hole; an orthographic projection of the third vent hole on the base substrate is partially overlapped with an orthographic projection of the first planarization layer on the base substrate and the first planarization layer is exposed; and the orthographic projection of the third vent hole on the base substrate is located between an orthographic projection of the first scan signal line on the base substrate and an orthographic projection of the light emitting signal line on the base substrate, and there is no overlapping region between the orthographic projection of the third vent hole on the base substrate and orthographic projections of an active pattern, a gate electrode, a first electrode, and a second electrode of any transistor, and a reference signal line, a first scan signal line, a second scan signal line, a third scan signal line, an initial signal line, a first power supply line, and a light emitting signal line on the base substrate.

In an exemplary implementation mode, the fifth insulation layer is further provided with at least one of a fourth vent hole and a fifth vent hole; orthographic projections of the fourth vent hole and the fifth vent hole on the base substrate are partially overlapped with an orthographic projection of the first planarization layer on the base substrate and the first planarization layer is exposed; an orthographic projection of the fourth vent hole on the base substrate is at least partially overlapped with the orthographic projection of the reference signal line on the base substrate, and there is no overlapping region between the orthographic projection of the fourth vent hole on the base substrate and orthographic projections of an active pattern, a gate electrode, a first electrode, and a second electrode of any transistor, and a first scan signal line, a second scan signal line, a third scan signal line, an initial signal line, a first power supply line, and a light emitting signal line on the base substrate; and there is no overlapping region between an orthographic projection of one portion of the fifth vent hole on the base substrate and orthographic projections of an active pattern, a gate electrode, a first electrode, and a second electrode of any transistor, and a reference signal line, a first scan signal line, a second scan signal line, a third scan signal line, an initial signal line, a first power supply line, and a light emitting signal line on the base substrate, and an orthographic projection of the other portion of the fifth vent hole on the base substrate is at least partially overlapped with the orthographic projection of the first power supply line on the base substrate and there is no overlapping region between the orthographic projection of the other portion of the fifth vent hole on the base substrate and orthographic projections of an active pattern, a gate electrode, a first electrode, and a second electrode of any transistor, and a reference signal line, a first scan signal line, a second scan signal line, a third scan signal line, an initial signal line, and a light emitting signal line on the base substrate.

In an exemplary implementation mode, a length of the fourth vent hole along the second direction is greater than a length of the third via along the second direction, and a length of the fourth vent hole along the first direction is less than a length of the third via along the first direction; and the fourth vent hole and the seventh via are arranged along the first direction, and a distance between the orthographic projection of the fourth vent hole on the base substrate and an orthographic projection of a gate electrode of a first transistor of an adjacent sub-pixel on the base substrate is smaller than a distance between the orthographic projection of the seventh via on the base substrate and an orthographic projection of a gate electrode of a first transistor of an adjacent sub-pixel on the base substrate.

In an exemplary implementation mode, a length of the fifth vent hole along the second direction is greater than a length of the fourth via along the second direction, and a length of the fifth vent hole along the first direction is less than a length of the fourth via along the first direction; and the fifth vent hole and the eighth via are arranged along the first direction, and a distance between an orthographic projection of the fifth vent hole on the base substrate and the orthographic projection of the fourth via on the base substrate is smaller than a distance between the orthographic projection of the fourth via on the base substrate and an orthographic projection of a gate electrode of a first transistor on the base substrate.

In an exemplary implementation mode, the pixel drive circuit further includes a capacitor, and the capacitor includes a first electrode plate, a second electrode plate, and a third electrode plate, and the first electrode plate is electrically connected with the third electrode plate; the semiconductor layer at least includes: an active pattern of at least one transistor; the first conductive layer at least includes a gate electrode of at least one transistor and the first electrode plate of the capacitor; the second conductive layer at least includes the second electrode plate of the capacitor; the third conductive layer at least includes a first electrode and a second electrode of at least one transistor, a first scan signal line, a second scan signal line, a third scan signal line, a light emitting signal line, an initial signal line, a reference signal line, a first power supply line, and the third electrode plate of the capacitor; and the fourth conductive layer at least includes a data signal line.

In an exemplary implementation mode, the first electrode plate of the capacitor includes a first gate connection portion and a second gate connection portion, a second gate connection portion of a present column of sub-pixels is located on a side of a first gate connection portion close to a next column of sub-pixels, and a distance between a boundary of the first gate connection portion close to a gate electrode of the fifth transistor and the gate electrode of the fifth transistor is less than a distance between a boundary of the second gate connection portion close to the gate electrode of the fifth transistor and the gate electrode of the fifth transistor; a distance between a boundary of the first gate connection portion away from the gate electrode of the fifth transistor and the gate electrode of the fifth transistor is less than a distance between a boundary of the second gate connection portion away from the gate electrode of the fifth transistor and the gate electrode of the fifth transistor; and a length of the first gate connection portion along the first direction is larger than a length of the second gate connection portion along the first direction, and a length of the first gate connection portion along the second direction is larger than a length of the second gate connection portion along the second direction.

In an exemplary implementation mode, an orthographic projection of the second electrode plate of the capacitor on the base substrate is at least partially overlapped with an orthographic projection of the first electrode plate of the capacitor on the base substrate; shapes and areas of second electrode plates of capacitors located in a same column of sub-pixels are the same, and an area of a second electrode plate of a capacitor of a (3k+1)-th column of sub-pixels is smaller than any one of an area of a second electrode plate of a capacitor of a (3k+2)-th column of sub-pixels and an area of a second electrode plate of a capacitor of a (3k+3)-th column of sub-pixels; an area of an overlapping region between the second electrode plate of the capacitor and a first electrode plate of the capacitor of the (3k+1)-th column of sub-pixels is smaller than an area of an overlapping region between the second electrode plate of the capacitor and a first electrode plate of the capacitor of the (3k+2)-th column sub-pixels, and the area of the overlapping region between the second electrode plate of the capacitor and the first electrode plate of the capacitor of the (3k+2)-th column of sub-pixels is smaller than an area of an overlapping region between the second electrode plate of the capacitor and a first electrode plate of the capacitor of the (3k+3)-th column of sub-pixels; an area of an overlapping region between the second electrode plate of the capacitor and a first gate connection portion of the (3k+1)-th column of sub-pixels is smaller than an area of an overlapping region between the second electrode plate of the capacitor and a first gate connection portion of the (3k+2)-th column of sub-pixels, and the area of the overlapping region between the second electrode plate of the capacitor and the first gate connection portion of the (3k+2)-th column of sub-pixels is smaller than an area of an overlapping region between the second electrode plate of the capacitor and a first gate connection portion of the (3k+3)-th column of sub-pixels; and an area of an overlapping region between the second electrode plate of the capacitor and a second gate connection portion of the (3k+1)-th column of sub-pixels is smaller than an area of an overlapping region between the second electrode plate of the capacitor and a second gate connection portion of the (3k+2)-th column of sub-pixels, and an area of an overlapping region between the second electrode plate of the capacitor and a second gate connection portion of the (3k+3)-th column of sub-pixels is smaller than the area of the overlapping region between the second electrode plate of the capacitor and the second gate connection portion of the (3k+2)-th column of sub-pixels.

In an exemplary implementation mode, an orthographic projection of the third electrode plate of the capacitor on the base substrate is at least partially overlapped with orthographic projections of the first electrode plate of the capacitor and the second electrode plate of the capacitor on the base substrate, respectively, there is a non-overlapping region between the orthographic projection of the third electrode plate of the capacitor on the base substrate and an orthographic projection of the first electrode plate of the capacitor on the base substrate, and there is a non-overlapping region between the orthographic projection of the third electrode plate of the capacitor on the base substrate and an orthographic projection of the second electrode plate of the capacitor on the base substrate.

In an exemplary implementation mode, further including: an initial connection line located in the first conductive layer, wherein the initial connection line at least partially extends along the second direction, and the initial connection line is electrically connected with the initial signal line; two initial connection lines are disposed between at least two columns of sub-pixels, and two initial connection lines located between at least two adjacent sub-pixels are symmetrically disposed with respect to a centerline of two adjacent sub-pixels extending along the second direction; and the orthographic projection of the sixth via on the base substrate is not overlapped with an orthographic projection of the initial connection line on the base substrate.

In an exemplary implementation mode, further including: at least one of a power supply connection line and a reference connection line located in the fourth conductive layer, and any one of the power supply connection line and the reference connection line at least partially extends along the second direction; the power supply connection line is electrically connected with the first power supply line, and the reference connection line is electrically connected with the reference signal line; and an orthographic projection of at least a portion of the reference connection line on the base substrate is located between orthographic projections of two initial connection lines between two adjacent sub-pixels on the base substrate, and an orthographic projection of the power supply connection line on the base substrate and the orthographic projection of the initial connection line on the base substrate are away from a side of an orthographic projection of the reference connection line on the base substrate.

In an exemplary implementation mode, when the fifth insulation layer is provided with at least one of a first vent hole to a fifth vent hole, there is no overlapping region between orthographic projections of the first vent hole to the fifth vent hole on the base substrate and orthographic projections of the power supply connection line, the reference connection line, and the data signal line on the base substrate; and an orthographic projection of the fourth vent hole on the base substrate is partially overlapped with the orthographic projection of the initial connection line on the base substrate.

In an exemplary implementation mode, further including: a light emitting structure layer, and the sub-pixel further includes a light emitting device, the light emitting device includes a first electrode, an organic emitting layer, and a second electrode, wherein the light emitting structure layer includes a light emitting device, and the light emitting structure layer includes a fifth conductive layer, a first pixel definition layer, a second pixel definition layer, a light emitting material layer, and a sixth conductive layer which are sequentially stacked on a side of the drive structure layer away from the base substrate; the fifth conductive layer at least includes the first electrode; the light emitting material layer at least includes the organic emitting layer; the sixth conductive layer at least includes the second electrode; and a light transmittance of the first pixel definition layer is smaller than a light transmittance of the second pixel definition layer.

In an exemplary implementation mode, a thickness of the fifth insulation layer is about 1,200 angstroms to 1,600 angstroms; and a thickness of the first planarization layer is about 18,000 angstroms to 22,000 angstroms, and a manufacturing material of the first planarization layer includes polyimide.

In a second aspect, the present disclosure also provides a display apparatus, including the display substrate described above.

Other aspects may be comprehended after drawings and detailed description are read and understood.

### BRIEF DESCRIPTION OF DRAWINGS

Accompany drawings are used for providing understanding of technical solutions of the present disclosure, and constitute a part of the specification. The accompany drawings, together with embodiments of the present disclosure, are used for explaining the technical solutions of the present disclosure, and do not constitute limitations on the technical solutions of the present disclosure.

FIG. 1 is a schematic diagram of a structure of a display apparatus.

FIG. 2 is a first schematic diagram of a planar structure of a display substrate.

FIG. 3 is a second schematic diagram of a planar structure of a display substrate.

FIG. 4 is a third schematic diagram of a planar structure of a display substrate.

FIG. 5A is an equivalent circuit diagram of a pixel drive circuit.

FIG. 5B is a working timing diagram of the pixel drive circuit provided in FIG. 5A.

FIG. 6 is a schematic diagram of a display substrate.

FIG. 7A is a first schematic diagram of a structure of a display substrate according to an embodiment of the present disclosure.

FIG. 7B is a second schematic diagram of a structure of a display substrate according to an embodiment of the present disclosure.

FIG. 8A is a schematic diagram of a partial film layer of the display substrate provided in FIG. 7A.

FIG. 8B is a schematic diagram of a partial film layer of the display substrate provided in FIG. 7B.

FIG. 9A is an enlarged schematic diagram of a region A in the display substrate provided in FIG. 8A.

FIG. 9B is an enlarged schematic diagram of a region B in the display substrate provided in FIG. 8A.

FIG. 9C is an enlarged schematic diagram of a region C in the display substrate provided in FIG. 8A.

FIG. 9D is an enlarged schematic diagram of a region D in the display substrate provided in FIG. 8A.

FIG. 10 is a schematic diagram of a capacitor of the display substrate provided in FIGS. 7A and 7B.

FIG. 11 is a schematic diagram of a partial film layer of the capacitor of the display substrate provided in FIG. 7A and FIG. 7B.

FIG. 12 is a schematic diagram of a pattern of a semiconductor layer in FIGS. 7A and 7B.

FIG. 13 is a schematic diagram of a pattern of a first conductive layer in FIGS. 7A and 7B.

FIG. 14 is a schematic diagram after the pattern of the first conductive layer is formed in FIGS. 7A and 7B.

FIG. 15 is a schematic diagram of a pattern of a second conductive layer in FIGS. 7A and 7B.

FIG. 16 is a schematic diagram after the pattern of the second conductive layer is formed in FIGS. 7A and 7B.

FIG. 17 is a schematic diagram after a pattern of a fourth insulation layer is formed in FIGS. 7A and 7B.

FIG. 18 is a schematic diagram of a pattern of a third conductive layer in FIGS. 7A and 7B.

FIG. 19 is a schematic diagram after the pattern of the third conductive layer is formed in FIGS. 7A and 7B.

FIG. 20 is a schematic diagram after a pattern of a first planarization layer is formed in FIGS. 7A and 7B.

FIG. 21 is a schematic diagram after a pattern of a fifth insulation layer is formed in FIG. 7A.

FIG. 22 is a schematic diagram after a pattern of a fifth insulation layer is formed in FIG. 7B.

FIG. 23 is a schematic diagram of a pattern of a fourth conductive layer in FIGS. 7A and 7B.

FIG. 24 is a schematic diagram after the pattern of the fourth conductive layer is formed in FIG. 7A.

FIG. 25 is a schematic diagram after the pattern of the fourth conductive layer is formed in FIG. 7B.

FIG. 26 is a schematic diagram after a pattern of a sixth insulation layer is formed in FIG. 7A.

FIG. 27 is a schematic diagram after a pattern of a sixth insulation layer is formed in FIG. 7B.

FIG. 28 is a schematic diagram after a pattern of a second planarization layer is formed in FIG. 7A.

FIG. 29 is a schematic diagram after a pattern of a second planarization layer is formed in FIG. 7B.

FIG. 30 is a schematic diagram of a pattern of a fifth conductive layer in FIGS. 7A and 7B.

FIG. 31 is a schematic diagram after the pattern of the fifth conductive layer is formed in FIG. 7A.

FIG. 32 is a schematic diagram after the pattern of the fifth conductive layer is formed in FIG. 7B.

FIG. 33 is a schematic diagram after a pattern of a first pixel definition layer is formed in FIG. 7A.

FIG. 34 is a schematic diagram after a pattern of a first pixel definition layer is formed in FIG. 7B.

FIG. 35 is a schematic diagram after a pattern of a second pixel definition layer is formed in FIG. 7A.

FIG. 36 is a schematic diagram after a pattern of a second pixel definition layer is formed in FIG. 7B.

### DETAILED DESCRIPTION

To make objectives, the technical solutions, and advantages of the present disclosure clearer, the embodiments of the present disclosure will be described in detail below in combination with the accompany drawings. It is to be noted that the implementation modes may be implemented in multiple different forms. Those of ordinary skills in the art may easily understand such a fact that modes and contents may be transformed into various forms without departing from the purpose and scope of the present disclosure. Therefore, the present disclosure should not be explained as being limited to contents recorded in following implementation modes only. The embodiments and features in the embodiments of the present disclosure may be randomly combined with each other if there is no conflict. In order to keep following description of the embodiments of the present disclosure clear and concise, detailed description of part of known functions and known components are omitted in the present disclosure. The drawings in the embodiments of the present disclosure relate only to structures involved in the embodiments of the present disclosure, and other structures may be referred to conventional designs.

Scales of the drawings in the present disclosure may be used as a reference in actual processes, but are not limited thereto. For example, a width-length ratio of a channel, a thickness and spacing of each film layer, and a width and spacing of each signal line may be adjusted according to actual needs. A quantity of pixels in a display substrate and a quantity of sub-pixels in each pixel are not limited to numbers shown in the drawings. The drawings described in the present disclosure are schematic structural diagrams only, and one mode of the present disclosure is not limited to shapes, numerical values, or the like shown in the drawings.

Ordinal numerals “first”, “second”, “third”, etc., in the specification are set not to form limits in numbers but only to avoid confusion between constituent elements.

In the specification, for convenience, expressions “central”, “above”, “below”, “front”, “back”, “vertical”, “horizontal”, “top”, “bottom”, “inside”, “outside”, etc., indicating directional or positional relationships are used to illustrate positional relationships between the constituent elements with reference to the drawings, not to indicate or imply that a referred apparatus or element must have a specific orientation and be structured and operated with the specific orientation but only to easily and simply describe the present specification, and thus should not be understood as limitations on the present disclosure. The positional relationships between the constituent elements may be changed as appropriate according to a direction according to which each constituent element is described. Therefore, appropriate replacements based on situations are allowed, which is not limited to the expressions in the specification.

In the specification, unless otherwise specified and defined, terms “mounting”, “mutual connection”, and “connection” should be understood in a broad sense. For example, a connection may be a fixed connection, or a detachable connection, or an integral connection; it may be a mechanical connection or an electrical connection; it may be a direct connection, or an indirect connection through an intermediate, or internal communication inside two elements. Those of ordinary skills in the art may understand specific meanings of the above terms in the present disclosure according to specific situations.

In the specification, a transistor refers to an element that at least includes three terminals, i.e., a gate electrode, a drain electrode, and a source electrode. The transistor has a channel region between the drain electrode (drain electrode terminal, drain region, or drain) and the source electrode (source electrode terminal, source region, or source), and a current can flow through the drain electrode, the channel region, and the source electrode. It is to be noted that in the specification, the channel region refers to a region through which a current mainly flows.

In the specification, a first electrode may be a drain electrode, and a second electrode may be a source electrode. Or, the first electrode may be a source electrode, and the second electrode may be a drain electrode. In a case that transistors with opposite polarities are used, or in a case that a direction of a current changes during operation of a circuit, or the like, functions of the “source electrode” and the “drain electrode” are sometimes interchangeable. Therefore, the “source electrode” and the “drain electrode” are interchangeable in the specification.

In the specification, an “electrical connection” includes a case that constituent elements are connected together through an element with a certain electrical action. An “element with a certain electrical action” is not particularly limited as long as electrical signals between the connected constituent elements may be sent and received. Examples of the “element with the certain electrical action” not only include an electrode and a wiring, but also include a switching element such as a transistor, a resistor, an inductor, a capacitor, another element with various functions, etc.

In the specification, “parallel” refers to a state in which an angle formed by two straight lines is −10° or more and 10° or less, and thus also includes a state in which the angle is −5° or more and 5° or less. In addition, “perpendicular” refers to a state in which an angle formed by two straight lines is 80° or more and 100° or less, and thus also includes a state in which the angle is 85° or more and 95° or less.

In the specification, a “film” and a “layer” are interchangeable. For example, a “conductive layer” may be replaced with a “conductive film” sometimes. Similarly, an “insulation film” may be replaced with an “insulation layer” sometimes.

In the specification, “disposed in a same layer” refers to a structure formed by patterning two (or more than two) structures through a same patterning process, and their materials may be the same or different. For example, materials of precursors for forming multiple structures disposed in a same layer are the same, and final materials may be the same or different.

A triangle, rectangle, trapezoid, pentagon, or hexagon, etc. in the specification is not strictly defined, and it may be an approximate triangle, rectangle, trapezoid, pentagon, or hexagon, etc. There may be some small deformation caused by tolerance, and there may be a chamfer, an arc edge, deformation, etc.

In the present disclosure, “about” refers to that a boundary is not defined so strictly and numerical values within a range of process and measurement errors are allowed.

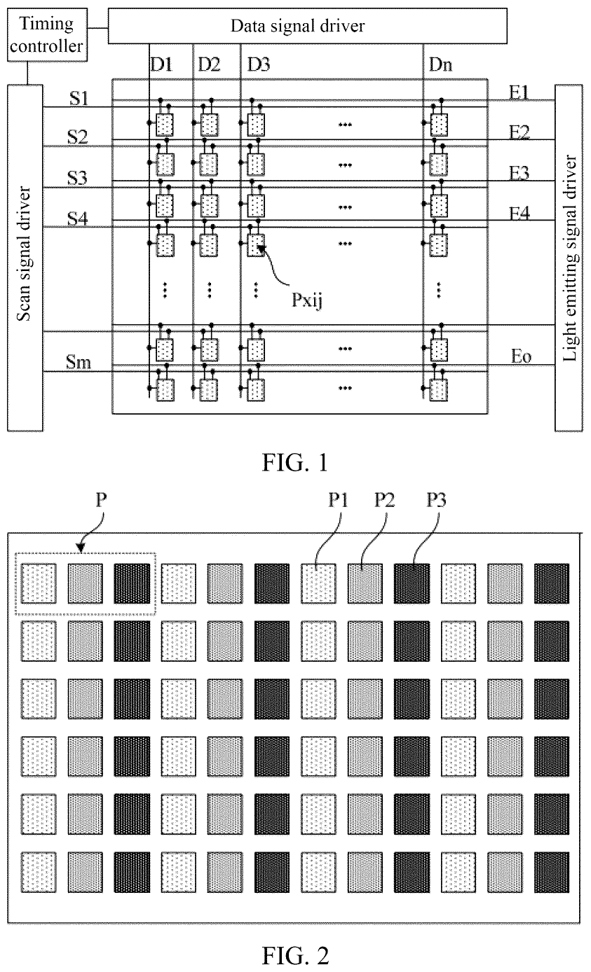

FIG. 1 is a schematic diagram of a structure of a display apparatus. As shown in FIG. 1, the display apparatus may include a timing controller, a data driver, a scan driver, a light emitting driver, and a pixel array. The timing controller is connected with the data driver, the scan driver, and the light emitting driver, respectively, the data driver is connected with a plurality of data signal lines (D1 to Dn) respectively, the scan driver is connected with a plurality of scan signal lines (S1 to Sm) respectively, and the light emitting driver is connected with a plurality of light emitting signal lines (E1 to Eo) respectively. The pixel array may include multiple sub-pixels Pxij, wherein i and j may be natural numbers. At least one sub-pixel Pxij may include a circuit unit and a light emitting device connected with the circuit unit. The circuit unit may include a pixel drive circuit, and the pixel drive circuit may be connected with a scan signal line, a light emitting signal line, and a data signal line respectively.

In an exemplary implementation mode, the timing controller may provide a grayscale value and a control signal suitable for a specification of the data signal driver to the data signal driver, may provide a clock signal, a scan start signal, etc. suitable for a specification of the scan driver to the scan driver, and may provide a clock signal, an emission stop signal, etc. suitable for a specification of the light emitting driver to the light emitting driver.

In an exemplary implementation mode, the data driver may generate a data voltage to be provided to the data signal lines D1, D2, D3, . . . , and Dn by using the gray-scale value and the control signal received from the timing controller. For example, the data driver may sample the grayscale value using the clock signal and apply a data voltage corresponding to the grayscale value to the data signal lines D1 to Dn by taking a pixel row as a unit, wherein n may be a natural number.

In an exemplary implementation mode, the scan driver may receive a clock signal, a scan start signal, etc., from the timing controller to generate a scan signal that is to be provided to the scan signal lines S1, S2, S3, . . . , and Sm. For example, the scan driver may sequentially provide a scan signal with an on-level pulse to the scan signal lines S1 to Sm. For example, the scan driver may be constructed in a form of a shift register and may generate a scan signal in a manner in which a scan start signal provided in a form of an on-level pulse is transmitted to a next-stage circuit sequentially under control of the clock signal, wherein m may be a natural number.

In an exemplary implementation mode, the light emitting driver may receive the clock signal, the emission stop signal, etc., from the timing controller to generate an emission signal that is to be provided to the light emitting signal lines E1, E2, E3, . . . , and Eo. For example, the light emitting driver may sequentially provide an emission signal with an off-level pulse to the light emitting signal lines E1 to Eo. For example, the light emitting driver may be constructed in a form of a shift register and may generate an emission signal in a manner of sequentially transmitting an emission stop signal provided in a form of an off-level pulse to a next-stage circuit under control of the clock signal, wherein o may be a natural number.

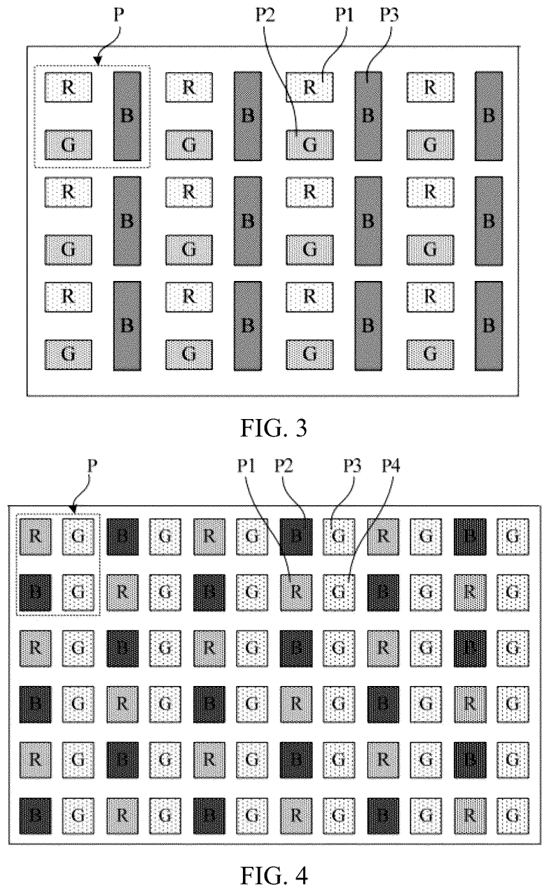

FIG. 2 is a first schematic diagram of a planar structure of a display substrate, FIG. 3 is a second schematic diagram of a planar structure of a display substrate, and FIG. 4 is a third schematic diagram of a planar structure of a display substrate. As shown in FIG. 2 to FIG. 4, the display substrate may include multiple pixel units P arranged in a matrix, at least one of the multiple pixel units P includes a first sub-pixel P1 emitting light of a first color, a second sub-pixel P2 emitting light of a second color, and a third sub-pixel P3 emitting light of a third color, and the first sub-pixel P1, the second sub-pixel P2, and the third sub-pixel P3 each includes a pixel drive circuit and a light emitting device. Pixel drive circuits in the first sub-pixel P1, the second sub-pixel P2, and the third sub-pixel P3 are connected with a scan signal line, a data signal line, and a light emitting signal line respectively. A pixel drive circuit is configured to receive a data voltage transmitted by the data signal line under control of the scan signal line and the light emitting signal line, and output a corresponding current to the light emitting device. Light emitting devices in the first sub-pixel P1, the second sub-pixel P2, and the third sub-pixel P3 are respectively connected with a pixel drive circuit of a sub-pixel in which a light emitting device is located, and the light emitting device is configured to emit light with corresponding brightness in response to a current outputted by the pixel drive circuit of the sub-pixel in which the light emitting device is located.

In an exemplary implementation mode, the first sub-pixel P1 may be a Red (R) sub-pixel emitting red light, the second sub-pixel P2 may be a Blue (B) sub-pixel emitting blue light, and the third sub-pixel P3 may be a Green (G) sub-pixel emitting green light. In an exemplary implementation mode, a sub-pixel may have a shape of a rectangle, a rhombus, a pentagon, or a hexagon.

In an exemplary implementation mode, a pixel unit may include three sub-pixels, and the three sub-pixels may be arranged in a manner to side by side horizontally, in a manner to side by side vertically, or in a manner like a Chinese character “ [symbol] ”, which is not limited here in the present disclosure. FIG. 2 and FIG. 3 are illustrated by taking a case that a pixel unit includes three sub-pixels as an example, wherein three sub-pixels in FIG. 2 are arranged side by side horizontally, and three sub-pixels in FIG. 3 are arranged in a manner like a Chinese character “ [symbol] ”.

In an exemplary implementation mode, a pixel unit may include four sub-pixels, and the four sub-pixels may be arranged in a manner to stand side by side horizontally, in a manner to stand side by side vertically, or in a manner to form a square, which is not limited here in the present disclosure. FIG. 4 is illustrated by taking a case that a pixel unit includes four sub-pixels and the four sub-pixels are arranged in a manner to form a square as an example.

On a plane perpendicular to the display substrate, the display panel may include a drive structure layer disposed on a base substrate, a light emitting structure layer disposed on one side of the drive structure layer away from the base substrate, and an encapsulation structure layer disposed on one side of the light emitting structure layer away from the base substrate. In some possible implementation modes, the display substrate may include another film layer, such as a touch structure layer, which is not limited here in the present disclosure.

In an exemplary implementation mode, the base substrate may be a rigid base substrate or a flexible base substrate, wherein the rigid base substrate may be, but is not limited to, one or more of glass and conductive foil. The flexible base substrate may be, but is not limited to, one or more of polyethylene terephthalate, ethylene terephthalate, polyether ether ketone, polystyrene, polycarbonate, polyarylate, polyarylester, polyimide, polyvinyl chloride, polyethylene, and textile fiber.

In an exemplary implementation mode, the light emitting device may be an Organic Light Emitting Diode (OLED) including a first electrode (anode), an organic emitting layer, and a second electrode (cathode) that are stacked.

In an exemplary implementation mode, the drive structure layer may include a plurality of transistors and a storage capacitor, which constitute a pixel drive circuit. The light emitting structure layer may include an anode, a pixel definition layer, an organic emitting layer, and a cathode, wherein the anode is connected with a drain electrode of a transistor through a via, the organic emitting layer is connected with the anode, the cathode is connected with the organic emitting layer, and the organic emitting layer emits light of a corresponding color under drive of the anode and the cathode.

In an exemplary implementation mode, the organic emitting layer may include an Emitting Layer (EML), and any one or more of following: a Hole Injection Layer (HIL), a Hole Transport Layer (HTL), an Electron Block Layer (EBL), a Hole Block Layer (HBL), an Electron Transport Layer (ETL), and an Electron Injection Layer (EIL). In an exemplary implementation mode, one or more of hole injection layers, hole transport layers, electron block layers, hole block layers, electron transport layers, and electron injection layers of all sub-pixels may be connected together to form a common layer. Emitting layers of adjacent sub-pixels may be overlapped slightly with each other, or may be isolated from each other.

In an exemplary implementation mode, the encapsulation structure layer may include a first encapsulation layer, a second encapsulation layer, and a third encapsulation layer that are stacked. The first encapsulation layer and the third encapsulation layer may be made of an inorganic material, and the second encapsulation layer may be made of an organic material. The second encapsulation layer is disposed between the first encapsulation layer and the third encapsulation layer, and it may be ensured that external water vapor cannot enter the light emitting structure layer.

In an exemplary implementation mode, the touch structure layer may include a first touch insulation layer disposed on the encapsulation structure layer, a first touch metal layer disposed on the first touch insulation layer, a second touch insulation layer covering the first touch metal layer, a second touch metal layer disposed on the second touch insulation layer, and a touch protective layer covering the second touch metal layer, the first touch metal layer may include a plurality of bridge electrodes, the second touch metal layer may include a plurality of first touch electrodes and second touch electrodes, and a first touch electrode or a second touch electrode may be connected with a bridge electrode through a via.

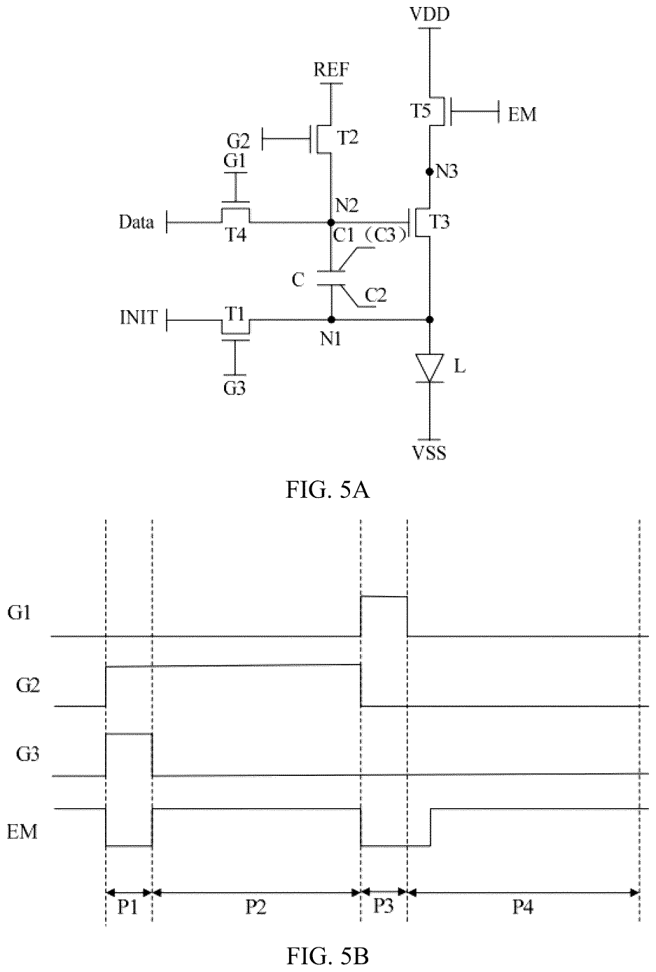

FIG. 5A is an equivalent circuit diagram of a pixel drive circuit. In an exemplary implementation mode, the pixel drive circuit may have a structure of 3T1C, 4T1C, 5T1C, 5T2C, 6T1C, 7T1C, or 8T1C. As shown in FIG. 5A, the pixel drive circuit may include five transistors (a first transistor T1 to a fifth transistor T5) and one capacitor C, the pixel drive circuit may be connected with seventh signal lines (a data signal line Data, a first scan signal line G1, a second scan signal line G2, a third scan signal line G3, a light emitting signal line EM, an initial signal line INIT, a reference signal line REF, a first power supply line VDD), and a light emitting device L is connected with a second power supply line VSS.

In an exemplary implementation mode, as shown in FIG. 5A, a gate electrode of the first transistor T1 is electrically connected with the third scan signal line G3, a first electrode of the first transistor T1 is electrically connected with the initial signal line INIT, and a second electrode of the first transistor T1 is electrically connected with a first node N1; a gate electrode of the second transistor T2 is electrically connected with the second scan signal line G2, a first electrode of the second transistor T2 is electrically connected with the reference signal line REF, and a second electrode of the second transistor T2 is electrically connected with a second node N2; a gate electrode of the third transistor T3 is electrically connected with the second node N2, a first electrode of the third transistor T3 is electrically connected with a third node N3, and a second electrode of the third transistor T3 is electrically connected with the first node N1; a gate electrode of the fourth transistor T4 is electrically connected with the first scan signal line G1, a first electrode of the fourth transistor T4 is electrically connected with the data signal line Data, a second electrode of the fourth transistor T4 is electrically connected with the second N2; a gate electrode of the fifth transistor T5 is electrically connected with light emitting signal line EM, a first electrode of the fifth transistor T5 is electrically connected with the first power supply line VDD, and a second electrode of the fifth transistor T5 is electrically connected with the third node N3; and the capacitor C includes a first electrode plate C1, a second electrode plate C2, and a third electrode plate C3 which are stacked on the base substrate sequentially, wherein the first electrode plate C1 and the third electrode plate C3 are electrically connected with the second node N2, and the second electrode plate C2 is electrically connected with the first node N1.

In an exemplary implementation mode, the first transistor T1 may be referred to as a reset transistor, and when a signal of the third scan signal line G3 is an effective level signal, the first transistor T1 enables a signal of the initial signal line to be transmitted to the first node N1 to reset a charge amount of a first electrode of the light emitting device L.

In an exemplary implementation mode, the third transistor T3 may be referred to as a drive transistor, and the third transistor T3 determines a magnitude of a drive current flowing between the first power supply line VDD and the second power supply line VSS according to a potential difference between its gate electrode and first electrode.

In an exemplary implementation mode, the fourth transistor T4 may be referred to as a switching transistor, a scan transistor, etc., and when a scan signal with an on level is applied to the first scan signal line S1, the fourth transistor T4 enables a data voltage of the data signal line Data to be input into the second node N2.

In an exemplary implementation mode, the fifth transistor T5 may be referred to as a light emitting transistor. When a light emitting signal with an on level is applied to the light emitting signal line EM, the fifth transistor T5 enables the light emitting device L to emit light by forming a drive current path between the first power supply line VDD and the second power supply line VSS.

In an exemplary implementation mode, as shown in FIG. 5A, a quantity of any one of the first transistor T1, the second transistor T2, and the fourth transistor T4 may be at least one. FIG. 5A is illustrated by taking one first transistor T1, one second transistor T2, and one fourth transistor T4 as an example.

In an exemplary implementation mode, when a quantity of first transistors T1 may be at least two, gate electrodes of all the first transistors are all electrically connected with the third scan signal line, at least two first transistors are arranged in series, a first electrode of a first first transistor is electrically connected with the initial signal line, and a second electrode of a last first transistor is electrically connected with the first node N1.

In an exemplary implementation mode, when a quantity of second transistors T2 may be at least two, gate electrodes of all the second transistors are all electrically connected with the second scan signal line, at least two second transistors are arranged in series, a first electrode of a first second transistor is electrically connected with the reference signal line, and a second electrode of a last second transistor is electrically connected with the second node N2.

In an exemplary implementation mode, when a quantity of fourth transistors T4 may be at least two, gate electrodes of all the fourth transistors are all electrically connected with the first scan signal line, at least two fourth transistors are arranged in series, a first electrode of a first fourth transistor is electrically connected with the data signal line, and a second electrode of a last fourth transistor is electrically connected with the second node N2.

In an exemplary implementation mode, as shown in FIG. 5A, the first electrode of the light emitting device L is electrically connected with the first node N1, and a second electrode of the light emitting device L is connected with the second power supply line VSS.

In an exemplary implementation mode, the first power supply line VDD continuously provides a high-level signal, and the second power supply line VSS continuously provides a low-level signal.

In an exemplary implementation mode, a voltage value of the signal of the initial signal line INIT may be smaller than a voltage value of a signal of the second power supply line VSS, which may avoid false light emission of the light emitting device.

In an exemplary implementation mode, a first scan signal line G1 is a scan signal line in a pixel drive circuit of a present display row, a third scan signal line G3 is a scan signal line in a pixel drive circuit of a previous display row, and a third scan signal line G3 of the present display row and a first scan signal line G1 in the pixel drive circuit of the previous display row are a same signal line, so that signal lines of the display substrate may be reduced and a narrow bezel of the display substrate may be achieved.

Transistors may be divided into N-type transistors and P-type transistors according to characteristics of the transistors. When a transistor is a P-type transistor, a turn-on voltage is a low-level voltage (e.g., 0 V, −5 V, −10 V, or another suitable voltage), and a turn-off voltage is a high-level voltage (e.g., 5 V, 10 V, or another suitable voltage). When a transistor is an N-type transistor, a turn-on voltage is a high-level voltage (e.g., 5 V, 10 V, or another suitable voltage), and a turn-off voltage is a low-level voltage (e.g., 0 V, −5 V, −10 V, or another suitable voltage).

In an exemplary implementation mode, the first transistor T1 to the fifth transistor T5 may be P-type transistors, or may be N-type transistors. Use of a same type of transistors in a pixel drive circuit may simplify a process flow, reduce process difficulties of the display substrate, and improve a yield of products.

In an exemplary implementation mode, the first transistor T1 to the fifth transistor T5 are all N-type transistors.

In an exemplary implementation mode, the first power supply line VDD continuously provides a high-level signal, the second power supply line VSS continuously provides a low-level signal, and the reference signal line REF continuously provides a reference signal, wherein a voltage of the reference signal is 0 V.

FIG. 5B is a working timing diagram of the pixel drive circuit provided in FIG. 5A. An exemplary embodiment of the present disclosure will be described below through a working process of the pixel drive circuit exemplified in FIG. 5A. The pixel drive circuit in FIG. 5B includes five transistors (the first transistor T1 to the fifth transistor T5) and one capacitor C, and the five transistors are all N-type transistors.

In an exemplary implementation mode, the working process of the pixel drive circuit may include following stages.

In a first stage P1, referred to as a reset stage, signals of the second scan signal line G2 and the third scan signal line G3 are high-level signals, and signals of the first scan signal line G1 and the light emitting signal line EM are low-level signals. A signal of the second scan signal line G2 is a high-level signal, the second transistor T2 is turned on, a signal of the reference signal line REF is provided to the second node N2 to initialize (reset) a signal of the second node N2, and an original charge in the second node N2 is cleared. A signal of the third scan signal line G3 is a high-level signal, the first transistor T1 is turned on, a signal of the initial signal line INIT is provided to the first node N1 to initialize (reset) an anode of the light emitting device L, and an original charge in the anode of the light emitting device L is cleared. The signals of the first scan signal line G1 and the light emitting signal line EM are low-level signals, and the fourth transistor T4 and the fifth transistor T5 are turned off. In this stage, the light emitting device L does not emit light.

In a second stage P2, i.e., a threshold compensation stage, signals of the second scan signal line G2 and the light emitting signal line EM are high-level signals, signals of the first scan signal line G1 and the third scan signal line G3 are low-level signals, a signal of the second scan signal line G2 is a high-level signal, the second transistor T2 is turned on, a signal of the reference signal line REF is continuously provided to the second node N2, a signal of the light emitting signal line EM is a high-level signal, the fifth transistor T5 is turned on, and a signal of the first power supply line VDD is written into the first node N1 through the turned-on fifth transistor T5, the third node N3, and the turned-on third transistor T3 until a voltage of a signal of the second node N2 is V2=Vref−Vth, wherein Vref is a voltage value of the reference signal line REF, Vth is a threshold voltage of the third transistor T3, and the capacitor C stores a voltage difference Vth of signals of the first node N1 and the second node N2.

In a third stage P3, referred to as a data writing stage, a signal of the first scan signal line G1 is a high-level signal, signals of the second scan signal line G2, the third scan signal line G3, and the light emitting signal line EM are low-level signals, and the data signal line Data outputs a data voltage. The signal of the first scan signal line G1 is the high-level signal, the fourth transistor T4 is turned on, and the data voltage of the data signal line Data is written into the second node N2. At this time, a voltage value of the second node N2 is V2=Vdata, wherein Vdata is the data voltage of the data signal line, and a signal of the second node N2 jumps from a voltage value of a present stage compared with a voltage value of a previous stage. Therefore, a signal of the first node N1 also jumps under an action of the capacitor C, and at this time, a voltage value of the signal of the first node N1 is V1=Vref−Vth+a (Vdata−Vref). The signals of the second scan signal line G2, the third scan signal line G3, and the light emitting signal line EM are low-level signals, and the first transistor T1, the second transistor T2, and the fifth transistor T5 are turned off. In the present stage, the light emitting device L does not emit light.

In a fourth stage P4, i.e., a light emitting stage, a signal of the light emitting signal line EM is a high-level signal, and signals of the first scan signal line G1, the second scan signal line G2, and the third scan signal line G3 are all low-level signals. The signal of the light emitting signal line EM is the high-level signal, the fifth transistor T5 is turned on, and a power supply voltage output by the first power supply line VDD provides a drive voltage to the first electrode of the light emitting element L through the turned-on fifth transistor T5 and the third transistor T3 to drive the light emitting device L to emit light.

In a drive process of the pixel drive circuit, a drive current flowing through the third transistor T3 (the drive transistor) is decided by a voltage difference between a gate electrode (also the second node N2) and a first electrode (also the first node N1) of the third transistor T3. Since the voltage value of the signal of the first node is V1=Vref−Vth+a (Vdata−Vref), and the voltage value of the signal of the second node N1 is V1=Vdata, the drive current of the third transistor T3 is as follows.

$$I = K * {( Vgs - Vth )}^{2} = K * {[ Vdata - Vref + Vth - α ( Vdata - Vref ) ]}^{2} = K * {[ ( 1 - α ) ( Vdata - Vref ) ]}^{2}$$

Herein, I is the drive current flowing through the third transistor T3, that is, a drive current for driving the light emitting device L, K is a constant, and Vgs is the voltage difference between the gate electrode and the first electrode of the third transistor T3.

It may be seen from a derivation result of the above current formula that in the light emitting stage, the drive current of the third transistor T3 is not affected by the threshold voltage of the third transistor T3. Therefore, an influence of the threshold voltage of the third transistor T3 on the drive current is eliminated, which may ensure uniformity of display brightness of a display product, and improve a display effect of the whole display product.

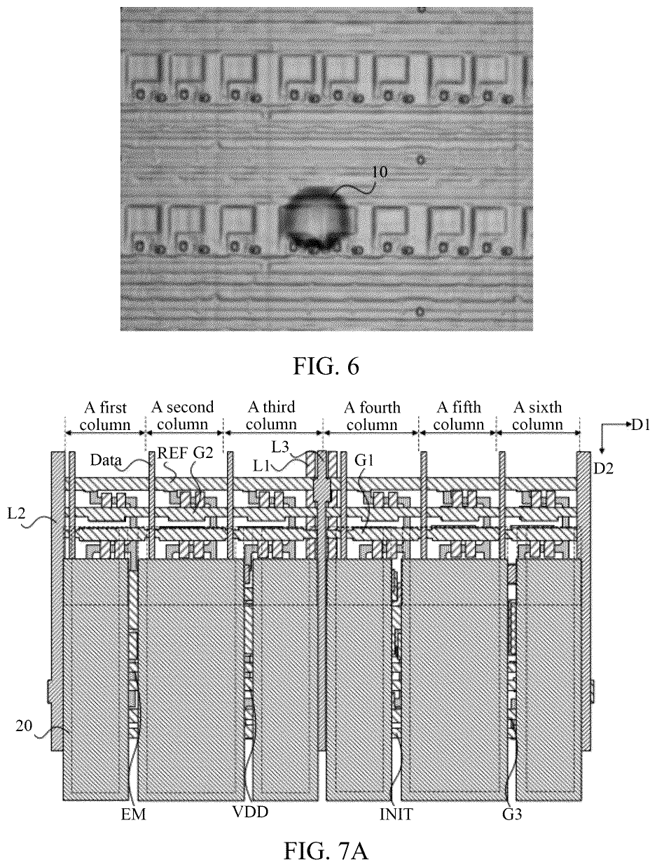

FIG. 6 is a schematic diagram of a display substrate. As shown in FIG. 6, a drive structure layer of the display substrate includes a first conductive layer, a second conductive layer, a third conductive layer, and a fourth conductive layer, wherein a planarization layer and an insulation layer are disposed between the third conductive layer and the fourth conductive layer, and the insulation layer covers the planarization layer. The planarization layer will be made of polyimide material, which may achieve good planarization. When the fourth conductive layer is formed subsequently, since the fourth conductive layer is prepared in a high temperature environment, high temperature will lead to accumulation of residual water vapor within the planarization layer, resulting in bulge 10, which will lead to a bulge defect of the display substrate, which will further lead to low reliability of a display product, and further affect a display effect of the display product adversely.

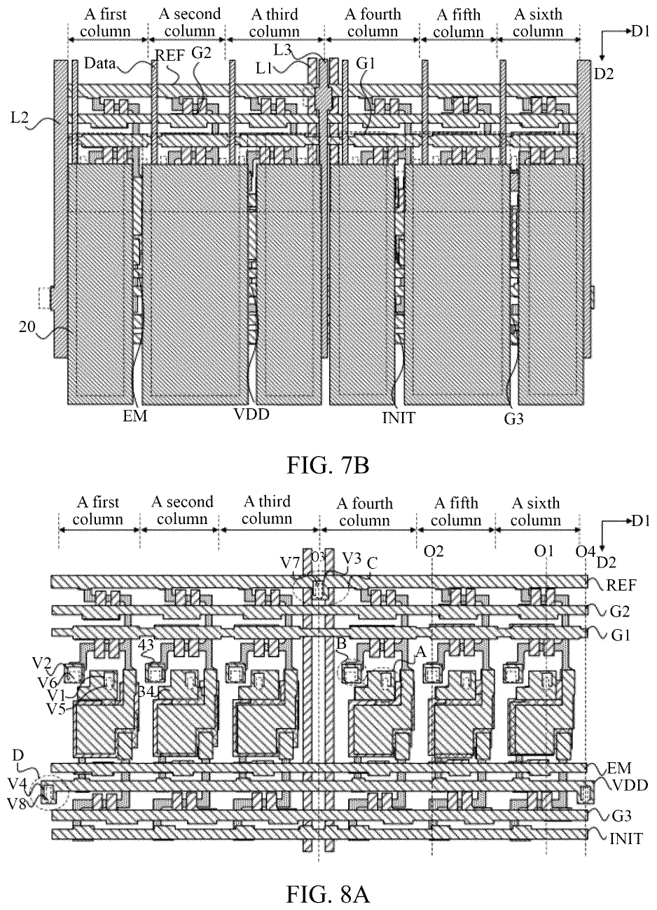

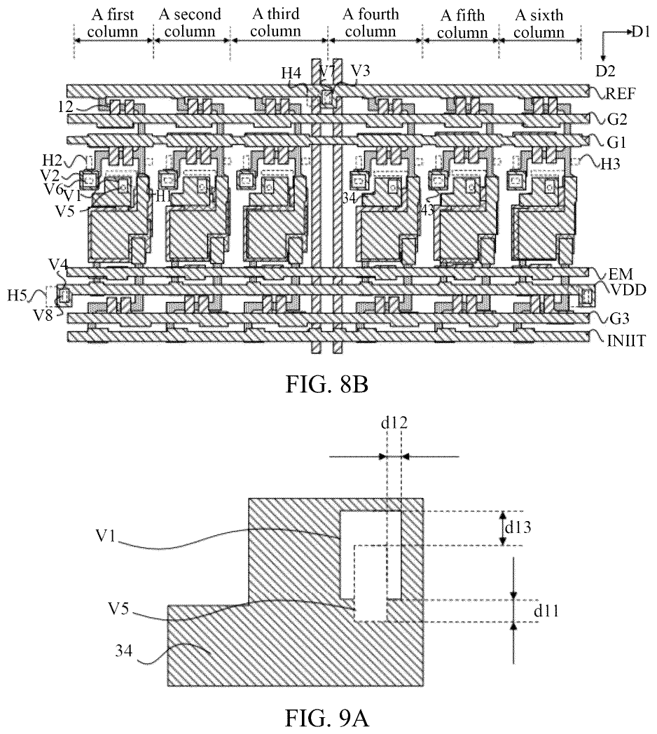

FIG. 7A is a first schematic diagram of a structure of a display substrate according to an embodiment of the present disclosure, FIG. 7B is a second schematic diagram of a structure of a display substrate according to an embodiment of the present disclosure, FIG. 8A is a schematic diagram of a partial film layer of the display substrate provided in FIG. 7A, and FIG. 8B is a schematic diagram of a partial film layer of the display substrate provided in FIG. 7B. As shown in FIG. 7A, FIG. 7B, FIG. 8A, and FIG. 8B, an embodiment of the present disclosure provides a display substrate provided with a plurality of sub-pixels arranged in an array, at least one of the sub-pixels includes a pixel drive circuit, wherein the display substrate includes a base substrate and a drive structure layer disposed on the base substrate, and the pixel drive circuit is disposed on the drive structure layer.

In an exemplary implementation mode, the drive structure layer at least includes a first insulation layer, a semiconductor layer, a second insulation layer, a first conductive layer, a third insulation layer, a second conductive layer, a fourth insulation layer, a third conductive layer, a first planarization layer, a fifth insulation layer, and a fourth conductive layer which are stacked on the base substrate sequentially. FIGS. 7A and 7B show a first insulation layer, a semiconductor layer, a second insulation layer, a first conductive layer, a third insulation layer, a second conductive layer, a fourth insulation layer, a third conductive layer, a first planarization layer, and a fifth insulation layer.

As shown in FIGS. 7A and 7B, the fifth insulation layer is provided with a plurality of vias, and at least one via on the fifth insulation layer exposes the first planarization layer.

As shown in FIGS. 7A and 7B, a thickness of the first planarization layer may be greater than a thickness of the fifth insulation layer.

In an exemplary implementation mode, the thickness of the fifth insulation layer is about 1,200 angstroms to 1,600 angstroms. Exemplarily, the thickness of the fifth insulation layer is about 1,400 angstroms.

In an exemplary implementation mode, the thickness of the first planarization layer is about 18,000 angstroms to 22,000 angstroms. Exemplarily, the thickness of the first planarization layer is about 20,000 angstroms.

In an exemplary implementation mode, a manufacturing material of the first planarization layer may include polyimide.

In the present disclosure, the first planarization layer is exposed by at least one via on the fifth insulation layer, which may form a deflation channel, so that residual water vapor within the first planarization layer in a subsequent manufacturing project may be released, a bulge defect of the display substrate is avoided, reliability of the display substrate is improved, and further a display effect of a display product is ensured.

In an exemplary implementation mode, as shown in conjunction with FIG. 7A to FIG. 7B, the pixel drive circuit may include a first transistor to a fifth transistor, and the drive structure layer further includes a first scan signal line G1, a second scan signal line G2, a third scan signal line G3, an initial signal line INIT, a data signal line Data, a light emitting signal line EM, a reference signal line REF, and a first power supply line VDD, wherein the first transistor is electrically connected with the third scan signal line G3 and the initial signal line INIT respectively, the second transistor is electrically connected with the second scan signal line G2 and the reference signal line REF respectively, the fourth transistor is electrically connected with the first scan signal line G1 and the data signal line Data respectively, and the fifth transistor is electrically connected with the light emitting signal line EM and the first power supply line VDD, respectively.

In an exemplary implementation mode, any of the first scan signal line G1, the second scan signal line G2, the third scan signal line G3, the initial signal line INIT, the light emitting signal line EM, the reference signal line REF, and the first power supply line VDD at least partially extends along a first direction D1, and the data signal line Data at least partially extends along a second direction D2, and the first direction D1 intersects with the second direction D2.

In an exemplary implementation mode, the reference signal line REF, the second scan signal line G2, the first scan signal line G1, the light emitting signal line EM, the first power supply line VDD, the third scan signal line G3, and the initial signal line INIT connected with any sub-pixel are arranged sequentially along the second direction D2.

In an exemplary implementation mode, as shown in FIGS. 8A and 8B, the first planarization layer is provided with a first via V1 to a fourth via V4, wherein an orthographic projection of the first via V1 on the base substrate is within a range of an orthographic projection of a second electrode 34 of the third transistor on the base substrate and the first via V1 exposes a surface of the second electrode 34 of the third transistor, an orthographic projection of the second via V2 on the base substrate is within a range of an orthographic projection of a first electrode 43 of the fourth transistor on the base substrate and the second via V2 exposes a surface of the first electrode 43 of the fourth transistor, an orthographic projection of the third via V3 on the base substrate is within a range of an orthographic projection of a reference signal line REF on the base substrate and the third via V3 exposes a surface of the reference signal line REF, and an orthographic projection of the fourth via V4 on the base substrate is within a range of an orthographic projection of the first power supply line VDD on the base substrate and the fourth via V4 exposes a surface of the first power supply line VDD.

In an exemplary implementation mode, as shown in FIGS. 8A and 8B, the third via V3 is located on a centerline of two adjacent fourth vias V4 extending along the second direction D2.

In an exemplary implementation mode, as shown in FIG. 8A, the fifth insulation layer is provided with a fifth via V5 to an eighth via V8. Herein, an orthographic projection of the fifth via V5 on the base substrate is within a range of orthographic projections of the first via V1 and the first planarization layer on the base substrate, an orthographic projection of the sixth via V6 on the base substrate is within a range of orthographic projections of the second via V2 and the first planarization layer on the base substrate, an orthographic projection of the seventh via V7 on the base substrate is within a range of orthographic projections of the third via V3 and the first planarization layer on the base substrate, and an orthographic projection of the eighth via V8 on the base substrate is within a range of orthographic projections of the fourth via V4 and the first planarization layer on the base substrate. In an exemplary implementation mode, an orthographic projection of any one of the fifth via V5 to the eighth via V8 on the base substrate is overlapped with an orthographic projection of the first planarization layer on the base substrate, namely, any one of the fifth via V5 to the eighth via V8 exposes the first planarization layer, and may be used as a deflation channel, so that residual water vapor within the first planarization layer in a subsequent manufacturing project may be released, a bulge defect of the display substrate is avoided, reliability of the display substrate is improved, and further a display effect of a display product is ensured.

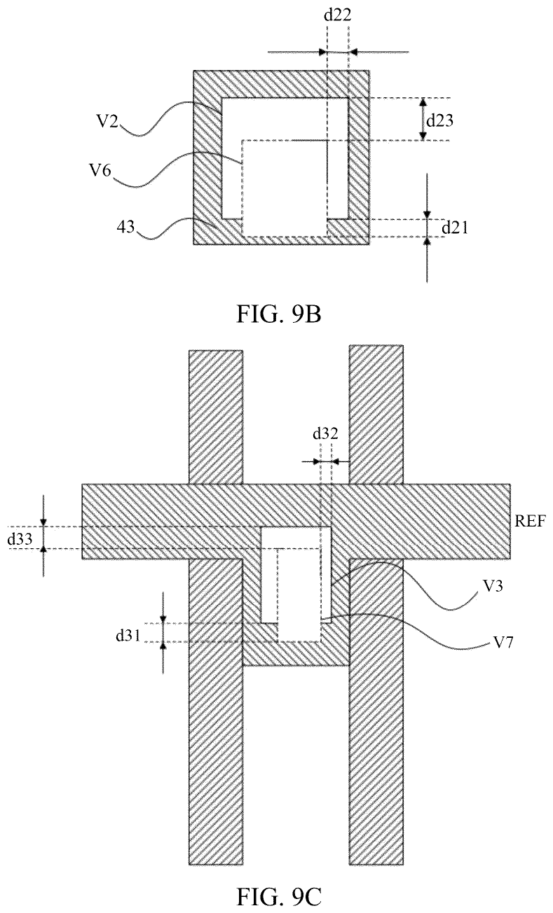

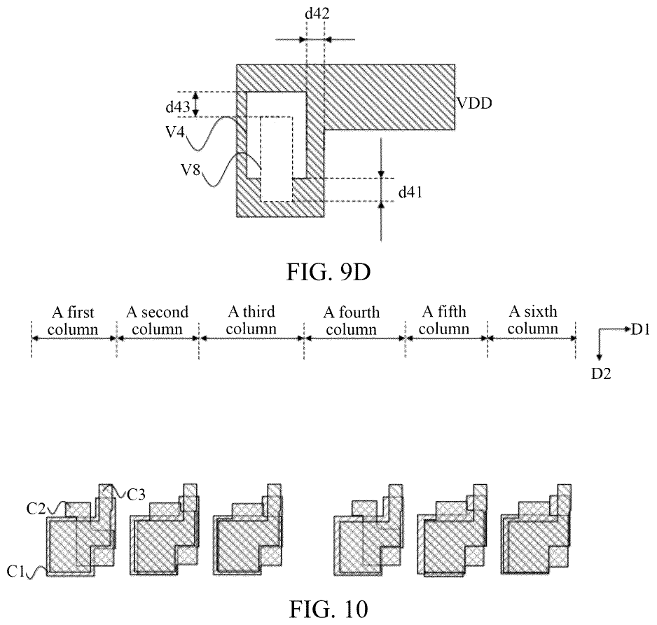

FIG. 9A is an enlarged schematic diagram of a region A in the display substrate provided in FIG. 8A, FIG. 9B is an enlarged schematic diagram of a region B in the display substrate provided in FIG. 8A, FIG. 9C is an enlarged schematic diagram of a region C in the display substrate provided in FIG. 8A, and FIG. 9D is an enlarged schematic diagram of a region D in the display substrate provided in FIG. 8A.

In an exemplary implementation mode, as shown in FIGS. 8A and 9A, a length of the fifth via V5 along the first direction D1 is less than a length of the first via V1 along the first direction D1, and a length of the fifth via V5 along the second direction D2 is less than a length of the first via V1 along the second direction D2.

In an exemplary implementation mode, as shown in FIG. 8A, within any sub-pixel, boundaries of a via include a first boundary, a second boundary, a third boundary, and a fourth boundary, wherein the first boundary of the via is a boundary of the via close to a first signal line, the second boundary of the via is a boundary of the via away from the first signal line, the third boundary of the via is a boundary located on one side of a first centerline O1, and the fourth boundary of the via is a boundary located on the other side of the first centerline O1. Herein, the via includes a first via V1 and a fifth via V5, the first signal line is one signal line of the light emitting signal line EM, the first power supply line VDD, the third scan signal line G3, and the initial signal line INIT connected with the sub-pixel, the first centerline O1 is a centerline of the first via extending along the second direction D2, a third boundary of the first via V1 and a third boundary of the fifth via V5 are located on a same side of the first centerline, and a fourth boundary of the first via V1 and a fourth boundary of the fifth via V5 are located on a same side of the first centerline.

In an exemplary implementation mode, as shown in FIG. 8A, a distance between an orthographic projection of a first boundary of the first via V1 on the base substrate and an orthographic projection of the first signal line on the base substrate is greater than a distance between an orthographic projection of a first boundary of the fifth via V5 on the base substrate and the orthographic projection of the first signal line on the base substrate, a distance between an orthographic projection of a second boundary of the first via V1 on the base substrate and the orthographic projection of the first signal line on the base substrate is greater than a distance between an orthographic projection of a second boundary of the fifth via V5 on the base substrate and the orthographic projection of the first signal line on the base substrate, a distance between a third boundary of the first via V1 and the first centerline O1 is greater than a distance between an orthographic projection of a third boundary of the fifth via V5 on the base substrate and an orthographic projection of the first centerline O1 on the base substrate, and a distance between a fourth boundary of the first via V1 and the first centerline O1 is greater than a distance between an orthographic projection of a fourth boundary of the fifth via V5 on the base substrate and the orthographic projection of the first centerline O1 on the base substrate.

In an exemplary implementation mode, as shown in FIG. 9A, within any sub-pixel, a distance d11 between the orthographic projection of the first boundary of the first via V1 on the base substrate and the orthographic projection of the first boundary of the fifth via V5 on the base substrate is greater than a distance d12 between the orthographic projection of the third boundary of the first via V1 on the base substrate and the orthographic projection of the third boundary of the fifth via V5 on the base substrate, and is smaller than a distance d13 between the orthographic projection of the second boundary of the first via V1 on the base substrate and the orthographic projection of the second boundary of the fifth via V5 on the base substrate. In the present disclosure, d11>d12 and d13>d11 may facilitate deflation of the first planarization layer on a basis of saving space of the fifth via.

In an exemplary implementation mode, as shown in FIG. 9A, the distance d11 between the orthographic projection of the first boundary of the first via V1 on the base substrate and the orthographic projection of the first boundary of the fifth via V5 on the base substrate is about 1 micron to 2 microns. Exemplarily, the distance d11 between the orthographic projection of the first boundary of the first via V1 on the base substrate and the orthographic projection of the first boundary of the fifth via V5 on the base substrate may be about 1.5 microns.

In an exemplary implementation mode, as shown in FIGS. 8A and 9B, a length of the sixth via V6 along the first direction D1 is less than a length of the second via V2 along the first direction D1, and a length of the sixth via V6 along the second direction D2 is less than a length of the second via V2 along the second direction D2.

In an exemplary implementation mode, as shown in FIG. 8A, within any sub-pixel, boundaries of a via include: a first boundary, a second boundary, a third boundary, and a fourth boundary, wherein the first boundary of the via is a boundary of the via close to a first signal line, the second boundary of the via is a boundary of the via away from the first signal line, the third boundary of the via is a boundary located on one side of a second centerline O2, and the fourth boundary of the via is a boundary located on the other side of the second centerline O2; the via includes a second via V2 and a sixth via V6; the first signal line is one signal line of the light emitting signal line EM, the first power supply line VDD, the third scan signal line G3, and the initial signal line INIT which are connected with the sub-pixel; the second centerline O2 is a centerline of the second via V2 extending along a second direction, a third boundary of the second via V2 and a third boundary of the sixth via V6 are located on a same side of the second centerline O2, and a fourth boundary of the second via V2 and a fourth boundary of the sixth via V6 are located on a same side of the second centerline O2.

In an exemplary implementation mode, as shown in FIG. 8A, a distance between an orthographic projection of a first boundary of the second via V2 on the base substrate and an orthographic projection of the first signal line on the base substrate is greater than a distance between an orthographic projection of a first boundary of the sixth via V6 on the base substrate and the orthographic projection of the first signal line on the base substrate, a distance between an orthographic projection of a second boundary of the second via V2 on the base substrate and the orthographic projection of the first signal line on the base substrate is greater than a distance between an orthographic projection of a second boundary of the sixth via V6 on the base substrate and the orthographic projection of the first signal line on the base substrate, a distance between a third boundary of the second via V2 and the second centerline O2 is greater than a distance between an orthographic projection of a third boundary of the sixth via V6 on the base substrate and an orthographic projection of the second centerline O2 on the base substrate, and a distance between a fourth boundary of the second via V2 and the second centerline O2 is greater than a distance between an orthographic projection of a fourth boundary of the sixth via V6 on the base substrate and the orthographic projection of the second centerline O2 on the base substrate.

In an exemplary implementation mode, as shown in FIG. 9B, within any sub-pixel, a distance d21 between the orthographic projection of the first boundary of the second via V2 on the base substrate and the orthographic projection of the first boundary of the sixth via V6 on the base substrate is greater than a distance d22 between the orthographic projection of the third boundary of the second via V2 on the base substrate and the orthographic projection of the third boundary of the sixth via V6 on the base substrate, and is less than a distance d23 between the orthographic projection of the second boundary of the second via V2 on the base substrate and the orthographic projection of the second boundary of the sixth via V6 on the base substrate. In the present disclosure, d21>d22 and d23>d21 may facilitate deflation of the first planarization layer on a basis of saving space of the sixth via.

In an exemplary implementation mode, as shown in FIG. 9B, the distance between the orthographic projection of the first boundary of the second via V2 on the base substrate and the orthographic projection of the first boundary of the sixth via V6 on the base substrate is about 1 micron to 2 microns. Exemplarily, the distance between the orthographic projection of the first boundary of the second via V2 on the base substrate and the orthographic projection of the first boundary of the sixth via V6 on the base substrate may be about 1.5 microns.

In an exemplary implementation mode, as shown in FIGS. 8A and 9C, a length of the seventh via V7 along the first direction D1 is less than a length of the third via V3 along the first direction D1, and a length of the seventh via V7 along the second direction D2 is less than or equal to a length of the third via V3 along the second direction D2.

In an exemplary implementation mode, as shown in FIG. 8A, boundaries of a via include: a first boundary, a second boundary, a third boundary, and a fourth boundary, wherein the first boundary of the via is a boundary of the via close to a second signal line, the second boundary of the via is a boundary of the via away from the second signal line, the third boundary of the via is a boundary located on one side of a third centerline O3, and the fourth boundary of the via is a boundary located on the other side of the third centerline O3; the via includes a third via V3 and a seventh via V7; the second signal line is one signal line of a light emitting signal line EM, a first power supply line VDD, a first scan signal line G1, a second scan signal line G2, a third scan signal line G3, an initial signal line INIT, and a light emitting signal line EM which are connected with a sub-pixel connected with a reference signal line REF exposed by the third via V3; the third centerline O3 is a centerline of the third via V3 extending along the second direction D2, a third boundary of the third via V3 and a third boundary of the seventh via V7 are located on a same side of the third centerline O3, and a fourth boundary of the third via V3 and a fourth boundary of the seventh via V7 are located on a same side of the third centerline O3.

In an exemplary implementation mode, as shown in FIG. 8A, a distance between an orthographic projection of a first boundary of the third via V3 on the base substrate and an orthographic projection of the second signal line on the base substrate is greater than a distance between an orthographic projection of a first boundary of the seventh via V7 on the base substrate and the orthographic projection of the second signal line on the base substrate, a distance between an orthographic projection of a second boundary of the third via V3 on the base substrate and the orthographic projection of the second signal line on the base substrate is greater than a distance between an orthographic projection of a second boundary of the seventh via V7 on the base substrate and the orthographic projection of the second signal line on the base substrate, a distance between the third boundary of the third via V3 and the third centerline O3 is greater than a distance between an orthographic projection of the third boundary of the seventh via V7 on the base substrate and an orthographic projection of the third centerline O3 on the base substrate, and a distance between the fourth boundary of the third via V3 and the third centerline O3 is greater than a distance between an orthographic projection of the fourth boundary of the seventh via V7 on the base substrate and the orthographic projection of the third centerline O3 on the base substrate.

In an exemplary implementation mode, as shown in FIG. 9C, a distance d31 between the orthographic projection of the first boundary of the third via V3 on the base substrate and the orthographic projection of the first boundary of the seventh via V7 on the base substrate is greater than a distance d33 between the orthographic projection of the third boundary of the third via V3 on the base substrate and the orthographic projection of the third boundary of the seventh via V7 on the base substrate, and is less than a distance d32 between the orthographic projection of the second boundary of the third via V3 on the base substrate and the orthographic projection of the second boundary of the seventh via V7 on the base substrate. In the present disclosure, d31>d32 and d33>d31 may facilitate deflation of the first planarization layer on a basis of saving space of the seventh via.

In an exemplary implementation mode, as shown in FIG. 9C, the distance d31 between the orthographic projection of the first boundary of the third via V3 on the base substrate and the orthographic projection of the first boundary of the seventh via V7 on the base substrate is about 1 micron to 2 microns. Exemplarily, the distance d31 between the orthographic projection of the first boundary of the third via V3 on the base substrate and the orthographic projection of the first boundary of the seventh via V7 on the base substrate may be about 1.5 microns.

In an exemplary implementation mode, as shown in FIGS. 8A and 9D, a length of the eighth via V8 along the first direction D1 is greater than a length of the fourth via V4 along the first direction D1, and a length of the eighth via V8 along the second direction D2 is greater than or equal to a length of the fourth via V4 along the second direction D2.

In an exemplary implementation mode, as shown in FIG. 8A, boundaries of a via include: a first boundary, a second boundary, a third boundary, and a fourth boundary, wherein the first boundary of the via is a boundary of the via close to a third signal line, the second boundary of the via is a boundary of the via away from the third signal line, the third boundary of the via is a boundary located on one side of a fourth centerline O4, and the fourth boundary of the via is a boundary located on the other side of the fourth centerline O4; the via includes a fourth via V4 and an eighth via V8; the third signal line is any one signal line of a third scan signal line and an initial signal line which are connected with a sub-pixel connected with a first power supply line exposed by the fourth via V4; the fourth centerline O4 is a centerline of the fourth via V4 extending along the second direction D2, a third boundary of the fourth via V4 and a third boundary of the eighth via V8 are located on a same side of the fourth centerline O4, and a fourth boundary of the fourth via V4 and a fourth boundary of the eighth via V8 are located on a same side of the fourth centerline O4.

In an exemplary implementation mode, as shown in FIG. 8A, a distance between an orthographic projection of a first boundary of the fourth via V4 on the base substrate and an orthographic projection of the third signal line on the base substrate is greater than a distance between an orthographic projection of a first boundary of the eighth via V8 on the base substrate and the orthographic projection of the third signal line on the base substrate, a distance between an orthographic projection of a second boundary of the fourth via V4 on the base substrate and the orthographic projection of the third signal line on the base substrate is greater than a distance between an orthographic projection of a second boundary of the eighth via V8 on the base substrate and the orthographic projection of the third signal line on the base substrate, a distance between the third boundary of the fourth via V4 and the fourth centerline O4 is greater than a distance between an orthographic projection of the third boundary of the eighth via V8 on the base substrate and an orthographic projection of the fourth centerline O4 on the base substrate, and a distance between the fourth boundary of the fourth via V4 and the fourth centerline O4 is greater than a distance between an orthographic projection of the fourth boundary of the eighth via V8 on the base substrate and the orthographic projection of the fourth centerline O4 on the base substrate.

In an exemplary implementation mode, as shown in FIG. 9D, a distance d41 between the orthographic projection of the first boundary of the fourth via V4 on the base substrate and the orthographic projection of the first boundary of the eighth via V8 on the base substrate is greater than a distance d42 between the orthographic projection of the third boundary of the fourth via V4 on the base substrate and the orthographic projection of the third boundary of the eighth via V8 on the base substrate, and is less than a distance d43 between the orthographic projection of the second boundary of the fourth via V4 on the base substrate and the orthographic projection of the second boundary of the eighth via V8 on the base substrate. In the present disclosure, d41>d42 and d43>d41 may facilitate deflation of the first planarization layer on a basis of saving space of the eighth via.

In an exemplary implementation mode, as shown in FIG. 9D, the distance d41 between the orthographic projection of the first boundary of the fourth via V4 on the base substrate and the orthographic projection of the first boundary of the eighth via V8 on the base substrate is about 1 micron to 2 microns. Exemplarily, the distance d41 between the orthographic projection of the first boundary of the fourth via V4 on the base substrate and the orthographic projection of the first boundary of the eighth via V8 on the base substrate may be about 1.5 microns.

In an exemplary implementation mode, as shown in FIG. 8B, the fifth insulation layer is provided with a fifth via V5 to an eighth via V8. Herein, an orthographic projection of the fifth via V5 on the base substrate is within a range of an orthographic projection of the first via V1 on the base substrate, an orthographic projection of the sixth via V6 on the base substrate is within a range of an orthographic projection of the second via V2 on the base substrate, an orthographic projection of the seventh via V7 on the base substrate is within a range of an orthographic projection of the third via V3 on the base substrate, and an orthographic projection of the eighth via V8 on the base substrate is within a range of an orthographic projection of the fourth via V4 on the base substrate.

In an exemplary implementation mode, as shown in FIG. 8B, the fifth insulation layer is further provided with any one of a first vent hole H1 and a second vent hole H2.

In an exemplary implementation mode, as shown in FIG. 8B, orthographic projections of the first vent hole H1 and the second vent hole H2 on the base substrate are partially overlapped with an orthographic projection of the first planarization layer on the base substrate, and the first planarization layer is exposed.

In an exemplary implementation mode, as shown in FIG. 8B, there is no overlapping region between the orthographic projections of the first vent hole H1 and the second vent hole H2 on the base substrate and orthographic projections of an active pattern, a gate electrode, a first electrode, and a second electrode of any transistor, and a reference signal line REF, a first scan signal line G1, a second scan signal line G2, a third scan signal line G3, an initial signal line INIT, a first power supply line VDD, and a light emitting signal line EM on the base substrate.

In an exemplary implementation mode, as shown in FIG. 8B, a length of the first vent hole H1 along the first direction D1 is greater than a length of the second electrode 34 of the third transistor close to a boundary of the first scan signal line G1, and a length of the first vent hole H1 along the second direction D2 is greater than a length of the sixth via V6 along the second direction D2.

In an exemplary implementation mode, as shown in FIG. 8B, an orthographic projection of the first vent hole H1 on the base substrate is at least disposed surrounding at least one side of the orthographic projection of the first via V1 on the base substrate.

In an exemplary implementation mode, as shown in FIG. 8B, a distance between the orthographic projection of the first vent hole H1 on the base substrate and the orthographic projection of the fifth via V5 on the base substrate is smaller than a distance between an orthographic projection of the first scan signal line G1 on the base substrate and the orthographic projection of the fifth via V5 on the base substrate, that is, the first vent hole H1 is disposed at a periphery of a sleeve hole including the fifth via V5 and the first via V1.

In an exemplary implementation mode, as shown in FIG. 8B, a length of the second vent hole H2 along the second direction D2 is greater than a length of the sixth via V6 along the second direction D2, and a length of the second vent hole H2 along the first direction D1 is less than a length of the sixth via V6 along the first direction D1.

In an exemplary implementation mode, as shown in FIG. 8B, the second vent hole H2 and the sixth via V6 are arranged along the second direction D2.

In an exemplary implementation mode, as shown in FIG. 8B, a distance between an orthographic projection of the sixth via V6 on the base substrate and an orthographic projection of the first scan signal line G1 on the base substrate is greater than a distance between the second vent hole H2 and the sixth via V6. That is, the second vent hole is disposed at a periphery of a sleeve hole including the second via V2 and the sixth via V6.

In an exemplary implementation mode, as shown in FIG. 8B, the fifth insulation layer is further provided with a third vent hole H3. Herein, an orthographic projection of the third vent hole H3 on the base substrate is partially overlapped with an orthographic projection of the first planarization layer on the base substrate, and the first planarization layer is exposed.

In an exemplary implementation mode, as shown in FIG. 8B, the orthographic projection of the third vent hole H3 on the base substrate is located between the orthographic projection of the first scan signal line G1 on the base substrate and an orthographic projection of the light emitting signal line EM on the base substrate, and there is no overlapping region between the orthographic projection of the third vent hole H3 on the base substrate and orthographic projections of an active pattern, a gate electrode, a first electrode, and a second electrode of any transistor, and the reference signal line REF, the first scan signal line G1, the second scan signal line G2, the third scan signal line G3, the initial signal line INIT, the first power supply line VDD, and the light emitting signal line EM on the base substrate.

In an exemplary implementation mode, as shown in FIG. 8B, the fifth insulation layer is further provided with at least one of a fourth vent hole H4 and a fifth vent hole H5. Herein, orthographic projections of the fourth vent hole H4 and the fifth vent hole H5 on the base substrate are partially overlapped with an orthographic projection of the first planarization layer on the base substrate, and the first planarization layer is exposed.

In an exemplary implementation mode, as shown in FIG. 8B, an orthographic projection of the fourth vent hole H4 on the base substrate is at least partially overlapped with an orthographic projection of the reference signal line REF on the base substrate, and there is no overlapping region between the orthographic projection of the fourth vent hole H4 on the base substrate and orthographic projections of an active pattern, a gate electrode, a first electrode, and a second electrode of any transistor, and the first scan signal line G1, the second scan signal line G2, the third scan signal line G3, the initial signal line INIT, the first power supply line VDD, and the light emitting signal line EM on the base substrate.

In an exemplary implementation mode, as shown in FIG. 8B, there is no overlapping region between an orthographic projection of one portion of the fifth vent hole H5 on the base substrate and orthographic projections of an active pattern, a gate electrode, a first electrode, and a second electrode of any transistor, and a reference signal line REF, a first scan signal line G1, a second scan signal line G2, a third scan signal line G3, an initial signal line INIT, a first power supply line VDD, and a light emitting signal line EM on the base substrate, and an orthographic projection of the other portion of the fifth vent hole H5 on the base substrate is at least partially overlapped with an orthographic projection of the first power supply line VDD and there is no overlapping region between the orthographic projection of the other portion of the fifth vent hole H5 on the base substrate and orthographic projections of an active pattern, a gate electrode, a first electrode, and a second electrode of any transistor, and a reference signal line REF, a first scan signal line G1, a second scan signal line G2, a third scan signal line G3, an initial signal line INIT, and a light emitting signal line EM on the base substrate. Exemplarily, there is no overlapping region between an orthographic projection of a fifth vent hole located on a side of a first column of sub-pixels away from a second column of sub-pixels on the base substrate and orthographic projections of an active pattern, a gate electrode, a first electrode, and a second electrode of any transistor, and a reference signal line REF, a first scan signal line G1, a second scan signal line G2, a third scan signal line G3, an initial signal line INIT, a first power supply line VDD, and a light emitting signal line EM on the base substrate, and an orthographic projection of a remaining fifth vent hole on the base substrate is at least partially overlapped with an orthographic projection of the first power supply line VDD and there is no overlapping region between the orthographic projection of the remaining fifth vent hole on the base substrate and orthographic projections of an active pattern, a gate electrode, a first electrode, and a second electrode of any transistor, a reference signal line REF, a first scan signal line G1, a second scan signal line G2, a third scan signal line G3, an initial signal line INIT, and a light emitting signal line EM on the base substrate.

In an exemplary implementation mode, as shown in FIG. 8B, a length of the fourth vent hole H4 along the second direction D2 is greater than a length of the third via V3 along the second direction D2, and a length of the fourth vent hole H4 along the first direction D1 is less than a length of the third via V3 along the first direction D1.

In an exemplary implementation mode, as shown in FIG. 8B, the fourth vent hole H4 and the seventh via V7 are arranged along the first direction D1, and a distance between an orthographic projection of the fourth vent hole on the base substrate and an orthographic projection of a gate electrode 12 of a first transistor of an adjacent sub-pixel on the base substrate is smaller than a distance between an orthographic projection of the seventh via V7 on the base substrate and an orthographic projection of the gate electrode 12 of the first transistor of the adjacent sub-pixel on the base substrate. That is, the fourth vent hole H4 is located at a periphery of a sleeve hole including the third via V3 and the seventh via V7.

In an exemplary implementation mode, as shown in FIG. 8B, a length of the fifth vent hole H5 along the second direction D2 is greater than a length of the fourth via V4 along the second direction D2, and a length of the fifth vent hole H5 along the first direction D1 is less than a length of the fourth via V4 along the first direction D1.

In an exemplary implementation mode, as shown in FIG. 8B, the fifth vent hole H5 and the eighth via H8 are arranged along the first direction D1, and a distance between an orthographic projection of the fifth vent hole H5 on the base substrate and an orthographic projection of the fourth via V4 on the base substrate is smaller than a distance between the orthographic projection of the fourth via V4 on the base substrate and the orthographic projection of the gate electrode 12 of the first transistor on the base substrate. That is, the fifth vent hole H5 is located at a periphery of a sleeve hole including the fourth via V4 and the eighth via V8.

In an exemplary implementation mode, FIG. 10 is a schematic diagram of a capacitor of the display substrate provided in FIGS. 7A and 7B. As shown in conjunction with FIGS. 7A, 7B, and 10, the pixel drive circuit further includes a capacitor, the capacitor includes a first electrode plate C1, a second electrode plate C2, and a third electrode plate C3, wherein the first electrode plate C1 is electrically connected with the third electrode plate C3; the semiconductor layer at least includes: an active pattern of at least one transistor; the first conductive layer at least includes a gate electrode of at least one transistor and the first electrode plate C1 of the capacitor; the second conductive layer at least includes the second electrode plate C2 of the capacitor; the third conductive layer at least includes a first electrode and a second electrode of at least one transistor, a first scan signal line G1, a second scan signal line G2, a third scan signal line G3, a light emitting signal line EM, an initial signal line INIT, a reference signal line REF, a first power supply line VDD, and the third electrode plate C3 of the capacitor; and the fourth conductive layer at least includes a data signal line Data.

In an exemplary implementation mode, as shown in FIG. 10, the first electrode plate C1 of the capacitor includes a first gate connection portion and a second gate connection portion, a second gate connection portion of a present column of sub-pixels is located on a side of a first gate connection portion close to a next column of sub-pixels, and a distance between a boundary of the first gate connection portion close to a gate electrode of a fifth transistor and the gate electrode of the fifth transistor is less than a distance between a boundary of the second gate connection portion close to the gate electrode of the fifth transistor and the gate electrode of the fifth transistor; a distance between a boundary of the first gate connection portion away from the gate electrode of the fifth transistor and the gate electrode of the fifth transistor is less than a distance between a boundary of the second gate connection portion away from the gate electrode of the fifth transistor and the gate electrode of the fifth transistor.

In an exemplary implementation mode, a length of the first gate connection portion along the first direction D1 is larger than a length of the second gate connection portion along the first direction D1, and a length of the first gate connection portion along the second direction D2 is larger than a length of the second gate connection portion along the second direction D2.

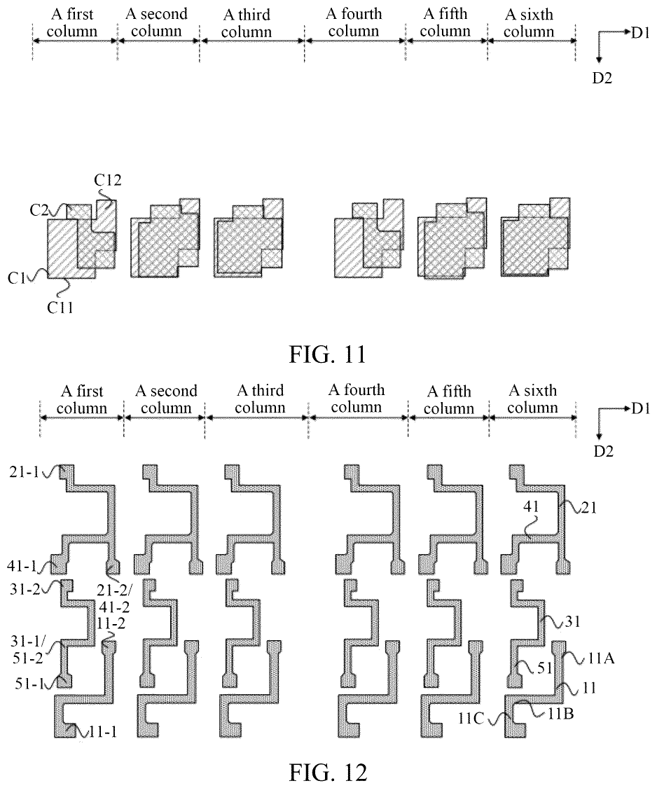

In an exemplary implementation mode, FIG. 11 is a schematic diagram of a partial film layer of the capacitor of the display substrate provided in FIG. 7A and FIG. 7B. As shown in FIG. 11, an orthographic projection of the second electrode plate C2 of the capacitor on the base substrate is at least partially overlapped with an orthographic projection of the first electrode plate of the capacitor on the base substrate.

In an exemplary implementation mode, as shown in FIG. 11, shapes and areas of second electrode plates of capacitors located in a same column of sub-pixels are the same, and an area of a second electrode plate of a capacitor of a (3k+1)-th column of sub-pixels is smaller than any one of an area of a second electrode plate of a capacitor of a (3k+2)-th column of sub-pixels and an area of a second electrode plate of a capacitor of a (3k+3)-th column of sub-pixels.

In an exemplary implementation mode, as shown in FIG. 11, an area of an overlapping region between a second electrode plate of a capacitor and a first electrode plate of the capacitor of a (3k+1)-th column of sub-pixels is smaller than an area of an overlapping region between a second electrode plate of a capacitor and a first electrode plate of the capacitor of a (3k+2)-th column sub-pixels, and the area of the overlapping region between the second electrode plate of the capacitor and the first electrode plate of the capacitor of the (3k+2)-th column of sub-pixels is smaller than an area of an overlapping region between a second electrode plate of a capacitor and a first electrode plate of the capacitor of a (3k+3)-th column of sub-pixels.

In an exemplary implementation mode, as shown in FIG. 11, an area of an overlapping region between a second electrode plate of a capacitor and a first gate connection portion of a (3k+1)-th column of sub-pixels is smaller than an area of an overlapping region between a second electrode plate of a capacitor and a first gate connection portion of a (3k+2)-th column of sub-pixels, and the area of the overlapping region between the second electrode plate of the capacitor and the first gate connection portion of the (3k+2)-th column of sub-pixels is smaller than an area of an overlapping region between a second electrode plate of a capacitor and a first gate connection portion of a (3k+3)-th column of sub-pixels.

In an exemplary implementation mode, as shown in FIG. 11, an area of an overlapping region between a second electrode plate of a capacitor and a second gate connection portion of a (3k+1)-th column of sub-pixels is smaller than an area of an overlapping region between a second electrode plate of a capacitor and a second gate connection portion of a (3k+2)-th column of sub-pixels, and an area of an overlapping region between a second electrode plate of a capacitor and a second gate connection portion of a (3k+3)-th column of sub-pixels is smaller than the area of the overlapping region between the second electrode plate of the capacitor and the second gate connection portion of the (3k+2)-th column of sub-pixels.

In an exemplary implementation mode, as shown in FIG. 10, an orthographic projection of the third electrode plate of the capacitor on the base substrate is at least partially overlapped with orthographic projections of the first electrode plate of the capacitor and the second electrode plate of the capacitor on the base substrate, respectively, and there is a non-overlapping region between the orthographic projection of the third electrode plate of the capacitor on the base substrate and an orthographic projection of the first electrode plate of the capacitor on the base substrate, and there is a non-overlapping region between the orthographic projection of the third electrode plate of the capacitor on the base substrate and an orthographic projection of the second electrode plate of the capacitor on the base substrate.

In an exemplary implementation mode, as shown in FIGS. 7A, 7B, 8A, and 8B, the display substrate may further include an initial connection line L1 located in the first conductive layer, the initial connection line L1 at least partially extends along the second direction D2, and the initial connection line L1 is electrically connected with the initial signal line INIT.

In an exemplary implementation mode, as shown in FIGS. 7A, 7B, 8A, and 8B, two initial connection lines L1 are disposed between at least two columns of sub-pixels, and two initial connection lines L1 located between at least two adjacent sub-pixels are symmetrically disposed with respect to a centerline of the two adjacent sub-pixels extending along the second direction D2.

In an exemplary implementation mode, a plurality of initial connection lines L1 and a plurality of initial signal lines INIT form a mesh structure, which may improve display uniformity of the display substrate and further improve reliability of the display substrate.

In an exemplary implementation mode, as shown in FIGS. 8A and 8B, an orthographic projection of the sixth via V6 on the base substrate is not overlapped with an orthographic projection of the initial connection line L1 on the base substrate.

In an exemplary implementation mode, as shown in FIGS. 7A and 7B, the display substrate may further include at least one of a power supply connection line L2 and a reference connection line L3 located in the fourth conductive layer, and any of the power supply connection line L2 and the reference connection line L3 at least partially extends along the second direction D2.

In an exemplary implementation mode, as shown in FIGS. 7A and 7B, the power supply connection line L2 is electrically connected with the first power supply line VDD, and the reference connection line is electrically connected with the reference signal line REF.

In an exemplary implementation mode, as shown in FIGS. 7A and 7B, an orthographic projection of at least a portion of the reference connection line L3 on the base substrate is located between orthographic projections of two initial connection lines L1 located between two adjacent sub-pixels on the base substrate, and an orthographic projection of the power supply connection line L2 on the base substrate and an orthographic projection of an initial connection line L1 on the base substrate are away from a side of an orthographic projection of the reference connection line L3 on the base substrate.

In an exemplary implementation mode, a plurality of reference connection lines L3 and a plurality of reference signal lines REF form a mesh structure, and a plurality of power supply connection lines L2 and a plurality of first power supply lines VDD form a mesh structure, which may improve display uniformity of the display substrate and further improve reliability of the display substrate.

In an exemplary implementation mode, as shown in FIG. 8B, when the fifth insulation layer is provided with at least one of a first vent hole H1 to a fifth vent hole H5, there is no overlapping region between orthographic projections of the first vent hole H1 to the fifth vent hole H5 on the base substrate and orthographic projections of the power supply connection line L2, the reference connection line L3, and the data signal line Data on the base substrate.

In an exemplary implementation mode, as shown in FIG. 8B, an orthographic projection of the fourth vent hole H4 on the base substrate is partially overlapped with an orthographic projection of the initial connection line L1 on the base substrate.

In an exemplary implementation mode, further including a light emitting structure, and the sub-pixel further includes a light emitting device, the light emitting device includes a first electrode, an organic emitting layer, and a second electrode, wherein the light emitting structure layer includes a light emitting device, and the light emitting structure layer includes a fifth conductive layer, a first pixel definition layer, a second pixel definition layer, a light emitting material layer, and a sixth conductive layer which are sequentially stacked on a side of the drive structure layer away from the base substrate; the fifth conductive layer at least includes the first electrode; the light emitting material layer at least includes the organic emitting layer; and the sixth conductive layer at least includes the second electrode.

In an exemplary implementation mode, a light transmittance of the first pixel definition layer may be less than a light transmittance of the second pixel definition layer.

In an exemplary implementation mode, the display substrate according to the present disclosure may be applied to a display device with a pixel drive circuit, such as an OLED, quantum dot display (QLED), light emitting diode display (Micro LED or Mini LED), or Quantum Dot Light Emitting Diode display (QDLED), which is not limited here in the present disclosure.

Exemplary description is made below through a preparation process of a display substrate. A “patterning process” mentioned in the present disclosure includes photoresist coating, mask exposure, development, etching, photoresist stripping, etc., for a metal material, an inorganic material, or a transparent conductive material, and includes organic material coating, mask exposure, development, etc., for an organic material. Deposition may be any one or more of sputtering, evaporation, and chemical vapor deposition, coating may be any one or more of spray coating, spin coating, and inkjet printing, and etching may be any one or more of dry etching and wet etching, which is not limited here in the present disclosure. A “thin film” refers to a layer of thin film made of a certain material on a base substrate using deposition, coating, or other processes. If the “thin film” does not need to be processed through a patterning process in an entire manufacturing process, the “thin film” may also be called a “layer”. If the “thin film” needs to be processed through the patterning process in the entire manufacturing process, the “thin film” is called a “thin film” before the patterning process is performed and is called a “layer” after the patterning process is performed. At least one “pattern” is contained in the “layer” which has been processed through the patterning process. “A and B are disposed in a same layer” in the present disclosure means that A and B are formed simultaneously through a same patterning process, and a “thickness” of a film layer is a dimension of the film layer in a direction perpendicular to a display substrate. In an exemplary implementation mode of the present disclosure, “an orthographic projection of B is within a range of an orthographic projection of A” or “an orthographic projection of A contains an orthographic projection of B” refers to that a boundary of the orthographic projection of B falls within a range of a boundary of the orthographic projection of A, or the boundary of the orthographic projection of A is overlapped with the boundary of the orthographic projection of B.

In an exemplary implementation mode, taking six sub-pixels (one sub-pixel row and six sub-pixel columns, for example, first to sixth columns of sub-pixels) as an example, a preparation process of a display substrate may include following operations.

(1) A pattern of a semiconductor layer is formed. In an exemplary implementation mode, forming the pattern of the semiconductor layer may include: depositing sequentially a first insulation thin film and a semiconductor thin film on a base substrate, and patterning the semiconductor thin film through a patterning process to form a first insulation layer covering the base substrate and the pattern of the semiconductor layer disposed on the first insulation layer. As shown in FIG. 12, FIG. 12 is a schematic diagram of a pattern of a semiconductor layer in FIGS. 7A and 7B.

In an exemplary implementation mode, as shown in FIG. 12, the pattern of the semiconductor layer may at least include an active pattern 11 of a first transistor to an active pattern 51 of a fifth transistor of each sub-pixel.

In an exemplary implementation mode, the active pattern 11 of the first transistor may be separately disposed, the active pattern 21 of the second transistor and the active pattern 41 of the fourth transistor are of an interconnected integral structure, and the active pattern 31 of the third transistor and the active pattern 51 of the fifth transistor are of an interconnected integral structure.

In the exemplary implementation mode, in a second direction D2, the integral structure of the active pattern 21 of the second transistor and the active pattern 41 of the fourth transistor, and the active pattern 11 of the first transistor are located on different sides of the integral structure of the active pattern 31 of the third transistor and the active pattern 51 of the fifth transistor, respectively. An integral structure of an active pattern 21 of a second transistor and an active pattern 41 of a fourth transistor of a present sub-pixel is located on a side of an integral structure of an active pattern 31 of a third transistor and an active pattern 51 of a fifth transistor of the present sub-pixel close to a previous row of sub-pixels, and an active pattern 11 of a first transistor of the present sub-pixel is located on a side of the integral structure of the active pattern 31 of the third transistor and the active pattern 51 of the fifth transistor of the present sub-pixel close to a next row of sub-pixels. The active pattern 41 of the fourth transistor is located on a side of the active pattern 21 of the second transistor close to the active pattern 11 of the first transistor, and the active pattern 51 of the fifth transistor is located on a side of the active pattern 31 of the third transistor close to the active pattern 11 of the first transistor.

In an exemplary implementation mode, the active pattern 11 of the first transistor may include a first active connection portion 11A, a second active connection portion 11B, and a third active connection portion 11C, wherein the first active connection portion 11A is located on a side of the second active connection portion 11B close to the integral structure of the active pattern 31 of the third transistor and the active pattern 51 of the fifth transistor, and the third active connection portion 11C is located on s side of the second active connection portion 11B away from the integral structure of the active pattern 31 of the third transistor and the active pattern 51 of the fifth transistor, the first active connection portion 11A may be in a strip shape and extend along the second direction D2, the second active connection portion 11B may be in a strip shape and extend along a first direction D1, the third active connection portion 11C may be in a shape of “L”, one end of the first active connection portion 11A is connected with one end of the second active connection portion 11B, and one end of the third active connection portion 11C is connected with the other end of the second active connection portion 11B.

In an exemplary implementation mode, the active pattern 21 of the second transistor may be in a shape of “┐”, the active pattern 31 of the third transistor may be in a shape of “Ω” rotated to the left, the active pattern 41 of the fourth transistor may be in a shape of “n”, and the active pattern 51 of the fifth transistor may be in a shape of “I”.

In an exemplary implementation mode, the first active connection portion 11A and the active pattern 51 of the fifth transistor are arranged along the second direction D2.

In an exemplary implementation mode, an active pattern of each transistor may include a first region, a second region, and a channel region located between the first region and the second region. In an exemplary implementation mode, a second region 21-2 of the active pattern 21 of the second transistor may serve as a second region 41-2 of the active pattern 41 of the fourth transistor, and a first region 31-1 of the active pattern 31 of the third transistor may serve as a second region 51-2 of the active pattern 51 of the fifth transistor. A first region 11-1 and a second region 11-2 of the active pattern 11 of the first transistor, a first region 21-1 of the active pattern 21 of the second transistor, a second region 31-2 of the active pattern 31 of the third transistor, a first region 41-1 of the active pattern 41 of the fourth transistor, and a first region 51-1 of the active pattern 51 of the fifth transistor may be separately disposed.

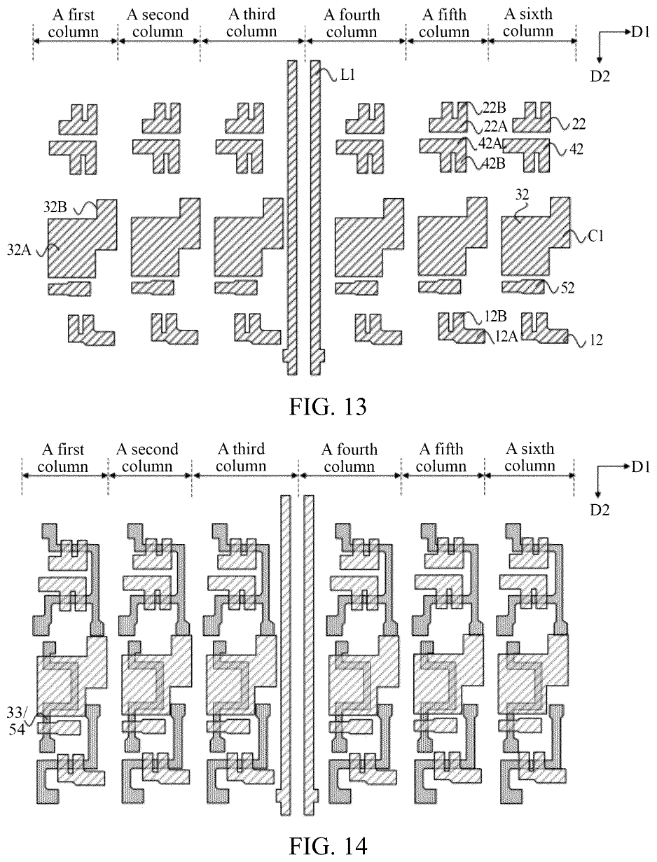

(2) A pattern of a first conductive layer is formed. In an exemplary implementation mode, forming the pattern of the first conductive layer may include: sequentially depositing a second insulation thin film and a first conductive thin film on the base substrate on which the aforementioned pattern is formed, and patterning the first conductive thin film through a patterning process to form a second insulation layer that covers the pattern of the semiconductor layer and a pattern of a first conductive layer disposed on the second insulation layer. As shown in FIG. 13 and FIG. 14, FIG. 13 is a schematic diagram of a pattern of a first conductive layer in FIGS. 7A and 7B, and FIG. 14 is a schematic diagram after the pattern of the first conductive layer is formed in FIGS. 7A and 7B. In an exemplary implementation mode, the first conductive layer may be referred to as a first gate metal (GATE1) layer.

In an exemplary implementation mode, the pattern of the first conductive layer may at least include a gate electrode 12 of a first transistor to a gate electrode 52 of a fifth transistor and a first electrode plate C1 of a capacitor located in each sub-pixel, and two initial connection lines L1 located between at least two columns of adjacent sub-pixels.

In an exemplary implementation mode, an initial connection line L1 may be in a shape of a line in which a main body portion extends along the second direction D2, and two initial connection lines L1 between at least two adjacent sub-pixels are disposed symmetrically with respect to a centerline of the two adjacent sub-pixels extending along the second direction D2.

In an exemplary implementation mode, the gate electrode 32 of the third transistor and the first electrode plate C1 of the capacitor are of an interconnected integral structure. The gate electrode 12 of the first transistor, the gate electrode 22 of the second transistor, the gate electrode 42 of the fourth transistor, and the gate electrode 52 of the fifth transistor may be separately disposed.

In an exemplary implementation mode, an integral structure of the gate electrode 32 of the third transistor and the first electrode plate C1 of the capacitor includes a first gate connection portion 32A and a second gate connection portion 32B, and shapes of the first gate connection portion 32A and the second gate connection 32B may be rectangular; a second gate connection portion 32B of a present column of sub-pixels is located on a side of a first gate connection portion 32A close to a next column of sub-pixels, and a distance between a boundary of the first gate connection portion 32A close to a gate electrode 52 of a fifth transistor and the gate electrode 52 of the fifth transistor is less than a distance between a boundary of the second gate connection portion 32B close to the gate electrode 52 of the fifth transistor and the gate electrode 52 of the fifth transistor; a distance between a boundary of the first gate connection portion 32A away from the gate electrode 52 of the fifth transistor and the gate electrode 52 of the fifth transistor is less than a distance between a boundary of the second gate connection portion 32B away from the gate electrode 52 of the fifth transistor and the gate electrode 52 of the fifth transistor.

In an exemplary implementation mode, a length of the first gate connection portion 32A along the first direction D1 is larger than a length of the second gate connection portion 32B along the first direction D1, and a length of the first gate connection portion 32A along the second direction D2 is larger than a length of the second gate connection portion 32B along the second direction D2.

In an exemplary implementation mode, the gate electrode 12 of the first transistor may include a first connection segment 12A and two first branch segments 12B, the two first branch segments 12B are located on a side of the first connection segment 12A close to the gate electrode 32 of the third transistor (also the first electrode plate C1 of the capacitor) and are respectively connected with the first connection segment 12A, wherein one end of one first branch segment 12B is connected with an end of the first connection segment 12A, and the other first branch segment 12B is connected with a middle of the first connection segment 12A. The first connection segment 12A may be in a strip shape and extend along the first direction D1, a first branch segment 12B extends along the second direction D2, and the two first branch segments 12B are arranged along the first direction D1.

In an exemplary implementation mode, a length of the first branch segment 12B along the first direction D1 is smaller than a sum of lengths of the first gate connection portion 32A and the second gate connection portion 32B along the first direction D1 and is larger than a length of the second gate connection portion 32B along the first direction D1, and a boundary of a first branch segment 12B of a present column of sub-pixels close to a next column of sub-pixels, and a boundary of a second gate connection portion 32B of the present column of sub-pixels close to the next column of sub-pixels are arranged along the second direction D2.

In an exemplary implementation mode, the gate electrode 22 of the second transistor may include a second connection segment 22A and two second branch segments 22B, the two second branch segments 22B are located on a side of the second connection segment 22A away from the gate electrode 32 of the third transistor (also the first electrode plate C1 of the capacitor) and are respectively connected with the second connection segment 22A, wherein one end of one second branch segment 22B is connected with an end of the second connection segment 22A, and the other second branch segment 22B is connected with a middle of the second connection segment 22A. The second connection segment 22A may be in a strip shape and extend along the first direction D1, a second branch segment 22B extends along the second direction D2, and the two second branch segments 22B are arranged along the first direction D1.

In an exemplary implementation mode, a length of the second branch segment 22B along the first direction D1 is smaller than a length of the first gate connection portion 32A along the first direction D1, and a distance between a straight line where a boundary of a second branch segment 22B of a present column of sub-pixels close to a next column of sub-pixels is located and a straight line where a boundary of the first gate connection portion 32A close to a previous column of sub-pixels is located is smaller than a length of the first gate connection portion 32A along the first direction D1.

In an exemplary implementation mode, a length of the first connection segment 12A along the first direction D1 is greater than a length of the second connection segment 22A along the first direction D1.

In an exemplary implementation mode, the gate electrode 42 of the fourth transistor may include a third connection segment 42A and two third branch segments 42B, the two third branch segments 42B are located on a side of the third connection segment 42A close to the gate electrode 32 of the third transistor (also the first electrode plate C1 of the capacitor) and are respectively connected with the third connection segment 42A, wherein one end of one third branch segment 42B is connected with an end of the third connection segment 42A, and the other third branch segment 42B is connected with a middle of the third connection segment 42A. The third connection segment 42A may be in a strip shape and extend along the first direction D1, a third branch segment 42B extends along the second direction D2, and the two third branch segments 42B are arranged along the first direction D1.

In an exemplary implementation mode, a length of the third branch segment 42B along the first direction D1 is smaller than a length of the first gate connection portion 32A along the first direction D1, and a distance between a straight line where a boundary of a third branch segment 42B of a present column of sub-pixels close to a next column of sub-pixels is located and a straight line where a boundary of a first gate connection portion 32A of the present column of sub-pixels close to a previous column of sub-pixels is located is smaller than a length of the first gate connection portion 32A along the first direction D1.

In an exemplary implementation mode, a length of the third connection segment 42A along the first direction D1 is greater than a length of the second connection segment 22A along the first direction D1, and a length of the third branch segment 42B along the second direction D2 is greater than a length of the second branch segment 22B along the second direction D2.

In an exemplary implementation mode, an area of the gate electrode 42 of the fourth transistor is larger than an area of the gate electrode 22 of the second transistor.

In an exemplary implementation mode, the gate electrode 52 of the fifth transistor may be in a strip shape and extend along the first direction D1.

In an exemplary implementation mode, a length of the gate electrode 52 of the fifth transistor along the first direction D1 is smaller than a length of the first gate connection portion 32A along the first direction D1, and a boundary of a gate electrode 52 of a fifth transistor of a present column of sub-pixels close to a next column of sub-pixels is located between a boundary of the first gate connection portion 32A close to a previous column of sub-pixels and a boundary of the first gate connection portion 32A close to a next column of sub-pixels.

In an exemplary implementation mode, the two first branch segments 12B of the gate electrode 12 of the first transistor are disposed across an active pattern of the first transistor, the two second branch segments 22B of the gate electrode 22 of the second transistor are disposed across an active pattern of the second transistor, the gate electrode 32 of the third transistor (also the first electrode plate C1 of the capacitor) is disposed across an active pattern of the third transistor, a third branch segment 42B of the gate electrode 42 of the fourth transistor is disposed across an active pattern of the fourth transistor, and the gate electrode 52 of the fifth transistor is disposed across an active pattern of the fifth transistor, that is to say, an extension direction of a gate electrode of at least one transistor is perpendicular to an extension direction of an active pattern.

In an exemplary implementation mode, the two first branch segments 12B of the gate electrode 12 of the first transistor are disposed across the active pattern of the first transistor, i.e., the first transistor is of a double-gate structure, structurally speaking, it is equivalent to that one sub-pixel includes two first transistors in series.

In an exemplary implementation mode, the two second branch segments 22B of the gate electrode 22 of the second transistor are disposed across the active pattern of the second transistor, i.e., the second transistor is of a double-gate structure, structurally speaking, it is equivalent to that one sub-pixel includes two second transistors in series.

In an exemplary implementation mode, the two third branch segments 42B of the gate electrode 42 of the fourth transistor are disposed across the active pattern of the fourth transistor, i.e., the fourth transistor is of a double-gate structure, structurally speaking, it is equivalent to that one sub-pixel includes two fourth transistors in series.

In an exemplary implementation mode, after the pattern of the first conductive layer is formed, a conductorization processing may be performed on the semiconductor layer by using the pattern of the first conductive layer as a shield, the semiconductor layer in a region shielded by the first conductive layer forms channel regions of the first transistor T1 to the fifth transistor T5, and the semiconductor layer in a region not shielded by the first conductive layer is conductorized, that is, first regions and second regions of the active pattern of the first transistor to the active pattern of the fifth transistor are all conductorized. A first region of the active pattern of the third transistor (also a second region of the active pattern of the fifth transistor) after conductorization may be used as a first electrode 33 of the third transistor, and a second electrode 54 of the fifth transistor.

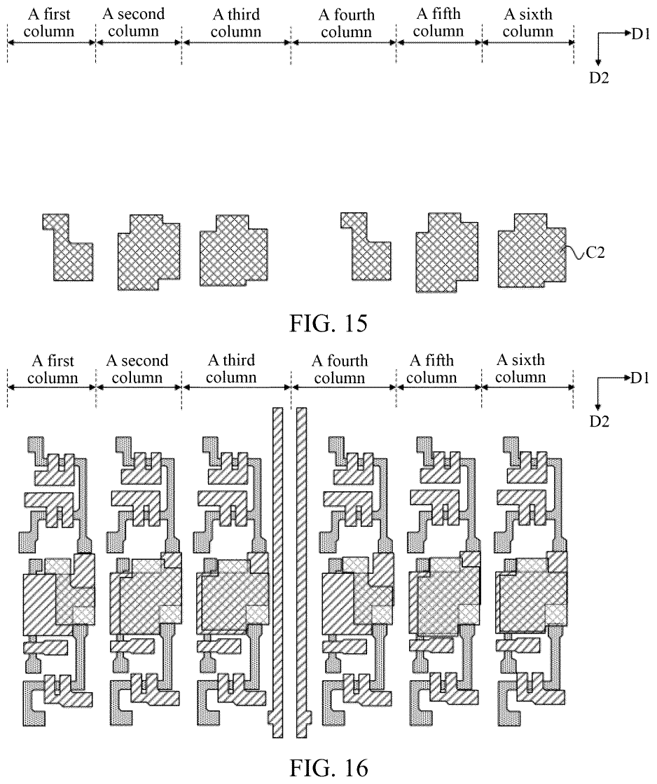

(3) A pattern of a second conductive layer is formed. In an exemplary implementation mode, forming the pattern of the second conductive layer may include: sequentially depositing a third insulation thin film and a second conductive thin film on the base substrate on which the aforementioned patterns are formed, and patterning the second conductive thin film through a patterning process to form a third insulation layer that covers the pattern of the first conductive layer and a pattern of a second conductive layer disposed on the third insulation layer, as shown in FIG. 15 and FIG. 16, wherein FIG. 15 is a schematic diagram of the pattern of the second conductive layer in FIGS. 7A and 7B, and FIG. 16 is a schematic diagram after the pattern of the second conductive layer is formed in FIGS. 7A and 7B. In an exemplary implementation mode, the second conductive layer may be referred to as a second gate metal (GATE2) layer.

In an exemplary implementation mode, as shown in FIGS. 15 and 16, the pattern of the second conductive layer may at least include a second electrode plate C2 of a capacitor located in each sub-pixel.

In an exemplary implementation mode, a shape of a main body portion of the second electrode plate C2 of the capacitor is a rectangle. The second electrode plate C2 of the capacitor of at least one sub-pixel may further include at least one protrusion.

In an exemplary implementation mode, an orthographic projection of the second electrode plate C2 of the capacitor on the base substrate is at least partially overlapped with an orthographic projection of the gate electrode of the third transistor (also a first electrode plate of the capacitor) on the base substrate.

In an exemplary implementation mode, for any sub-pixel, a line where a boundary of a second electrode C2 of a capacitor of a present column of sub-pixels close to a next column of sub-pixels is located coincides with a line where a boundary of the second gate connection portion close to the next column of sub-pixels is located.

In an exemplary implementation mode, for any sub-pixel, a distance between an orthographic projection of the second electrode plate C2 of the capacitor on the base substrate and an orthographic projection of the active pattern of the first transistor on the base substrate is smaller than a distance between an orthographic projection of the second gate connection portion on the base substrate and the orthographic projection of the active pattern of the first transistor on the base substrate.

In an exemplary implementation mode, shapes and areas of second electrode plates of capacitors located in a same column of sub-pixels are the same.

In an exemplary implementation mode, shapes and areas of second electrode plates C2 of capacitors of a (3k+1)-th column of sub-pixels are the same, wherein 0≤k<N/3, and N is a total number of columns of sub-pixels.

In an exemplary implementation mode, shapes and areas of second electrode plates C2 of capacitors of a (3k+2)-th column of sub-pixels are the same.

In an exemplary implementation mode, shapes and areas of second electrode plates C2 of capacitors of a (3k+3)-th column of sub-pixels are the same.

In an exemplary implementation mode, an area of a second electrode plate C2 of a capacitor of the (3k+1)-th column of sub-pixels is smaller than any of an area of a second electrode plate C2 of a capacitor of the (3k+2)-th column of sub-pixels and an area of a second electrode plate C2 of a capacitor of the (3k+3)-th column of sub-pixels.

In an exemplary implementation mode, a length of the second electrode plate C2 of the capacitor of the (3k+2)-th column of sub-pixels along the first direction D1 is smaller than a length of the second electrode plate C2 of the capacitor of the (3k+3)-th column of sub-pixels along the first direction D1, and a length of the second electrode plate C2 of the capacitor of the (3k+2)-th column of sub-pixels along the second direction D2 is larger than a length of the second electrode plate C2 of the capacitor of the (3k+3)-th column of sub-pixels along the second direction D2.

In an exemplary implementation mode, an area of an overlapping region between the second electrode plate C2 of the capacitor and a first electrode plate of the capacitor of the (3k+1)-th column of sub-pixels is smaller than an area of an overlapping region between the second electrode plate C2 of the capacitor and a first electrode plate of the capacitor of the (3k+2)-th column sub-pixels, and the area of the overlapping region between the second electrode plate C2 of the capacitor and the first electrode plate of the capacitor of the (3k+2)-th column of sub-pixels is smaller than an area of an overlapping region between the second electrode plate C2 of the capacitor and a first electrode plate of the capacitor of the (3k+3)-th column of sub-pixels.

In an exemplary implementation mode, an area of an overlapping region between the second electrode plate C2 of the capacitor and a first gate connection portion of the (3k+1)-th column of sub-pixels is smaller than an area of an overlapping region between the second electrode plate C2 of the capacitor and a first gate connection portion of the (3k+2)-th column of sub-pixels, and the area of the overlapping region between the second electrode plate C2 of the capacitor and the first gate connection portion of the (3k+2)-th column of sub-pixels is smaller than an area of an overlapping region between the second electrode plate C2 of the capacitor and a first gate connection portion of the (3k+3)-th column of sub-pixels.

In an exemplary implementation mode, an area of an overlapping region between the second electrode plate C2 of the capacitor and a second gate connection portion of the (3k+1)-th column of sub-pixels is smaller than an area of an overlapping region between the second electrode plate C2 of the capacitor and a second gate connection portion of the (3k+2)-th column of sub-pixels, and an area of an overlapping region between the second electrode plate C2 of the capacitor and a second gate connection portion of the (3k+3)-th column of sub-pixels is smaller than the area of the overlapping region between the second electrode plate C2 of the capacitor and the second gate connection portion of the (3k+2)-th column of sub-pixels.

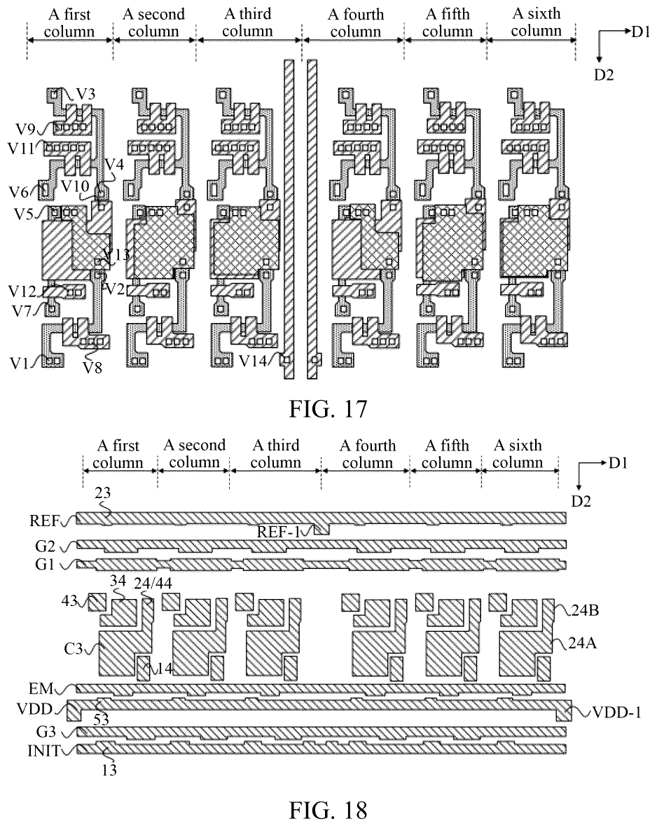

(4) A pattern of a fourth insulation layer is formed. In an exemplary implementation mode, forming the pattern of the fourth insulation layer may include: depositing a fourth insulation thin film on the base substrate on which the aforementioned patterns are formed, and patterning the fourth insulation thin film by using a patterning process, to form a pattern of a fourth insulation layer covering the pattern of the second conductive layer, wherein a plurality of vias are disposed on the pattern of the fourth insulation layer, as shown in FIG. 17, and FIG. 17 is a schematic diagram after the pattern of the fourth insulation layer is formed in FIG. 7A and FIG. 7B.

In an exemplary implementation mode, as shown in FIG. 17, the pattern of the fourth insulation layer may at least include: a ninth via V9 to a twenty-first via V21 located in each sub-pixel and a twenty-second via V22 located between at least two columns of adjacent sub-pixels.

In an exemplary implementation mode, an orthographic projection of the ninth via V9 on the base substrate is within a range of an orthographic projection of a first region of the active pattern of the first transistor on the base substrate, the second insulation layer and the third insulation layer within the ninth via V9 are etched away to expose a surface of the first region of the active pattern of the first transistor, and the ninth via V9 is configured such that an initial signal line subsequently formed is connected with the first region of the active pattern of the first transistor through the via.

In an exemplary implementation mode, an orthographic projection of the tenth via V10 on the base substrate is located within a range of an orthographic projection of a second region of the active pattern of the first transistor on the base substrate, the second insulation layer and the third insulation layer within the tenth via V10 are etched away to expose a surface of the second region of the active pattern of the first transistor, and the tenth via V10 is configured such that a second electrode of the first transistor formed subsequently is connected with the second region of the active pattern of the first transistor through the via.

In an exemplary implementation mode, an orthographic projection of the eleventh via V11 on the base substrate is within a range of an orthographic projection of a first region of the active pattern of the second transistor on the base substrate, the second insulation layer and the third insulation layer within the eleventh via V11 are etched away to expose a surface of the first region of the active pattern of the second transistor, and the eleventh via V11 is configured such that a reference signal line subsequently formed is connected with the first region of the active pattern of the second transistor through the via.

In an exemplary implementation mode, an orthographic projection of the twelfth via V12 on the base substrate is within a range of an orthographic projection of a second region of the active pattern of the second transistor (also a second region of the active pattern of the fourth transistor) on the base substrate, the second insulation layer and the third insulation layer within the twelfth via V12 are etched away to expose a surface of the second region of the active pattern of the second transistor (also the second region of the active pattern of the fourth transistor), and the twelfth via V12 is configured such that a second electrode of the second transistor (also a second electrode of the fourth transistor and a third electrode plate of the capacitor) formed subsequently is connected with the second region of the active pattern of the second transistor (also the second region of the active pattern of the fourth transistor) through the via.

In an exemplary implementation mode, an orthographic projection of the thirteenth via V13 on the base substrate is within a range of an orthographic projection of a second region of the active pattern of the third transistor on the base substrate, the second insulation layer and the third insulation layer within the thirteenth via V13 are etched away to expose a surface of the second region of the active pattern of the third transistor, and the thirteenth via V13 is configured such that a second electrode of the third transistor formed subsequently is connected with the second region of the active pattern of the third transistor through the via.

In an exemplary implementation mode, an orthographic projection of the fourteenth via V14 on the base substrate is within a range of an orthographic projection of a first region of the active pattern of the fourth transistor on the base substrate, the second insulation layer and the third insulation layer within the fourteenth via V14 are etched away to expose a surface of the first region of the active pattern of the fourth transistor, and the fourteenth via V14 is configured such that a first electrode of the fourth transistor formed subsequently is connected with the first region of the active pattern of the fourth transistor through the via.

In an exemplary implementation mode, an orthographic projection of the fifteenth via V15 on the base substrate is within a range of an orthographic projection of a first region of the active pattern of the fifth transistor on the base substrate, the second insulation layer and the third insulation layer within the fifteenth via V15 are etched away to expose a surface of the first region of the active pattern of the fifth transistor, and the fifteenth via V15 is configured such that a light emitting signal line subsequently formed is connected with the first region of the active pattern of the fifth transistor through the via.

In an exemplary implementation mode, an orthographic projection of the sixteenth via V16 on the base substrate is within a range of an orthographic projection of a gate electrode of the first transistor on the base substrate, the third insulation layer within the sixteenth via V16 is etched away to expose a surface of the gate electrode of the first transistor, and the sixteenth via V16 is configured such that a third scan signal line subsequently formed is connected with the gate electrode of the first transistor through the via. Exemplarily, the sixteenth via V16 exposes a surface of a first connection segment of the gate electrode of the first transistor.

In an exemplary implementation mode, an orthographic projection of the seventeenth via V17 on the base substrate is within a range of an orthographic projection of a gate electrode of the second transistor on the base substrate, the third insulation layer within the seventeenth via V17 is etched away to expose a surface of the gate electrode of the second transistor, and the seventeenth via V17 is configured such that a second scan signal line subsequently formed is connected with the gate electrode of the second transistor through the via. Exemplarily, the seventeenth via V17 exposes a surface of a second connection segment of the gate electrode of the second transistor.

In an exemplary implementation mode, an orthographic projection of the eighteenth via V18 on the base substrate is within a range of an orthographic projection of a gate electrode of the third transistor (also the first electrode plate of the capacitor) on the base substrate, the third insulation layer within the eighteenth via V18 is etched away to expose a surface of the gate electrode of the third transistor (also the first electrode plate of the capacitor), and the eighteenth via V18 is configured such that a second electrode of the second transistor (also a second electrode of the fourth transistor) formed subsequently is connected with the gate electrode of the third transistor (also the first electrode plate of the capacitor) through the via.

In an exemplary implementation mode, an orthographic projection of the nineteenth via V19 on the base substrate is within a range of an orthographic projection of a gate electrode of the fourth transistor on the base substrate, the third insulation layer within the nineteenth via V19 is etched away to expose a surface of the gate electrode of the fourth transistor, and the nineteenth via V19 is configured such that a first scan signal line subsequently formed is connected with the gate electrode of the fourth transistor through the via. Exemplarily, the nineteenth via V19 exposes a surface of a third connection segment of the gate electrode of the fourth transistor.

In an exemplary implementation mode, an orthographic projection of the twentieth via V20 on the base substrate is within a range of an orthographic projection of a gate electrode of the fifth transistor on the base substrate, the third insulation layer within the twentieth via V20 is etched away to expose a surface of the gate electrode of the fifth transistor, and the twentieth via V20 is configured such that a light emitting signal line subsequently formed is connected with the gate electrode of the fifth transistor through the via.

In an exemplary implementation mode, an orthographic projection of the twenty-first via V21 on the base substrate is within a range of an orthographic projection of a second electrode plate of the capacitor on the base substrate, the twenty-first via V21 exposes a surface of the second electrode plate of the capacitor, and the twenty-first via V21 is configured such that a second electrode of the third transistor and a second electrode of the first transistor formed subsequently are connected with the second electrode plate of the capacitor through the via.

In an exemplary implementation mode, an orthographic projection of the twenty-second via V22 on the base substrate is within a range of an orthographic projection of an initial connection line on the base substrate, the third insulation layer within the twenty-second via V22 is etched away to expose a surface of the initial connection line, and the twenty-second via V22 is configured such that an initial signal line subsequently formed is connected with the initial connection line through the via.

In an exemplary implementation mode, one dummy straight line extending along the first direction D1 passes through the ninth via V9 and the twenty-second via V22. One dummy straight line extending along the first direction D1 passes through the thirteenth via V13 and another portion of the twenty-first via V21. One dummy straight line extending along the first direction D1 passes through the twelfth via V12 and the fourteenth via V14.

In an exemplary implementation mode, one dummy straight line extending along the second direction D2 passes through the tenth via V10 and another portion of the twenty-first via V21. One dummy straight line extending along the second direction D2 passes through the twelfth via V12 and the eighteenth via V18. One dummy straight line extending along the second direction D2 passes through the eleventh via V11, the thirteenth via V13, and the fifteenth via V15.

In an exemplary implementation mode, in each sub-pixel, a quantity of ninth vias V9 may be at least one, and when the quantity of ninth vias V9 is plural, a plurality of ninth vias V9 are arranged along the first direction D1.

In an exemplary implementation mode, in each sub-pixel, a quantity of any of tenth vias V10, eleventh vias V11, twelfth vias V12, thirteenth vias V13, fourteenth vias V14, fifteenth vias V15, and eighteenth vias V18 may be one.

In an exemplary implementation mode, in each sub-pixel, a quantity of sixteenth vias V16 may be plural, and a plurality of sixteenth vias V16 are arranged along the first direction D1.

In an exemplary implementation mode, in each sub-pixel, a quantity of seventeenth via V17 may be plural, and a plurality of seventeenth vias V17 are arranged along the first direction D1.

In an exemplary implementation mode, in each sub-pixel, a quantity of nineteenth vias V19 may be plural, and a plurality of nineteenth vias V19 are arranged along the first direction D1.

In an exemplary implementation mode, in each sub-pixel, a quantity of twentieth vias V20 may be plural, and a plurality of twentieth vias V20 are arranged along the first direction D1.

In an exemplary implementation mode, a quantity of twenty-first vias V21 may be plural, at least one portion of twenty-first vias V21 in a present row of sub-pixels are arranged along the first direction D1, and are located at a boundary of the second electrode plate of the capacitor close to a previous row of sub-pixels, and the other portion of the twenty-first vias V21 in the present row of sub-pixels are located at a boundary of the second electrode plate of the capacitor close to a next row of sub-pixels.

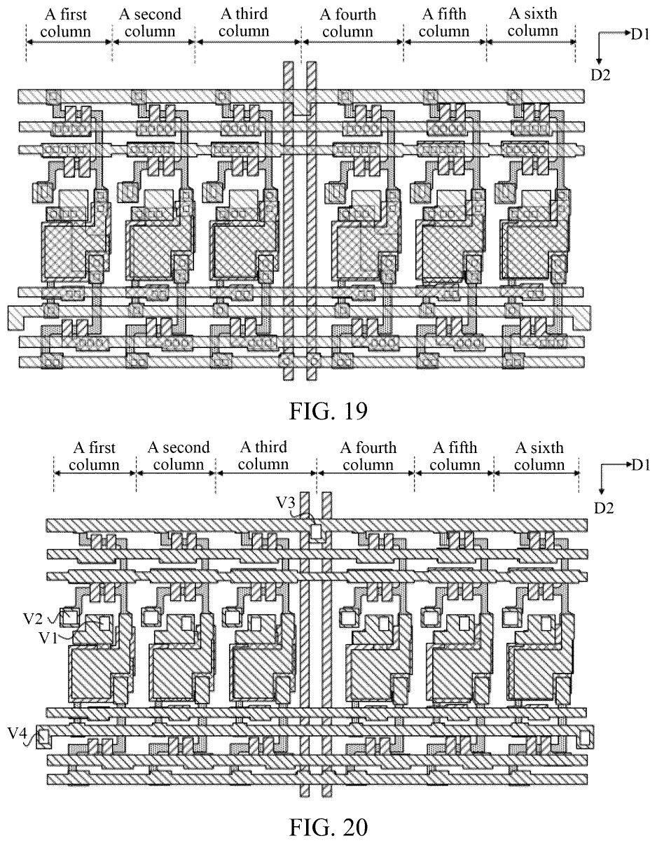

(5) A pattern of a third conductive layer is formed. In an exemplary implementation mode, forming the pattern of the third conductive layer may include: depositing a third conductive thin film on the base substrate on which the aforementioned patterns are formed, and patterning the third conductive thin film by using a patterning process to form the pattern of the third conductive layer on the fourth insulation layer, as shown in FIGS. 18 and 19, wherein FIG. 18 is a schematic diagram of a pattern of a third conductive layer in FIGS. 7A and 7B, and FIG. 19 is a schematic diagram after the pattern of the third conductive layer is formed in FIGS. 7A and 7B. In an exemplary implementation mode, the third conductive layer may be referred to as a first source-drain metal (SD1) layer.

In an exemplary implementation mode, as shown in FIGS. 18 and 19, the pattern of the third conductive layer may at least include: a first electrode 13 and a second electrode 14 of a first transistor, a first electrode 23 and a second electrode 24 of a second transistor, a second electrode 34 of a third transistor, a first electrode 43 and a second electrode 44 of a fourth transistor, a first electrode 53 of a fifth transistor, a third electrode plate C3 of the capacitor, a first scan signal line G1, a second scan signal line G2, a third scan signal line G3, a reference signal line REF, a light emitting signal line EM, a first power supply line VDD, and an initial signal line INIT which are located in each sub-pixel.

In an exemplary implementation mode, a shape of the reference signal line REF may be a line shape in which a main body portion extends along the first direction D1, and a reference signal line REF with which a present row of sub-pixels are connected may be located on a side of a third electrode plate C3 of a capacitor of a present sub-pixel close to a previous row of sub-pixels. Each reference signal line REF is provided with a first connection block REF-1, a first end of the first connection block REF-1 is connected with the reference signal line REF, the first connection block REF-1 is located on a side of the reference signal line REF close to the third electrode plate C3 of the capacitor and extends along the second direction D2, and an orthographic projection of at least a portion of the first connection block REF-1 on the base substrate is located between orthographic projections of two first signal lines on the base substrate. A region where the reference signal line REF is overlapped with an active pattern of the second transistor may serve as the first electrode 23 of the second transistor, and the reference signal line REF is electrically connected with a first region of the active pattern of the second transistor through a third via.

In an exemplary implementation mode, a shape of the second scan signal line G2 may be a line shape in which a main body portion extends along the first direction D1, and a second scan signal line G2 with which the present row of sub-pixels are connected may be located between the third electrode plate C3 of the capacitor of the present sub-pixel and the reference signal line REF with which the present row of sub-pixels are connected. An orthographic projection of the second scan signal line G2 on the base substrate is at least partially overlapped with an orthographic projection of a second connection segment of a gate electrode of the second transistor on the base substrate, and the second scan signal line G2 is electrically connected with the gate electrode of the second transistor through a seventeenth via.

In an exemplary implementation mode, a shape of the first scan signal line G1 may be a line shape in which a main body portion extends along the first direction D1, and a first scan signal line G1 with which the present row of sub-pixels are connected may be located between the third electrode plate C3 of the capacitor of the present sub-pixel and the second scan signal line G2 with which the present row of sub-pixels are connected. An orthographic projection of the first scan signal line G1 on the base substrate is at least partially overlapped with an orthographic projection of a third connection segment of a gate electrode of the fourth transistor on the base substrate, and the first scan signal line G1 is electrically connected with the gate electrode of the fourth transistor through a nineteenth via.

In an exemplary implementation mode, a shape of the light emitting signal line EM may be a line shape in which a main body portion extends along the first direction D1, and a light emitting signal line EM with which the present row of sub-pixels are connected may be located on a side of the third electrode plate C3 of the capacitor of the present sub-pixel away from the first scan signal line G1 with which the present row of sub-pixels are connected. An orthographic projection of the light emitting signal line EM on the base substrate is at least partially overlapped with an orthographic projection of a gate electrode of the fifth transistor on the base substrate, and the light emitting signal line EM is electrically connected with the gate electrode of the fifth transistor through a twentieth via.

In an exemplary implementation mode, a shape of the first power supply line VDD may be a line shape in which a main body portion extends along the first direction D1, and a first power supply line VDD with which the present row of sub-pixels are connected may be located on a side of the light emitting signal line EM with which the present sub-pixel is connected away from the third electrode plate C3 of the capacitor. Each first power supply line VDD is provided with a second connection block VDD-1, a first end of the second connection block VDD-1 is connected with the first power supply line VDD, the second connection block VDD-1 is located on a side of the first power supply line VDD away from the third electrode plate C3 of the capacitor and extends along the second direction D2. A region where the first power supply line VDD is overlapped with an active pattern of the fifth transistor may serve as the first electrode 53 of the fifth transistor, and the first power supply line VDD is electrically connected with a first region of the active pattern of the fifth transistor through a fifteenth via.

In an exemplary implementation mode, a straight line extending along the second direction D2 where the second connection block VDD-1 is located and a straight line extending along the second direction D2 where the first connection line REF-1 is located are alternately disposed.

In an exemplary implementation mode, a shape of the third scan signal line G3 may be a line shape in which a main body portion extends along the first direction D1, and a third scan signal line G3 with which the present row of sub-pixels are connected may be located on a side of the first power supply line VDD with which the present sub-pixel is connected away from the third electrode plate C3 of the capacitor of the present row of sub-pixels. An orthographic projection of the third scan signal line G3 on the base substrate is at least partially overlapped with an orthographic projection of a first connection segment of a gate electrode of the first transistor on the base substrate, and the third scan signal line G3 is electrically connected with the gate electrode of the first transistor through a sixteenth via.

In an exemplary implementation mode, a shape of the initial signal line INIT may be a line shape in which a main body portion extends along the first direction D1, and an initial signal line INIT with which the present row of sub-pixels are connected may be located on a side of the third scan signal line G3 with which the present row of sub-pixels are connected away from the first power supply line VDD with which the present row of sub-pixels are connected. A region where the initial signal line INIT is overlapped with an active pattern of the first transistor may serve as the first electrode 13 of the first transistor. The initial signal line INIT is electrically connected with a first region of the active pattern of the first transistor through a ninth via and is connected with a first signal line through a twenty-second via.

In an exemplary implementation mode, the second electrode 24 of the second transistor, the second electrode 44 of the fourth transistor, and the third electrode C3 of the capacitor are of an interconnected integral structure, and the second electrode 14 of the first transistor, the second electrode 34 of the third transistor, and the first electrode 43 of the fourth transistor may be separately disposed.

In an exemplary implementation mode, an orthographic projection of the integral structure of the second electrode 24 of the second transistor, the second electrode 44 of the fourth transistor, and the third electrode plate C3 of the capacitor on the base substrate is at least partially overlapped with an orthographic projection of a first electrode plate of the capacitor on the base substrate and an orthographic projection of a second electrode plate of the capacitor on the base substrate, respectively. There is a non-overlapping region between the orthographic projection of the integral structure of the second electrode 24 of the second transistor, the second electrode 44 of the fourth transistor, and the third electrode plate C3 of the capacitor on the base substrate and the orthographic projection of the first electrode plate of the capacitor on the base substrate, and there is a non-overlapping region between the orthographic projection of the integral structure of the second electrode 24 of the second transistor, the second electrode 44 of the fourth transistor, and the third electrode plate C3 of the capacitor on the base substrate and the orthographic projection of the second electrode plate of the capacitor on the base substrate.

In an exemplary implementation mode, the integral structure of the second electrode 24 of the second transistor, the second electrode 44 of the fourth transistor, and the third electrode plate C3 of the capacitor includes a first electrode connection portion 24A and a second electrode connection portion 24B, wherein the second electrode connection portion 24B is located on a side of the first electrode connection portion 24A close to the first scan signal line G1 and is disposed at right angles to the first electrode connection portion 24A. The second electrode connection portion 24B may be in a strip shape and extend along the second direction D2, and a shape of the first electrode connection portion 24A may be “┌”, wherein a width of an extension portion of the first electrode connection portion 24A along the second direction D2 is larger than a width of an extension portion of the first electrode connection portion 24A along the first direction D1. The second electrode 24 of the second transistor (also the second electrode 44 of the fourth transistor and the third electrode plate C3 of the capacitor) is connected with the second region of the active pattern of the second transistor (also the second region of the active pattern of the fourth transistor) through a twelfth via, and is connected with the gate electrode of the third transistor (also the first electrode plate of the capacitor) through an eighteenth via.

In the exemplary implementation mode, the second electrode 14 of the first transistor is located on a side of the first electrode connection portion 24A close to the light emitting signal line EM, and is arranged along the second direction D2 with the second electrode connection portion 24B. The second electrode 14 of the first transistor may be in a strip shape and extend along the second direction D2. The second electrode 14 of the first transistor is connected with the second region of the active pattern of the first transistor through a tenth via, and is electrically connected with the second electrode plate of the capacitor through a twenty-first via.

In an exemplary implementation mode, a length of the second electrode 14 of the first transistor along the first direction D1 is larger than a length of the second electrode connection portion 24B along the first direction D1.

In an exemplary implementation mode, the second electrode 34 of the third transistor is located on a side of the first electrode connection portion 24A close to the first scan signal line G1, and a second electrode 34 of a third transistor of a present column of sub-pixels is located on a side of a second electrode connection portion 24B of the present row of sub-pixels close to a previous column of sub-pixels; and the second electrode 34 of the third transistor and the second electrode connection portion 24B are arranged along the first direction D1. A shape of the second electrode 34 of the third transistor may be in a shape of “┘”, and a width of an extension portion of the second electrode 34 of the third transistor along the second direction D2 is larger than a width of an extension portion of the second electrode 34 of the third transistor along the first direction D1. The second electrode 34 of the third transistor is connected with the second region of the active pattern of the third transistor through a thirteenth via, and is electrically connected with the second electrode plate of the capacitor through a twenty-first via.

In an exemplary implementation mode, the first electrode 43 of the fourth transistor is located between the second electrode 34 of the third transistor and the first scan signal line G1, and is located on a side of the second electrode 34 of the third transistor away from the second electrode connection portion 24B. A shape of the first electrode 43 of the fourth transistor may be a block shape. The first electrode 43 of the fourth transistor is connected with the first region of the active pattern of the fourth transistor through a fourteenth via.

In an exemplary implementation mode, the first scan signal line G1, the second scan signal line G2, the third scan signal line G3, the reference signal line REF, the light emitting signal line EM, the first power supply line VDD, and the initial signal line INIT may be designed with equal width or may be designed with unequal width, may be straight lines or may be polygonal lines, which may not only facilitate a layout of a pixel structure, but also reduce a parasitic capacitance between signal lines, and the present disclosure is not limited here.

(6) A pattern of a first planarization layer is formed. In an exemplary implementation mode, forming the pattern of the first planarization layer may include: coating a first planarization thin film on the base substrate on which the above-mentioned patterns are formed, patterning the first planarization thin film by using a patterning process to form a pattern of a first planarization layer covering the pattern of the third conductive layer, and the pattern of the first planarization layer is provided with a plurality of vias, as shown in FIG. 20, wherein FIG. 20 is a schematic diagram after a pattern of a first planarization layer is formed in FIGS. 7A and 7B.

In an exemplary implementation mode, as shown in FIG. 20, the plurality of vias of the pattern of the first planarization layer at least include a first via V1 and a second via V2 located in each sub-pixel, and a third via V3 and a fourth via V4 located between at least two columns of adjacent sub-pixels.

In an exemplary implementation mode, an orthographic projection of the first via V1 on the base substrate is within a range of an orthographic projection of the second electrode of the third transistor on the base substrate, the first via V1 exposes a surface of the second electrode of the third transistor, and the first via V1 is configured such that an anode connection electrode formed subsequently is connected with the second electrode of the third transistor through the via.

In an exemplary implementation mode, an orthographic projection of the first via V1 on the base substrate is not overlapped with orthographic projections of the fifth via and the thirteenth via on the base substrate, and an area of the first via V1 is larger than an area of any of the fifth via and the thirteenth via.

In an exemplary implementation mode, an orthographic projection of the second via V2 on the base substrate is within a range of an orthographic projection of the first electrode of the fourth transistor on the base substrate, the second via V2 exposes a surface of the first electrode of the fourth transistor, and the second via V2 is configured such that a data signal line Data formed subsequently is connected with the first electrode of the fourth transistor through the via.

In an exemplary implementation mode, the orthographic projection of the second via V2 on the base substrate is at least partially overlapped with an orthographic projection of the sixth via V6 on the base substrate.

In an exemplary implementation mode, an orthographic projection of the third via V3 on the base substrate is within a range of an orthographic projection of the reference signal line on the base substrate, the third via V3 exposes a surface of the reference signal line, and the third via V3 is configured such that a third connection line formed subsequently is connected with the reference signal line through the via. Exemplarily, the third via V3 exposes a first connection block of the reference signal line.

In an exemplary implementation mode, an orthographic projection of the fourth via V4 on the base substrate is within a range of an orthographic projection of the first power supply line on the base substrate, the fourth via V4 exposes a surface of the first power supply line, and the fourth via V4 is configured such that a second connection line formed subsequently is connected with the first power supply line through the via. Exemplarily, the fourth via V4 exposes a second connection block of the first power supply line.

In an exemplary implementation mode, an area of the seventeenth via may be equal to an area of the eighteenth via, and the seventeenth via is located on a centerline of two adjacent eighteenth vias extending along the first direction D1.

In an exemplary implementation mode, a quantity of any of first vias V1 to fourth vias V4 may be one.

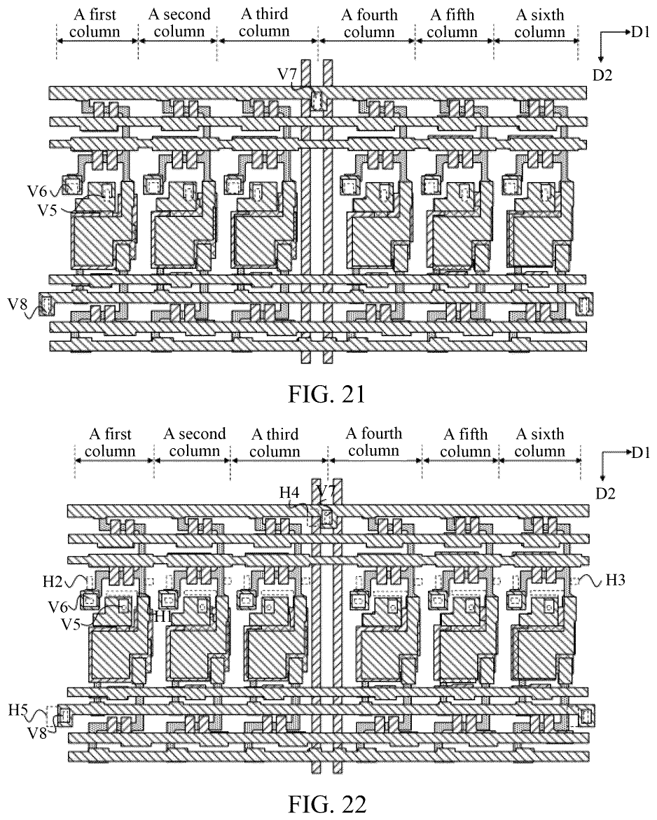

(7) A pattern of a fifth insulation layer is formed. In an exemplary implementation mode, forming the pattern of the fifth insulation layer may include: depositing a fifth insulation thin film on the base substrate on which the aforementioned patterns are formed, patterning the fifth insulation thin film by using a patterning process to form the pattern of the fifth insulation layer covering the pattern of the first planarization layer, wherein the fifth insulation layer is provided with a plurality of vias, as shown in FIGS. 21 and 22, FIG. 21 is a schematic diagram after a pattern of a fifth insulation layer is formed in FIG. 7A, and FIG. 22 is a schematic diagram after a pattern of a fifth insulation layer is formed in FIG. 7B.

In an exemplary implementation mode, as shown in FIGS. 21 and 22, the plurality of vias of the pattern of the fifth insulation layer at least include a fifth via V5 and a sixth via V6 located in each sub-pixel, and a seventh via V7 and an eighth via V8 located between at least two columns of adjacent sub-pixels.

In an exemplary implementation mode, as shown in FIGS. 21 and 22, a quantity of any of fifth vias V5 and sixth vias V6 in each sub-pixel is one.

In an exemplary implementation mode, as shown in FIGS. 21 and 22, an orthographic projection of the fifth via V5 on the base substrate is within a range of an orthographic projection of the second electrode of the third transistor on the base substrate, the fifth via V5 exposes a surface of the second electrode of the third transistor, and the fifth via V5 is configured such that an anode connection electrode formed subsequently is connected with the second electrode of the third transistor through the via.

In an exemplary implementation mode, as shown in FIG. 21, the orthographic projection of the fifth via V5 on the base substrate is not overlapped orthographic projections of the fifth via and the twenty-first via on the base substrate.

In an exemplary implementation mode, as shown in FIG. 21, an orthographic projection of one portion of the fifth via V5 on the base substrate is within a range of an orthographic projection of the first via on the base substrate, and an orthographic projection of the other portion of the fifth via V5 on the base substrate is within a range of an orthographic projection of the first planarization layer on the base substrate, i.e., the fifth via V5 exposes the second electrode of the third transistor, and may also expose the first planarization layer.

In an exemplary implementation mode, as shown in FIG. 21, a length of the fifth via V5 along the first direction D1 is less than a length of the first via along the first direction D1, and a length of the fifth via V5 along the second direction D2 is less than a length of the first via along the second direction D2.

In an exemplary implementation mode, as shown in FIG. 21, boundaries of a via include a first boundary, a second boundary, a third boundary, and a fourth boundary, wherein the first boundary of the via is a boundary of the via close to a first signal line, the second boundary of the via is a boundary of the via away from the first signal line, the third boundary of the via is a boundary located on one side of a first centerline, and the fourth boundary of the via is a boundary located on the other side of the first centerline; the via includes a first via and a fifth via; the first signal line is one of a light emitting signal line, a first power supply line, a third scan signal line, and an initial signal line which are connected with a sub-pixel; the first centerline is a centerline of the first via extending along the second direction, a third boundary of the first via and a third boundary of the fifth via are located on a same side of the first centerline, and a fourth boundary of the first via and a fourth boundary of the fifth via are located on a same side of the first centerline. A distance between an orthographic projection of the first boundary of the first via on the base substrate and an orthographic projection of the first signal line on the base substrate is greater than a distance between an orthographic projection of the first boundary of the fifth via on the base substrate and the orthographic projection of the first signal line on the base substrate, a distance between an orthographic projection of the second boundary of the first via on the base substrate and the orthographic projection of the first signal line on the base substrate is greater than a distance between an orthographic projection of the second boundary of the fifth via on the base substrate and the orthographic projection of the first signal line on the base substrate, a distance between the third boundary of the first via and the first centerline is greater than a distance between an orthographic projection of the third boundary of the fifth via on the base substrate and an orthographic projection of the first centerline on the base substrate, and a distance between the fourth boundary of the first via and the first centerline is greater than a distance between an orthographic projection of the fourth boundary of the fifth via on the base substrate and the orthographic projection of the first centerline on the base substrate.

In an exemplary implementation mode, as shown in FIG. 21, within any sub-pixel, a distance between the orthographic projection of the first boundary of the first via on the base substrate and the orthographic projection of the first boundary of the fifth via on the base substrate is greater than a distance between the orthographic projection of the third boundary of the first via on the base substrate and the orthographic projection of the third boundary of the fifth via on the base substrate, and is less than a distance between the orthographic projection of the second boundary of the first via on the base substrate and the orthographic projection of the second boundary of the fifth via on the base substrate.

In an exemplary implementation mode, as shown in FIG. 21, the distance between the orthographic projection of the first boundary of the first via on the base substrate and the orthographic projection of the first boundary of the fifth via on the base substrate is about 1 micron to 2 microns. Exemplarily, the distance between the orthographic projection of the first boundary of the first via on the base substrate and the orthographic projection of the first boundary of the fifth via on the base substrate is about 1.5 microns.

In an exemplary implementation mode, as shown in FIG. 22, the orthographic projection of the fifth via V5 on the base substrate is within a range of the orthographic projection of the first via on the base substrate.

In an exemplary implementation mode, as shown in FIGS. 21 and 22, an orthographic projection of the sixth via V6 on the base substrate is within a range of an orthographic projection of the first electrode of the fourth transistor on the base substrate, the sixth via V6 exposes a surface of the first electrode of the fourth transistor, and the sixth via V6 is configured such that a data signal line formed subsequently is connected with the first electrode of the fourth transistor through the via.

In an exemplary implementation mode, as shown in FIG. 21, an orthographic projection of one portion of the sixth via V6 on the base substrate is within a range of orthographic projections of the sixth via and the second via on the base substrate, and an orthographic projection of the other portion of the sixth via V6 on the base substrate is within a range of the orthographic projection of the first planarization layer on the base substrate, i.e., the twentieth via exposes the first electrode of the fourth transistor, and also exposes the first planarization layer.

In an exemplary implementation mode, as shown in FIG. 21, a length of the sixth via V6 along the first direction D1 is less than a length of the second via along the first direction D1, and a length of the sixth via V6 along the second direction D2 is less than a length of the second via along the second direction D2.

In an exemplary implementation mode, as shown in FIG. 21, within any sub-pixel, boundaries of a via include a first boundary, a second boundary, a third boundary, and a fourth boundary, wherein the first boundary of the via is a boundary of the via close to a first signal line, the second boundary is a boundary of the via away from the first signal line, the third boundary of the via is a boundary located on one side of a second centerline, and the fourth boundary of the via is a boundary located on the other side of the second centerline; the via includes a second via and a sixth via; the first signal line is one signal line of a light emitting signal line, a first power supply line, a third scan signal line, and an initial signal line connected with the sub-pixel, the second centerline is a centerline of the second via extending along the second direction, a third boundary of the second via and a third boundary of the sixth via are located on a same side of the second centerline, and a fourth boundary of the second via and a fourth boundary of the sixth via are located on a same side of the second centerline; a distance between an orthographic projection of a first boundary of the second via on the base substrate and an orthographic projection of the first signal line on the base substrate is greater than a distance between an orthographic projection of a first boundary of the sixth via on the base substrate and the orthographic projection of the first signal line on the base substrate, a distance between an orthographic projection of a second boundary of the second via on the base substrate and the orthographic projection of the first signal line on the base substrate is greater than a distance between an orthographic projection of a second boundary of the sixth via on the base substrate and the orthographic projection of the first signal line on the base substrate, a distance between the third boundary of the second via and the second centerline is greater than a distance between an orthographic projection of the third boundary of the sixth via on the base substrate and an orthographic projection of the second centerline on the base substrate, and a distance between the fourth boundary of the second via and the second centerline is greater than a distance between an orthographic projection of the fourth boundary of the sixth via on the base substrate and the orthographic projection of the second centerline on the base substrate.

In an exemplary implementation mode, as shown in FIG. 21, within any sub-pixel, a distance between the orthographic projection of the first boundary of the second via on the base substrate and the orthographic projection of the first boundary of the sixth via on the base substrate is greater than a distance between the orthographic projection of the third boundary of the second via on the base substrate and the orthographic projection of the third boundary of the sixth via on the base substrate, and is less than a distance between the orthographic projection of the second boundary of the second via on the base substrate and the orthographic projection of the second boundary of the sixth via on the base substrate.

In an exemplary implementation mode, as shown in FIG. 21, the distance between the orthographic projection of the first boundary of the second via on the base substrate and the orthographic projection of the first boundary of the sixth via on the base substrate is about 1 micron to 2 microns. Exemplarily, the distance between the orthographic projection of the first boundary of the second via on the base substrate and the orthographic projection of the first boundary of the sixth via on the base substrate may be about 1.5 microns.

In an exemplary implementation mode, as shown in FIG. 22, an orthographic projection of the sixth via V6 on the base substrate is within a range of an orthographic projection of the second via on the base substrate.

In an exemplary implementation mode, as shown in FIG. 21, an orthographic projection of the seventh via V7 on the base substrate is within a range of an orthographic projection of the reference signal line on the base substrate, the seventh via V7 exposes a surface of the reference signal line, and the seventh via V7 is configured such that a third connection line formed subsequently is connected with the reference signal line through the via.

In an exemplary implementation mode, as shown in FIGS. 21 and 22, an orthographic projection of the twentieth via V21 on the base substrate is not overlapped with an orthographic projection of the first signal line on the base substrate.

In an exemplary implementation mode, as shown in FIG. 21, an orthographic projection of one portion of the seventh via V7 on the base substrate is within a range of an orthographic projection of the third via on the base substrate, and an orthographic projection of the other portion of the seventh via V7 on the base substrate is within a range of an orthographic projection of the first planarization layer on the base substrate, i.e., the seventh via V7 exposes the reference signal line, and also exposes the first planarization layer.

In an exemplary implementation mode, as shown in FIG. 21, a length of the seventh via V7 along the first direction D1 is less than a length of the third via along the first direction D1, and a length of the seventh via V7 along the second direction D2 is less than a length of the third via along the second direction D2.

In an exemplary implementation mode, as shown in FIG. 21, boundaries of a via include a first boundary, a second boundary, a third boundary, and a fourth boundary, wherein the first boundary of the via is a boundary of the via close to a second signal line, the second boundary is a boundary of the via away from the second signal line, the third boundary of the via is a boundary located on one side of a third centerline, and the fourth boundary of the via is a boundary located on the other side of the third centerline; the via includes a third via and a seventh via; the second signal line is one signal line of a light emitting signal line, a first power supply line, a first scan signal line, a second scan signal line, a third scan signal line, an initial signal line, and a light emitting signal line which are connected with a sub-pixel connected with a reference signal line exposed by the third via, the third centerline is a centerline of the third via extending along the second direction, a third boundary of the third via and a third boundary of the seventh via are located on a same side of the third centerline, and a fourth boundary of the third via and a fourth boundary of the seventh via are located on a same side of the third centerline; a distance between an orthographic projection of a first boundary of the third via on the base substrate and an orthographic projection of the second signal line on the base substrate is greater than a distance between an orthographic projection of a first boundary of the seventh via on the base substrate and the orthographic projection of the second signal line on the base substrate, a distance between an orthographic projection of a second boundary of the third via on the base substrate and the orthographic projection of the second signal line on the base substrate is greater than a distance between an orthographic projection of a second boundary of the seventh via on the base substrate and the orthographic projection of the second signal line on the base substrate, a distance between a third boundary of the third via and the third centerline is greater than a distance between an orthographic projection of a third boundary of the seventh via on the base substrate and an orthographic projection of the third centerline on the base substrate, and a distance between a fourth boundary of the third via and the third centerline is greater than a distance between an orthographic projection of a fourth boundary of the seventh via on the base substrate and the orthographic projection of the third centerline on the base substrate.

In an exemplary implementation mode, as shown in FIG. 21, a distance between the orthographic projection of the first boundary of the third via on the base substrate and the orthographic projection of the first boundary of the seventh via on the base substrate is greater than a distance between the orthographic projection of the third boundary of the third via on the base substrate and the orthographic projection of the third boundary of the seventh via on the base substrate, and is less than a distance between the orthographic projection of the second boundary of the third via on the base substrate and the orthographic projection of the second boundary of the seventh via on the base substrate.

In an exemplary implementation mode, as shown in FIG. 21, the distance between the orthographic projection of the first boundary of the third via on the base substrate and the orthographic projection of the first boundary of the seventh via on the base substrate is about 1 micron to 2 microns. Exemplarily, the distance between the orthographic projection of the first boundary of third via on the base substrate and the orthographic projection of the first boundary of the seventh via on the base substrate may be about 1.5 microns.

In an exemplary implementation mode, as shown in FIG. 22, an orthographic projection of the seventh via V7 on the base substrate is within a range of an orthographic projection of the third via on the base substrate.

In an exemplary implementation mode, as shown in FIGS. 21 and 22, an orthographic projection of the eighth via V8 on the base substrate is within a range of an orthographic projection of the first power supply line on the base substrate, the eighth via V8 exposes a surface of the first power supply line, and the eighth via V8 is configured such that a second signal line formed subsequently is connected with the first power supply line through the via.

In an exemplary implementation mode, as shown in FIG. 21, an orthographic projection of one portion of the eighth via V8 on the base substrate is within a range of an orthographic projection of the fourth via V4 on the base substrate, and an orthographic projection of the other portion of the eighth via V8 on the base substrate is within a range of an orthographic projection of the first planarization layer on the base substrate. The eighth via V8 exposes the first power supply line and may also expose the first planarization layer.

In an exemplary implementation mode, as shown in FIG. 21, a length of the eighth via V8 along the first direction D1 is less than a length of the fourth via along the first direction D1, and a length of the eighth via V8 along the second direction D2 is less than a length of the fourth via along the second direction D2.

In an exemplary implementation mode, as shown in FIG. 21, boundaries of a via include a first boundary, a second boundary, a third boundary, and a fourth boundary, wherein the first boundary of the via is a boundary of the via close to a third signal line, the second boundary is a boundary of the via away from the third signal line, the third boundary of the via is a boundary located on one side of a fourth centerline, and the fourth boundary of the via is a boundary located on the other side of the fourth centerline; the via includes a fourth via and an eighth via; the third signal line is any one signal line of a third scan signal line and an initial signal line which are connected with a sub-pixel connected with a first power supply line exposed by the fourth via, the fourth centerline is a centerline of the fourth via extending along the second direction, a third boundary of the fourth via and a third boundary of the eighth via are located on a same side of the fourth centerline, and a fourth boundary of the fourth via and a fourth boundary of the fourth via are located on a same side of the fourth centerline; a distance between an orthographic projection of a first boundary of the fourth via on the base substrate and an orthographic projection of the third signal line on the base substrate is greater than a distance between an orthographic projection of a first boundary of the eighth via on the base substrate and the orthographic projection of the third signal line on the base substrate, a distance between an orthographic projection of a second boundary of the fourth via on the base substrate and the orthographic projection of the third signal line on the base substrate is greater than a distance between an orthographic projection of a second boundary of the eighth via on the base substrate and the orthographic projection of the third signal line on the base substrate, a distance between the third boundary of the fourth via and the fourth centerline is greater than a distance between an orthographic projection of the third boundary of the eighth via on the base substrate and an orthographic projection of the fourth centerline on the base substrate, and a distance between the fourth boundary of the fourth via and the fourth centerline is greater than a distance between an orthographic projection of the fourth boundary of the eighth via on the base substrate and the orthographic projection of the fourth centerline on the base substrate.

In an exemplary implementation mode, as shown in FIG. 21, a distance between the orthographic projection of the first boundary of the fourth via on the base substrate and the orthographic projection of the first boundary of the eighth via on the base substrate is greater than a distance between the orthographic projection of the third boundary of the fourth via on the base substrate and the orthographic projection of the third boundary of the eighth via on the base substrate, and is less than a distance between the orthographic projection of the second boundary of the fourth via on the base substrate and the orthographic projection of the second boundary of the eighth via on the base substrate.

In an exemplary implementation mode, as shown in FIG. 21, the distance between the orthographic projection of the first boundary of the fourth via on the base substrate and the orthographic projection of the first boundary of the eighth via on the base substrate is about 1 micron to 2 microns. Exemplarily, the distance between the orthographic projection of the first boundary of the fourth via on the base substrate and the orthographic projection of the first boundary of the eighth via on the base substrate is about 1.5 microns.

In an exemplary implementation mode, as shown in FIG. 22, an orthographic projection of the eighth via V8 on the base substrate is within a range of an orthographic projection of the fourth via on the base substrate.

In an exemplary implementation mode, as shown in FIG. 22, the pattern of the fifth insulation layer in the display substrate provided in FIG. 8 may further include a first vent hole H1 to a third vent hole H3 located in least one sub-pixel, and a fourth vent hole H4 and a fifth vent hole H5 located between at least two columns of adjacent sub-pixels.

In an exemplary implementation mode, as shown in FIG. 22, an orthographic projection of any one of the first vent hole H1 to the fifth vent hole H5 on the base substrate is partially overlapped with an orthographic projection of the first planarization layer on the base substrate, i.e., any one of the first vent hole H1 to the fifth vent hole H5 exposes the first planarization layer.

In an exemplary implementation mode, as shown in FIG. 22, a distance between an orthographic projection of the first vent hole H1 on the base substrate and an orthographic projection of the fifth via on the base substrate is smaller than a distance between an orthographic projection of the first scan signal line on the base substrate and an orthographic projection of the fifth via on the base substrate. That is, the first vent hole H1 is disposed at a periphery of a sleeve hole including the fifth via and the first via.

In an exemplary implementation mode, as shown in FIG. 22, a shape of a cross section of the first vent hole H1 may be a polyline type. An orthographic projection of the first vent hole H1 on the base substrate is at least disposed surrounding at least one side of an orthographic projection of the first via on the base substrate.

In an exemplary implementation mode, as shown in FIG. 22, there is no overlapping region between the orthographic projection of the first vent hole H1 on the base substrate and orthographic projections of an active pattern, a gate electrode, a first electrode, and a second electrode of any transistor, and a reference signal line, a first scan signal line, a second scan signal line, a third scan signal line, an initial signal line, a first power supply line, a light emitting signal line, and an initial connection line on the base substrate.

In an exemplary implementation mode, as shown in FIG. 22, a length of the first vent hole H1 along the first direction D1 may be greater than a length of a boundary of the second electrode of the third transistor close to the first scan signal line, and a length of the first vent hole H1 along the second direction D2 may be greater than a length of the sixth via V6 along the second direction D2.

In an exemplary implementation mode, as shown in FIG. 22, the second vent hole H2 and the sixth via V6 are arranged along the second direction D2. A distance between an orthographic projection of the sixth via V6 on the base substrate and an orthographic projection of the first scan signal line on the base substrate is greater than a distance between the second vent hole H2 and the sixth via V6, that is, the second vent hole H2 is disposed at a periphery of a sleeve hole including the sixth via and the second via.

In an exemplary implementation mode, as shown in FIG. 22, a length of the second vent hole H2 along the second direction D2 is greater than a length of the sixth via V6 along the second direction D2, and a length of the second vent hole H2 along the first direction D1 is less than a length of the sixth via V6 along the first direction D1.

In an exemplary implementation mode, as shown in FIG. 22, there is no overlapping region between an orthographic projection of the second vent hole H2 on the base substrate and orthographic projections of an active pattern, a gate electrode, a first electrode, and a second electrode of any transistor, and a reference signal line, a first scan signal line, a second scan signal line, a third scan signal line, an initial signal line, a first power supply line, a light emitting signal line, and an initial connection line on the base substrate.

In an exemplary implementation mode, as shown in FIG. 22, an orthographic projection of the third vent hole H3 on the base substrate is located between the orthographic projection of the first scan signal line on the base substrate and an orthographic projection of the third electrode plate of the capacitor on the base substrate.

In an exemplary implementation mode, as shown in FIG. 22, there is no overlapping region between the orthographic projection of the third vent hole H3 on the base substrate and orthographic projections of an active pattern, a gate electrode, a first electrode, and a second electrode of any transistor, and a reference signal line, a first scan signal line, a second scan signal line, a third scan signal line, an initial signal line, a first power supply line, a light emitting signal line, and an initial connection line on the base substrate.

In an exemplary implementation mode, as shown in FIG. 22, in any sub-pixel, a quantity of any one of first vent holes H1 to third vent holes H3 may be one.

In an exemplary implementation mode, the display substrate includes a plurality of fourth vent holes H4 and a plurality of fifth vent holes H5.

In an exemplary implementation mode, as shown in FIG. 22, the fourth vent hole H4 and the seventh via V7 are arranged along the first direction D1. A distance between an orthographic projection of the fourth vent hole on the base substrate and an orthographic projection of a gate electrode of a first transistor of an adjacent sub-pixel on the base substrate is smaller than a distance between an orthographic projection of the seventh via on the base substrate and an orthographic projection of a gate electrode of a first transistor of an adjacent sub-pixel on the base substrate, that is, the fourth vent hole H4 is disposed at a periphery of a sleeve hole including the seventh via and the third via.

In an exemplary implementation mode, as shown in FIG. 22, the orthographic projection of the fourth vent hole H4 on the base substrate is at least partially overlapped with orthographic projections of the initial connection line and the reference signal line on the base substrate and there is no overlapping region between the orthographic projection of the fourth vent hole H4 on the base substrate and orthographic projections of an active pattern, a gate electrode, a first electrode, and a second electrode of any transistor, and a first scan signal line, a second scan signal line, a third scan signal line, an initial signal line, a first power supply line, and a light emitting signal line on the base substrate.

In an exemplary implementation mode, as shown in FIG. 22, a length of the fourth vent hole H4 along the second direction D2 is greater than a length of the third via along the second direction D2, and a length of the fourth vent hole H4 along the first direction D1 is less than a length of the third via along the first direction D1.

In an exemplary implementation mode, as shown in FIG. 22, the fifth vent hole H5 and the eighth via V8 are arranged along the first direction D1. A distance between an orthographic projection of the fifth vent hole H5 on the base substrate and an orthographic projection of the fourth via on the base substrate is smaller than a distance between the orthographic projection of the fourth via on the base substrate and an orthographic projection of a gate electrode of a first transistor on the base substrate, that is, the fifth vent hole H5 is disposed at a periphery of a sleeve hole including the eighth via and the fourth via.

In an exemplary implementation mode, as shown in FIG. 22, a length of the fifth vent hole H5 along the second direction D2 is larger than a length of the fourth via along the second direction D2, and a length of the fifth vent hole H5 along the first direction D1 is smaller than a length of the fourth via along the first direction D1.

In an exemplary implementation mode, as shown in FIG. 22, there is no overlapping region between an orthographic projection of a portion of the fifth vent hole H5 on the base substrate and orthographic projections of an active pattern, a gate electrode, a first electrode, and a second electrode of any transistor, and a reference signal line, a first scan signal line, a second scan signal line, a third scan signal line, an initial signal line, a first power supply line, a light emitting signal line, and an initial connection line on the base substrate. An orthographic projection of the other portion of the fifth vent hole H5 on the base substrate is at least partially overlapped with an orthographic projection of the first power supply line on the base substrate, and there is no overlapping region between the orthographic projection of the other portion of the fifth vent hole H5 on the base substrate and orthographic projections of an active pattern, a gate electrode, a first electrode, and a second electrode of any transistor, and a reference signal line, a first scan signal line, a second scan signal line, a third scan signal line, an initial signal line, a light emitting signal line, and an initial connection line on the base substrate.

In an exemplary implementation mode, a shape of a cross section of any of the second vent hole to the fifth vent hole may be a polygon, for example, a rectangle, a square, a pentagon, or a hexagon, and the present disclosure is illustrated by taking a rectangle as an example.

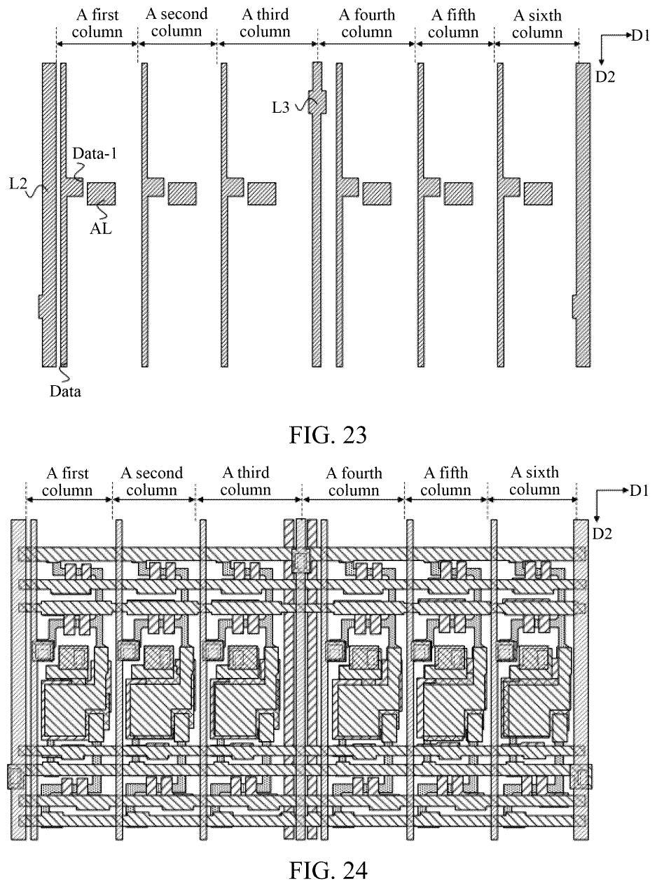

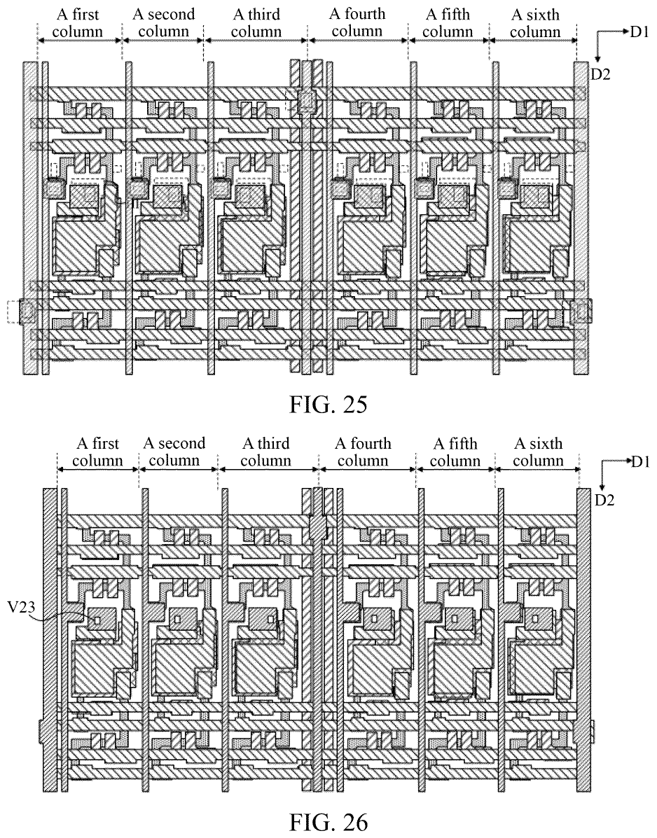

(8) A pattern of a fourth conductive layer is formed. In an exemplary implementation mode, forming the fourth conductive layer may include: depositing a fourth conductive thin film on the base substrate on which the aforementioned patterns are formed, patterning the fourth conductive thin film by using a patterning process to form the fourth conductive layer disposed on the fifth insulation layer. As shown in FIG. 23, FIG. 24, and FIG. 25, FIG. 23 is a schematic diagram of a pattern of a fourth conductive layer in FIGS. 7A and 7B, FIG. 24 is a schematic diagram after the pattern of the fourth conductive layer is formed in FIG. 7A, and FIG. 25 is a schematic diagram after the pattern of the fourth conductive layer is formed in FIG. 7B. In an exemplary implementation mode, the fourth conductive layer may be referred to as a second source-drain metal (SD2) layer.

In an exemplary implementation mode, as shown in FIGS. 23 to 25, the pattern of the fourth conductive layer may at least include an anode connection electrode AL located in each sub-pixel, and a data signal line Data, a power supply connection line L2, and a reference connection line L3.

In an exemplary implementation mode, a shape of the data signal line Data may be a line shape in which a main body portion extends along the second direction D2, and an orthographic projection of a data signal line Data with which a present column of sub-pixels is connected on the base substrate may be located on a side of an orthographic projection of the third electrode plate of the capacitor on the base substrate close to a previous column of sub-pixels. Each data signal line Data is provided with a third connection block Data-1, a first end of the third connection block Data-1 is connected with the data signal line Data, the third connection block Data-1 is located on a side of the data signal line Data close to the third electrode plate C3 of the capacitor and extends along the first direction D1, and an orthographic projection of the third connection block Data-1 on the base substrate is at least partially overlapped with an orthographic projection of the first electrode of the fourth transistor on the base substrate. The data signal line Data is electrically connected with the first electrode of the fourth transistor through the sixth via and the second via sequentially.

In an exemplary implementation mode, a shape of the power supply connection line L2 may be a line shape in which a main body portion extends along the second direction D2, and an orthographic projection of the power supply connection line L2 on the base substrate is at least partially overlapped with an orthographic projection of the second connection block of the first power supply line on the base substrate. The power supply connection line L2 is electrically connected with the first power supply line through the eighth via and the fourth via sequentially.

In an exemplary implementation mode, a plurality of power supply connection lines L2 and a plurality of first power supply lines may form a mesh structure, which may improve display uniformity of the display substrate.

In an exemplary implementation mode, a shape of the reference connection line L3 may be a line shape in which a main body portion extends along the second direction D2, and an orthographic projection of the reference connection line L3 on the base substrate is at least partially overlapped with an orthographic projection of the first connection block of the reference signal line on the base substrate. The reference connection line L3 is electrically connected with the reference signal line through the seventh via and the third via sequentially.

In an exemplary implementation mode, an orthographic projection of at least a portion of the reference connection line L3 on the base substrate is located between orthographic projections of two initial connection lines located between two adjacent sub-pixels on the base substrate.

In an exemplary implementation mode, a plurality of reference connection lines L3 and a plurality of reference signal lines may form a mesh structure, which may improve display uniformity of the display substrate.

In an exemplary implementation mode, a shape of the anode connection electrode AL may be a block shape, and an orthographic projection of the anode connection electrode AL on the base substrate is at least partially overlapped with an orthographic projection of the second electrode of the third transistor on the base substrate. The anode connection electrode AL is connected with the second electrode of the third transistor through the fifth via and the first via sequentially.

In an exemplary implementation mode, as shown in FIG. 25, there is no overlapping region between orthographic projections of the first vent hole to the fifth vent hole on the base substrate and orthographic projections of a power supply connection line, a reference connection line, a data signal line, and an anode connection electrode on the base substrate.

In an exemplary implementation mode, the power supply connection line L2, the reference connection line L3, and the data signal line Data may be designed with equal width, or may be designed with unequal width, may be straight lines, or may be polygonal lines, which may not only facilitate a layout of a pixel structure, but also reduce a parasitic capacitance between signal lines, which is not limited here in the present disclosure.

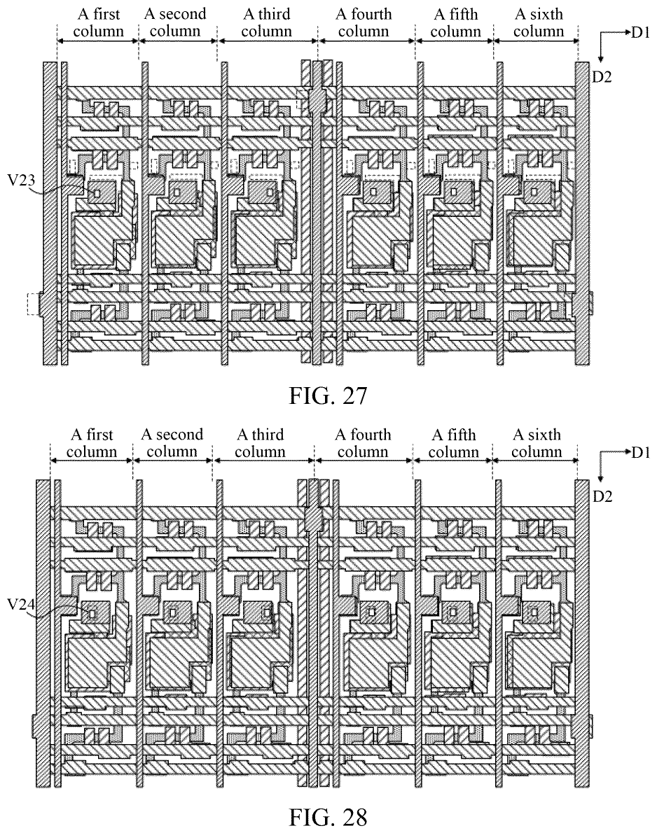

(9) A pattern of a sixth insulation layer is formed. In an exemplary implementation mode, forming the pattern of the sixth insulation layer may include: depositing a sixth insulation thin film on the base substrate on which the aforementioned patterns are formed, and patterning the sixth insulation thin film by using a patterning process to form the pattern of the sixth insulation layer covering the pattern of the fourth conductive layer, wherein the sixth insulation layer is provided with a plurality of vias. As shown in FIGS. 26 and 27, FIG. 26 is a schematic diagram after a pattern of a sixth insulation layer is formed in FIG. 7A, and FIG. 27 is a schematic diagram after a pattern of a sixth insulation layer is formed in FIG. 7B.

In an exemplary implementation mode, as shown in FIGS. 26 and 27, the plurality of vias of the pattern of the sixth insulation layer at least include a twenty-third via V23 located in each sub-pixel.

In an exemplary implementation mode, an orthographic projection of the twenty-third via V23 on the base substrate is within a range of an orthographic projection of the anode connection electrode on the base substrate, the twenty-third via V23 exposes a surface of the anode connection electrode, and the twenty-third via V23 is configured such that an anode of a light emitting device subsequently formed is connected with the anode connection electrode through the via.

In an exemplary implementation mode, in at least one sub-pixel, there is no overlapping region between the orthographic projection of the twenty-third via on the base substrate and orthographic projections of the fifteenth via and the nineteenth via on the base substrate.

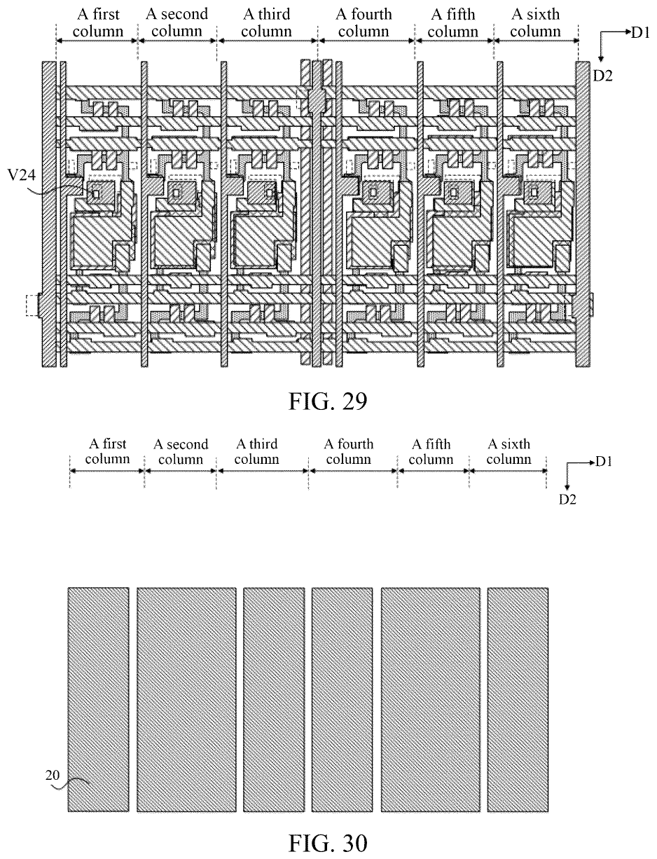

(10) A pattern of a second planarization layer is formed. In an exemplary implementation mode, forming the pattern of the second planarization layer may include: coating a second planarization thin film on the base substrate on which the aforementioned patterns are formed, and patterning the second planarization thin film by using a patterning process to form a second planarization layer covering the pattern of the sixth insulation layer, wherein the second planarization layer is provided with a plurality of vias. As shown in FIGS. 28 and 29, FIG. 28 is a schematic diagram after a pattern of a second planarization layer is formed in FIG. 7A, and FIG. 29 is a schematic diagram after a pattern of a second planarization layer is formed in FIG. 7B.

In an exemplary implementation mode, as shown in FIGS. 28 and 29, the plurality of vias of the pattern of the second planarization layer may at least include a twenty-fourth via V24 located in each sub-pixel.

In an exemplary implementation mode, an orthographic projection of the twenty-fourth via V24 on the base substrate is within a range of an orthographic projection of the anode connection electrode on the base substrate, the twenty-fourth via V24 exposes a surface of the anode connection electrode, and the twenty-fourth via V24 is configured such that an anode of a light emitting device subsequently formed is connected with the anode connection electrode through the via.

In an exemplary implementation mode, for any sub-pixel, an orthographic projection of the twenty-third via on the base substrate is within a range of the orthographic projection of the twenty-fourth via V24 on the base substrate. The orthographic projection of the twenty-fourth via on the base substrate is partially overlapped with an orthographic projection of a portion of the sixth insulation layer on the base substrate.

So far, a drive structure layer has been prepared on the base substrate. In a plane parallel to the display substrate, the drive structure layer may include a plurality of pixel drive circuits, and pixel drive circuit is connected with a first scan signal line, a second scan signal line, a third scan signal line, a light emitting signal line, an initial signal line, a reference signal line, a data signal line, and a first power supply line. In a plane perpendicular to the display substrate, the drive structure layer may be disposed on the base substrate.

The drive structure layer may include a first insulation layer, a semiconductor layer, a second insulation layer, a first conductive layer, a third insulation layer, a second conductive layer, a fourth insulation layer, a third conductive layer, a first planarization layer, a fifth insulation layer, a fourth conductive layer, a sixth insulation layer, and a second planarization layer sequentially disposed on the base substrate. Herein, the semiconductor layer may at least include active patterns of a first transistor to a fifth transistor, the first conductive layer may at least include gate electrodes of the first transistor to the fifth transistor, a first electrode plate of a capacitor and an initial connection line, the second conductive layer may at least include a second electrode plate of the capacitor, the third conductive layer may at least include a first scan signal line, a second scan signal line, a third scan signal line, a reference signal line, a light emitting signal line, an initial signal line, a first power supply line and first electrodes and second electrodes of a plurality of transistors, the initial signal line is connected through the initial connection line, the fourth conductive layer may at least include a data signal line, a power supply connection line, a reference connection line, and an anode connection electrode, the power supply connection line is connected with the first power supply line through a via, and the reference connection line is connected with the reference signal line through a via.

In an exemplary implementation mode, the semiconductor layer may be made of various materials, such as amorphous Indium Gallium Zinc Oxide (α-IGZO), Zinc Oxynitride (ZnON), Indium Zinc Tin Oxide (IZTO), amorphous Silicon (a-Si), polycrystalline Silicon (p-Si), hexathiophene, and polythiophene. That is, the present disclosure is applicable to transistors manufactured based on an oxide technology, a silicon technology, and an organic substance technology. Exemplarily, the semiconductor layer may be made of polycrystalline Silicon.

In an exemplary implementation mode, a thickness of the semiconductor layer may be about 430 angstroms to 520 angstroms. Exemplarily, a thickness of the semiconductor layer may be about 470 angstroms.

In an exemplary implementation mode, the first conductive layer, the second conductive layer, the third conductive layer, and the fourth conductive layer may be made of a metal material, such as any one or more of Argentum (Ag), Copper (Cu), Aluminum (Al), and Molybdenum (Mo), or an alloy material of the aforementioned metals, such as an Aluminum Neodymium alloy (AlNd) or a Molybdenum Niobium alloy (MoNb), and may be of a single-layer structure or a multi-layer composite structure, such as Mo/Cu/Mo or Ti/Al/Ti.

In an exemplary implementation mode, a resistivity of any film layer of the third conductive layer and the fourth conductive layer is smaller than a resistivity of any film layer of the first conductive layer and the second conductive layer. Exemplarily, the first conductive layer and the second conductive layer may be made of Molybdenum, and the third conductive layer and the fourth conductive layer may be made of Ti/Al/Ti.

In an exemplary implementation mode, a thickness of the first conductive layer may be about 2,500 angstroms to 3,000 angstroms, and exemplarily, a thickness of the first conductive layer may be about 2,800 angstroms.

In an exemplary implementation mode, a thickness of the second conductive layer may be about 2,500 angstroms to 3,000 angstroms, and exemplarily, a thickness of the second conductive layer may be about 2,800 angstroms.

In an exemplary implementation mode, the third conductive layer and the fourth conductive layer respectively include a first sub-conductive layer, a second sub-conductive layer, and a third sub-conductive layer which are sequentially stacked on the base substrate, wherein the first sub-conductive layer and the third sub-conductive layer may be made of Ti, and the second sub-conductive layer may be made of Al. Exemplarily, a thickness of the first sub-conductive layer may be about 400 angstroms to 600 angstroms, which may be, exemplarily, about 500 angstroms; a thickness of the second sub-conductive layer may be about 6,000 angstroms to 7,000 angstroms, which may be, exemplarily, 6,500 angstroms; and a thickness of the third sub-conductive layer may be about 200 angstroms to 400 angstroms, which may be, exemplarily, about 300 angstroms.

In an exemplary implementation mode, the first insulation layer, the second insulation layer, the third insulation layer, the fourth insulation layer, the fifth insulation layer, and the sixth insulation layer may be made of any one or more of Silicon Oxide (SiOx), Silicon Nitride (SiNx), and Silicon Oxynitride (SiON), and may be a single layer, a multi-layer, or a composite layer. The first insulation layer may be referred to as a buffer layer, the second insulation layer and the third insulation layer may be referred to as Gate Insulation (GI) layers, the fourth insulation layer may be referred to as an Interlayer Dielectric (ILD) layer, and the fifth insulation layer may be referred to as a Passivation (PVX) layer.

In an exemplary implementation mode, when the first insulation layer is made of Silicon Oxide (SiOx), a thickness of the first insulation layer may be about 2,500 angstroms to 3,500 angstroms, and exemplarily, the thickness of the first insulation layer may be about 3000 angstroms. When the first insulation layer is made of Silicon Nitride (SiNx), a thickness of the first insulation layer may be about 500 angstroms to 1,500 angstroms, and exemplarily, the thickness of the first insulation layer may be about 1,000 angstroms.

In an exemplary implementation mode, when the second insulation layer is made of Silicon Oxide (SiOx), a thickness of the second insulation layer may be about 700 angstroms to 900 angstroms, and exemplarily, the thickness of the second insulation layer may be about 800 angstroms. When the second insulation layer is made of Silicon Nitride (SiNx), a thickness of the second insulation layer may be about 350 angstroms to 450 angstroms, and exemplarily, the thickness of the second insulation layer may be about 400 angstroms.

In an exemplary implementation mode, the third insulation layer may be made of Silicon Nitride (SiNx), a thickness of the third insulation layer may be about 2,500 angstroms to 3,000 angstroms, and exemplarily, the thickness of the third insulation layer may be about 2,800 angstroms.

In an exemplary implementation mode, when the fourth insulation layer is made of silicon oxide, a thickness of the fourth insulation layer may be about 1,500 angstroms to 2,500 angstroms, and exemplarily, the thickness of the fourth insulation layer may be about 2,000 angstroms; and when the fourth insulation layer is made of Silicon Nitride (SiNx), a thickness of the fourth insulation layer may be about 2,500 angstroms to 3,500 angstroms, and exemplarily, the thickness of the fourth insulation layer may be about 3,000 angstroms.

In an exemplary implementation mode, a manufacturing material of the fifth insulation layer may be about Silicon Nitride (SiNx), a thickness of the fifth insulation layer may be about 1,200 angstroms to 1,600 angstroms, and exemplarily, the thickness of the fifth insulation layer may be about 1,400 angstroms.

In an exemplary implementation mode, a manufacturing material of the sixth insulation layer may be about Silicon Nitride (SiNx), a thickness of the sixth insulation layer may be about 1,200 angstroms to 1,600 angstroms, and exemplarily, the thickness of the sixth insulation layer may be about 1,400 angstroms.

In an exemplary implementation mode, the first planarization layer and the second planarization layer may be made of an organic material such as a resin, for example, polyimide or the like.

In an exemplary implementation mode, a thickness of the first planarization layer may be about 18,000 to 22,000 angstroms, and exemplarily, the thickness of the first planarization layer may be about 20,000 angstroms.

In an exemplary implementation mode, a thickness of the second planarization layer may be about 20,000 to 40,000 angstroms, and exemplarily, the thickness of the second planarization layer may be about 20,000 angstroms.

In an exemplary implementation mode, after preparation of the drive structure layer is completed, a light emitting structure layer is prepared on the drive structure layer, and a preparation process of the light emitting structure layer may include following operations.

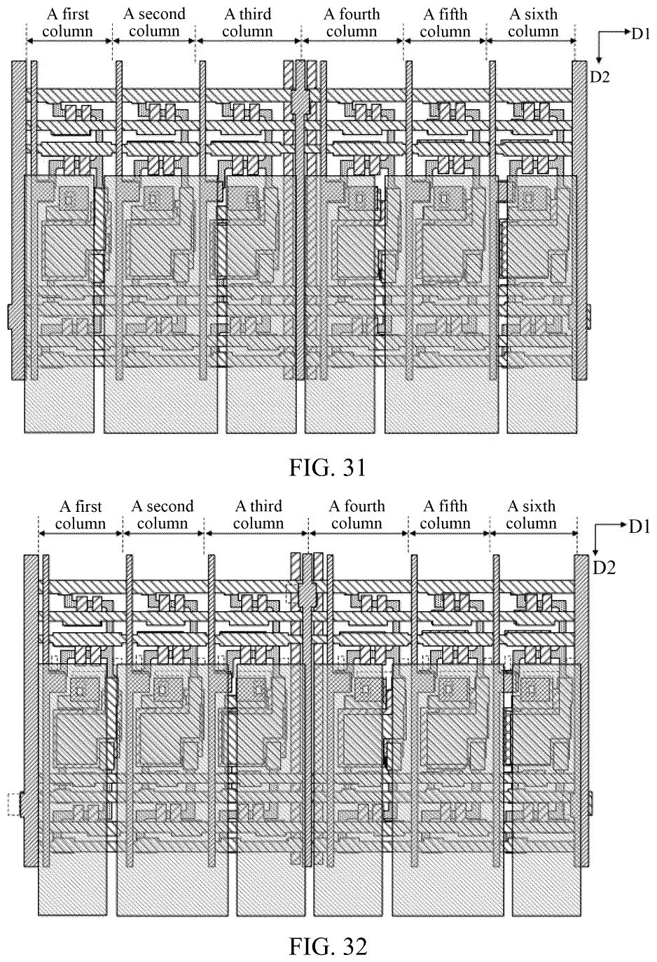

(11) A pattern of a fifth conductive layer is formed. In an exemplary implementation mode, forming the pattern of the fifth conductive layer may include: depositing a fifth conductive thin film on the base substrate on which the aforementioned patterns are formed, and patterning the fifth conductive thin film by using a patterning process to form the fifth conductive layer disposed on the second planarization layer. As shown in FIG. 30 to FIG. 32, FIG. 30 is a schematic diagram of a pattern of a fifth conductive layer in FIGS. 7A and 7B, FIG. 31 is a schematic diagram after the pattern of the fifth conductive layer is formed in FIG. 7A, and FIG. 32 is a schematic diagram after the pattern of the fifth conductive layer is formed in FIG. 7B.

In an exemplary implementation mode, the pattern of the fifth conductive layer at least includes a first electrode 20 located in each sub-pixel.

In an exemplary implementation mode, a shape of the first electrode 20 may be a rectangle, or may be another shape, which is not limited in the present disclosure.

In an exemplary implementation mode, for any sub-pixel, an anode 20 of a light emitting device is connected with an anode connection electrode through the twenty-fourth via and the twenty-third via sequentially.

In an exemplary implementation mode, an orthographic projection of at least a portion of any structure of an anode connection electrode, a first electrode plate of a capacitor, a second electrode plate of the capacitor, and a third electrode plate of the capacitor, a gate electrode of a fifth transistor, and a gate electrode of a first transistor on the base substrate is within a range of an orthographic projection of an anode on the base substrate.

In an exemplary implementation mode, a plurality of anodes may include a first anode of a red light emitting device, a second anode of a blue light emitting device, and a third anode of a first green light emitting device, wherein the first anode may be located in a red sub-pixel emitting red light, the second anode may be located in a blue sub-pixel emitting blue light, and the third anode may be located in a green sub-pixel emitting green light.

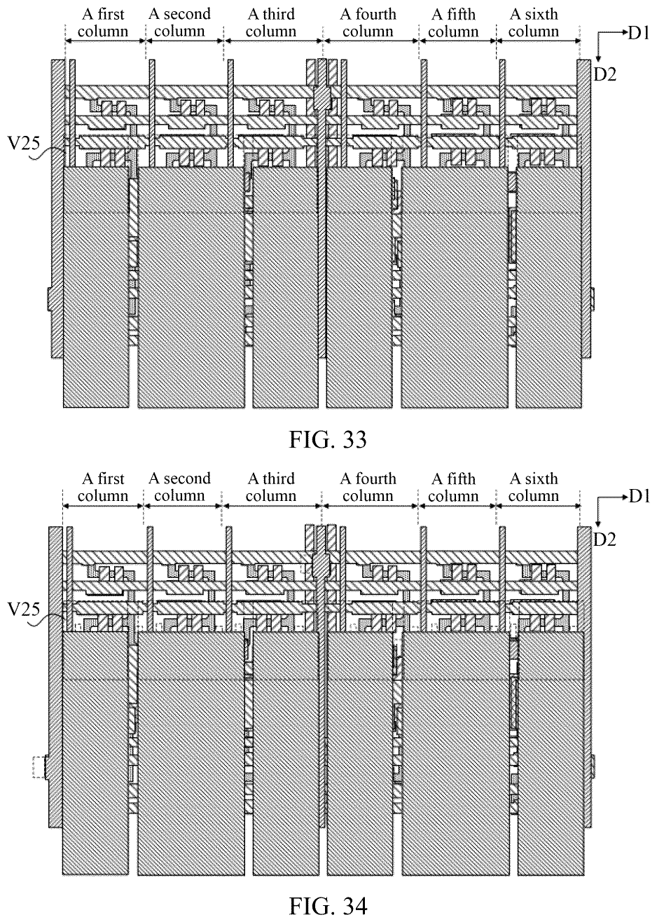

(12) A pattern of a first pixel definition layer is formed. In an exemplary implementation mode, forming the pattern of the first pixel definition layer may include: coating a first pixel definition thin film on the base substrate on which the aforementioned patterns are formed, and patterning the first pixel definition thin film by using a patterning process to form a pattern of a first pixel definition layer, wherein the pattern of the first pixel definition layer includes a plurality of vias. As shown in FIGS. 33 and 34, FIG. 33 is a schematic diagram after a pattern of a first pixel definition layer is formed in FIG. 7A, and FIG. 34 is a schematic diagram after a pattern of a first pixel definition layer is formed in FIG. 7B.

In an exemplary implementation mode, as shown in FIGS. 33 and 34, the pattern of the first pixel definition layer may include a twenty-fifth via V25 located in each sub-pixel.

In an exemplary implementation mode, an orthographic projection of the twenty-fifth via V25 on the base substrate is within ranges of orthographic projections of the anode and a portion of the second planarization layer on the base substrate, respectively, the twenty-fifth via V25 exposes a surface of the anode, and the twenty-fifth via V25 is configured such that an organic emitting layer formed subsequently is connected with the anode through the via.

In an exemplary implementation mode, a distance between an orthographic projection of a boundary of the twenty-fifth via V25 close to the reference signal line on the base substrate and an orthographic projection of the reference signal line on the base substrate is smaller than a distance between an orthographic projection of the anode on the base substrate and the orthographic projection of the reference signal line on the base substrate.

In an exemplary implementation mode, a length of the twenty-fifth via V25 along the first direction D1 may be greater than or equal to a length of the anode along the first direction D1. A length of the twenty-fifth via V25 along the second direction D2 may be less than or equal to a length of the anode along the second direction D2.

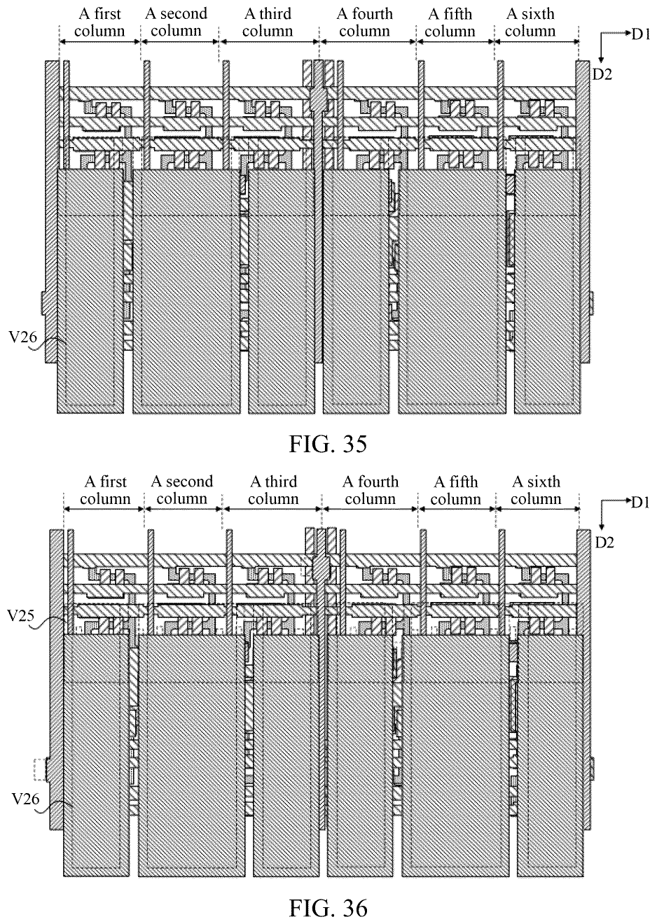

(13) A pattern of a second pixel definition layer is formed. In an exemplary implementation mode, forming the pattern of the second pixel definition layer may include coating a second pixel definition thin film on the base substrate on which the aforementioned patterns are formed, and patterning the second pixel definition thin film by using a patterning process to form a pattern of a second pixel definition layer, wherein the pattern of the second pixel definition layer includes a plurality of vias. As shown in FIGS. 35 and 36, FIG. 35 is a schematic diagram after a pattern of a second pixel definition layer is formed in FIG. 7, and FIG. 36 is a schematic diagram after a pattern of a second pixel definition layer is formed in FIG. 8.

In an exemplary implementation mode, as shown in FIGS. 35 and 36, the pattern of the second pixel definition layer may include a twenty-sixth via V26 located in each sub-pixel.

In an exemplary implementation mode, an orthographic projection of the twenty-sixth via V26 on the base substrate is within ranges of orthographic projections of the anode and a portion of the twenty-fifth via on the base substrate, respectively, the twenty-sixth via V26 exposes a surface of the anode, and the twenty-sixth via V26 is configured such that an organic emitting layer formed subsequently is connected with the anode through the via.

In an exemplary implementation mode, a distance between an orthographic projection of a boundary of the twenty-sixth via V26 close to the reference signal line on the base substrate and an orthographic projection of the reference signal line on the base substrate may be equal to the distance between the orthographic projection of the boundary of the twenty-fifth via close to the reference signal line on the base substrate and the orthographic projection of the reference signal line on the base substrate.

In an exemplary implementation mode, a length of the twenty-sixth via V26 along the first direction D1 may be smaller than a length of the anode along the first direction D1. A length of the twenty-sixth via V26 along the second direction D2 may be greater than a length of the anode along the second direction D2.

In an exemplary implementation mode, the fifth conductive layer may be of a single-layer structure, such as Indium Tin Oxide (ITO) or Indium Zinc Oxide (IZO), or may be of a multi-layer composite structure, such as ITO/Ag/ITO.

In an exemplary implementation mode, the fifth conductive layer may include a first anode layer, a second anode layer, and a third anode layer which are stacked on the base substrate sequentially, wherein the first anode layer and the third anode layer may be made of ITO, and the second anode layer may be made of Ag. Exemplarily, a thickness of the first anode layer and the third anode layer may be about 50 angstroms to 100 angstroms, and exemplarily, a thickness of the first anode layer may be about 70 angstroms; and a thickness of the second anode layer may be about 800 angstroms to 1,200 angstroms, and exemplarily, the thickness of the second anode layer may be about 1,000 angstroms.

In an exemplary implementation mode, materials of the first pixel definition layer and the second pixel definition layer may include polyimide, acrylic, or polyethylene terephthalate or the like.

In an exemplary implementation mode, a transmittance of the first pixel definition layer is less than a transmittance of the second pixel definition layer.

In an exemplary implementation mode, a thickness of the first pixel definition layer may be about 16,000 angstroms to 20,000 angstroms, and exemplarily, the thickness of the first pixel definition layer may be about 18,000 angstroms.

In an exemplary implementation mode, a thickness of the second pixel definition layer may be about 13,000 angstroms to 17,000 angstroms, and exemplarily, the thickness of the second pixel definition layer may be about 15,000 angstroms.

In an exemplary implementation mode, a subsequent preparation process may include forming a light emitting material layer by using an evaporation process or inkjet printing process at first, wherein the light emitting material layer may at least include an organic emitting layer, and the organic emitting layer located in a same sub-pixel may be connected with the anode sequentially through the twenty-sixth via and the twenty-fifth via; then forming a pattern of a sixth conductive layer on the organic emitting layer, wherein the pattern of the sixth conductive layer may at least include a second electrode; and then forming an encapsulation structure layer, wherein the encapsulation structure layer may include a first encapsulation layer, a second encapsulation layer, and a third encapsulation layer which are stacked, the first encapsulation layer and the third encapsulation layer may be made of an inorganic material, the second encapsulation layer may be made of an organic material, and the second encapsulation layer is disposed between the first encapsulation layer and the third encapsulation layer, which may ensure that external water vapor cannot enter the light emitting structure layer.

As may be seen from a structure and the preparation process of the display substrate described above, according to the display substrate of the present disclosure, the fifth insulation layer is provided with a via exposing the first planarization layer, which forms a deflation channel, such that residual water vapor in the first planarization layer in a subsequent manufacturing project may be released, thus improving reliability of the display substrate, and further ensuring a display effect of a display product. The preparation process of the display substrate according to the exemplary embodiment of the present disclosure may be compatible well with an existing preparation process, and the process is simple to implement and is easy to carry out, and has a high production efficiency, a low production cost, and a high yield.

The structure shown and mentioned above in the present disclosure and the preparation process thereof are merely an exemplary description. In an exemplary implementation mode, corresponding structures may be altered and patterning processes may be added or reduced according to actual needs. For example, a part of lapping vias may be disposed in sub-pixels away from the first centerline, so as to increase a spacing between adjacent lapping vias, reduce mutual interference, and ensure that there is no crosstalk of display pictures, which is not limited in the present disclosure.

In an exemplary implementation mode, the display substrate of the present disclosure may be applied to another display apparatus having a pixel drive circuit, such as quantum dot display, which is not limited in the present disclosure.

An embodiment of the present disclosure also provides a display apparatus, including a display substrate.

The display substrate is the display substrate according to any of the aforementioned embodiments, and has similar implementation principles and implementation effects, which will not be repeated here.

In an exemplary implementation mode, the display apparatus may be any product or component with a display function, such as a mobile phone, a tablet computer, a television, a display, a laptop computer, a digital photo frame, or a navigator, and the embodiments of the present disclosure are not limited thereto.

The drawings of the embodiments of the present disclosure only involve structures involved in the embodiments of the present disclosure, and other structures may be referred to general designs.

For the sake of clarity, a thickness and size of a layer or a micro structure are enlarged in the accompanying drawings used for describing the embodiments of the present disclosure. It may be understood that when an element such as a layer, film, region, or substrate is described as being “on” or “under” another element, the element may be “directly” located “on” or “under” the another element, or there may be an intermediate element.

Although implementation modes disclosed in the present disclosure are as above, contents described are only implementation modes used for convenience of understanding of the present disclosure and are not intended to limit the present disclosure. Any of those skilled in the art of the present disclosure may make any modifications and variations in forms and details of implementation without departing from the spirit and scope of the present disclosure. However, the scope of patent protection of the present disclosure should be subject to the scope defined in the appended claims.

1. A display substrate, provided with a plurality of sub-pixels arranged in an array, wherein at least one sub-pixel comprises: a pixel drive circuit, the display substrate comprises: a base substrate and a drive structure layer disposed on the base substrate, and the pixel drive circuit is disposed on the drive structure layer;
the drive structure layer at least comprises: a first insulation layer, a semiconductor layer, a second insulation layer, a first conductive layer, a third insulation layer, a second conductive layer, a fourth insulation layer, a third conductive layer, a first planarization layer, a fifth insulation layer, and a fourth conductive layer which are stacked on the base substrate sequentially;
the fifth insulation layer is provided with a plurality of vias, and at least one via on the fifth insulation layer exposes the first planarization layer; and
a thickness of the first planarization layer is greater than a thickness of the fifth insulation layer.

2. The display substrate according to claim 1, wherein the pixel drive circuit comprises a first transistor to a fifth transistor, and the drive structure layer further comprises a first scan signal line, a second scan signal line, a third scan signal line, an initial signal line, a data signal line, a light emitting signal line, a reference signal line, and a first power supply line, wherein the first transistor is electrically connected with the third scan signal line and the initial signal line respectively, the second transistor is electrically connected with the second scan signal line and the reference signal line respectively, the fourth transistor is electrically connected with the first scan signal line and the data signal line respectively, and the fifth transistor is electrically connected with the light emitting signal line and the first power supply line respectively;
any one of the first scan signal line, the second scan signal line, the third scan signal line, the initial signal line, the light emitting signal line, the reference signal line, and the first power supply line at least partially extends along a first direction, and the data signal line at least partially extends along a second direction, wherein the first direction intersects with the second direction;
a reference signal line, a second scan signal line, a first scan signal line, a light emitting signal line, a first power supply line, a third scan signal line, and an initial signal line which are connected with any sub-pixel are arranged sequentially along the second direction;
the first planarization layer is provided with a first via to a fourth via, wherein an orthographic projection of the first via on the base substrate is within a range of an orthographic projection of a second electrode of the third transistor on the base substrate and a surface of the second electrode of the third transistor is exposed, an orthographic projection of the second via on the base substrate is within a range of an orthographic projection of a first electrode of the fourth transistor on the base substrate and a surface of the first electrode of the fourth transistor is exposed, an orthographic projection of the third via on the base substrate is within a range of an orthographic projection of a reference signal line on the base substrate and a surface of the reference signal line is exposed, and an orthographic projection of the fourth via on the base substrate is within a range of an orthographic projection of a first power supply line on the base substrate and a surface of the first power supply line is exposed; and
the third via is located on a centerline of two adjacent fourth vias extending along the second direction.

3. The display substrate according to claim 2, wherein the fifth insulation layer is provided with a fifth via to an eighth via,
wherein an orthographic projection of the fifth via on the base substrate is within a range of orthographic projections of the first via and the first planarization layer on the base substrate, an orthographic projection of the sixth via on the base substrate is within a range of orthographic projections of the second via and the first planarization layer on the base substrate, an orthographic projection of the seventh via on the base substrate is within a range of orthographic projections of the third via and the first planarization layer on the base substrate, and an orthographic projection of the eighth via on the base substrate is within a range of orthographic projections of the fourth via and the first planarization layer on the base substrate.

4. The display substrate according to claim 3, wherein a length of the fifth via along the first direction is less than a length of the first via along the first direction, and a length of the fifth via along the second direction is less than a length of the first via along the second direction;
a length of the sixth via along the first direction is less than a length of the second via along the first direction, and a length of the sixth via along the second direction is less than a length of the second via along the second direction;
a length of the seventh via along the first direction is less than a length of the third via along the first direction, and a length of the seventh via along the second direction is less than a length of the third via along the second direction; and
a length of the eighth via along the first direction is less than the length of the fourth via along the first direction, and a length of the eighth via along the second direction is less than a length of the fourth via along the second direction.

5. The display substrate according to claim 4, wherein within any sub-pixel, boundaries of a via comprise a first boundary, a second boundary, a third boundary, and a fourth boundary, wherein the first boundary of the via is a boundary of the via close to a first signal line, the second boundary of the via is a boundary of the via away from the first signal line, the third boundary of the via is a boundary located on one side of a first centerline, and the fourth boundary of the via is a boundary located on the other side of the first centerline; the via comprises a first via and a fifth via; the first signal line is one of a light emitting signal line, a first power supply line, a third scan signal line, and an initial signal line which are connected with the sub-pixel; the first centerline is a centerline of the first via extending along the second direction, a third boundary of the first via and a third boundary of the fifth via are located on a same side of the first centerline, and a fourth boundary of the first via and a fourth boundary of the fifth via are located on a same side of the first centerline;
a distance between an orthographic projection of a first boundary of the first via on the base substrate and an orthographic projection of the first signal line on the base substrate is greater than a distance between an orthographic projection of a first boundary of the fifth via on the base substrate and the orthographic projection of the first signal line on the base substrate, a distance between an orthographic projection of a second boundary of the first via on the base substrate and the orthographic projection of the first signal line on the base substrate is greater than a distance between an orthographic projection of a second boundary of the fifth via on the base substrate and the orthographic projection of the first signal line on the base substrate, a distance between the third boundary of the first via and the first centerline is greater than a distance between an orthographic projection of the third boundary of the fifth via on the base substrate and an orthographic projection of the first centerline on the base substrate, and a distance between the fourth boundary of the first via and the first centerline is greater than a distance between an orthographic projection of the fourth boundary of the fifth via on the base substrate and the orthographic projection of the first centerline on the base substrate.

6. The display substrate according to claim 5, wherein within any sub-pixel, a distance between the orthographic projection of the first boundary of the first via on the base substrate and the orthographic projection of the first boundary of the fifth via on the base substrate is greater than a distance between an orthographic projection of the third boundary of the first via on the base substrate and the orthographic projection of the third boundary of the fifth via on the base substrate, and is less than a distance between the orthographic projection of the second boundary of the first via on the base substrate and the orthographic projection of the second boundary of the fifth via on the base substrate; and
the distance between the orthographic projection of the first boundary of the first via on the base substrate and the orthographic projection of the first boundary of the fifth via on the base substrate is about 1 micron to 2 microns.

7. The display substrate according to claim 4, wherein within any sub-pixel, boundaries of a via comprise a first boundary, a second boundary, a third boundary, and a fourth boundary, wherein the first boundary of the via is a boundary of the via close to a first signal line, the second boundary of the via is a boundary of the via away from the first signal line, the third boundary of the via is a boundary located on one side of a second centerline, and the fourth boundary of the via is a boundary located on the other side of the second centerline; the via comprises a second via and a sixth via; the first signal line is one of a light emitting signal line, a first power supply line, a third scan signal line, and an initial signal line which are connected with the sub-pixel; the second centerline is a centerline of the second via extending along the second direction, a third boundary of the second via and a third boundary of the sixth via are located on a same side of the second centerline, and a fourth boundary of the second via and a fourth boundary of the sixth via are located on a same side of the second centerline; and
a distance between an orthographic projection of a first boundary of the second via on the base substrate and an orthographic projection of the first signal line on the base substrate is greater than a distance between an orthographic projection of a first boundary of the sixth via on the base substrate and the orthographic projection of the first signal line on the base substrate, a distance between an orthographic projection of a second boundary of the second via on the base substrate and the orthographic projection of the first signal line on the base substrate is greater than a distance between an orthographic projection of a second boundary of the sixth via on the base substrate and the orthographic projection of the first signal line on the base substrate, a distance between the third boundary of the second via and the second centerline is greater than a distance between an orthographic projection of the third boundary of the sixth via on the base substrate and an orthographic projection of the second centerline on the base substrate, and a distance between the fourth boundary of the second via and the second centerline is greater than a distance between an orthographic projection of the fourth boundary of the sixth via on the base substrate and the orthographic projection of the second centerline on the base substrate.

8. The display substrate according to claim 7, wherein within any sub-pixel, a distance between the orthographic projection of the first boundary of the second via on the base substrate and the orthographic projection of the first boundary of the sixth via on the base substrate is greater than a distance between an orthographic projection of the third boundary of the second via on the base substrate and the orthographic projection of the third boundary of the sixth via on the base substrate, and is less than a distance between the orthographic projection of the second boundary of the second via on the base substrate and the orthographic projection of the second boundary of the sixth via on the base substrate; and
the distance between the orthographic projection of the first boundary of the second via on the base substrate and the orthographic projection of the first boundary of the sixth via on the base substrate is about 1 micron to 2 microns.

9. The display substrate according to claim 4, wherein boundaries of a via comprise: a first boundary, a second boundary, a third boundary, and a fourth boundary, wherein the first boundary of the via is a boundary of the via close to a second signal line, the second boundary of the via is a boundary of the via away from the second signal line, the third boundary of the via is a boundary located on one side of a third centerline, and the fourth boundary of the via is a boundary located on the other side of the third centerline; the via comprises a third via and a seventh via; the second signal line is one of a light emitting signal line, a first power supply line, a first scan signal line, a second scan signal line, a third scan signal line, an initial signal line, and a light emitting signal line which are connected with a sub-pixel connected with a reference signal line exposed by the third via; the third centerline is a centerline of the third via extending along the second direction, a third boundary of the third via and a third boundary of the seventh via are located on a same side of the third centerline, and a fourth boundary of the third via and a fourth boundary of the seventh via are located on a same side of the third centerline; and
a distance between an orthographic projection of a first boundary of the third via on the base substrate and an orthographic projection of the second signal line on the base substrate is greater than a distance between an orthographic projection of a first boundary of the seventh via on the base substrate and the orthographic projection of the second signal line on the base substrate, a distance between an orthographic projection of a second boundary of the third via on the base substrate and the orthographic projection of the second signal line on the base substrate is greater than a distance between an orthographic projection of a second boundary of the seventh via on the base substrate and the orthographic projection of the second signal line on the base substrate, a distance between the third boundary of the third via and the third centerline is greater than a distance between an orthographic projection of the third boundary of the seventh via on the base substrate and an orthographic projection of the third centerline on the base substrate, and a distance between the fourth boundary of the third via and the third centerline is greater than a distance between an orthographic projection of the fourth boundary of the seventh via on the base substrate and the orthographic projection of the third centerline on the base substrate.

10. The display substrate according to claim 9, wherein a distance between the orthographic projection of the first boundary of the third via on the base substrate and the orthographic projection of the first boundary of the seventh via on the base substrate is greater than a distance between an orthographic projection of the third boundary of the third via on the base substrate and the orthographic projection of the third boundary of the seventh via on the base substrate, and is less than a distance between the orthographic projection of the second boundary of the third via on the base substrate and the orthographic projection of the second boundary of the seventh via on the base substrate; and
the distance between the orthographic projection of the first boundary of the third via on the base substrate and the orthographic projection of the first boundary of the seventh via on the base substrate is about 1 micron to 2 microns.

11. The display substrate according to claim 4, wherein boundaries of a via comprise: a first boundary, a second boundary, a third boundary, and a fourth boundary, wherein the first boundary of the via is a boundary of the via close to a third signal line, the second boundary of the via is a boundary of the via away from the third signal line, the third boundary of the via is a boundary located on one side of a fourth centerline, and the fourth boundary of the via is a boundary located on the other side of the fourth centerline; the via comprises a fourth via and an eighth via; the third signal line is any one of a third scan signal line and an initial signal line which are connected with a sub-pixel connected with a first power supply line exposed by the fourth via; the fourth centerline is a centerline of the fourth via extending along the second direction, a third boundary of the fourth via and a third boundary of the eighth via are located on a same side of the fourth centerline, and a fourth boundary of the fourth via and a fourth boundary of the eighth via are located on a same side of the fourth centerline; and
a distance between an orthographic projection of a first boundary of the fourth via on the base substrate and an orthographic projection of the third signal line on the base substrate is greater than a distance between an orthographic projection of a first boundary of the eighth via on the base substrate and the orthographic projection of the third signal line on the base substrate, a distance between an orthographic projection of a second boundary of the fourth via on the base substrate and the orthographic projection of the third signal line on the base substrate is greater than a distance between an orthographic projection of a second boundary of the eighth via on the base substrate and the orthographic projection of the third signal line on the base substrate, a distance between the third boundary of the fourth via and the fourth centerline is greater than a distance between an orthographic projection of the third boundary of the eighth via on the base substrate and an orthographic projection of the fourth centerline on the base substrate, a distance between the fourth boundary of the fourth via and the fourth centerline is greater than a distance between an orthographic projection of the fourth boundary of the eighth via on the base substrate and the orthographic projection of the fourth centerline on the base substrate.

12. (canceled)

13. The display substrate according to claim 2, wherein the fifth insulation layer is provided with a fifth via to an eighth via,
wherein an orthographic projection of the fifth via on the base substrate is within a range of the orthographic projection of the first via on the base substrate, an orthographic projection of the sixth via on the base substrate is within a range of the orthographic projection of the second via on the base substrate, an orthographic projection of the seventh via on the base substrate is within a range of the orthographic projection of the third via on the base substrate, and an orthographic projection of the eighth via on the base substrate is within a range of the orthographic projection of the fourth via on the base substrate.

14. The display substrate according to claim 13, wherein the fifth insulation layer is further provided with any one of a first vent hole and a second vent hole;
orthographic projections of the first vent hole and the second vent hole on the base substrate are partially overlapped with an orthographic projection of the first planarization layer on the base substrate and the first planarization layer is exposed; and
there is no overlapping region between the orthographic projections of the first vent hole and the second vent hole on the base substrate and orthographic projections of an active pattern, a gate electrode, a first electrode, and a second electrode of any transistor, and a reference signal line, a first scan signal line, a second scan signal line, a third scan signal line, an initial signal line, a first power supply line, and a light emitting signal line on the base substrate.

15. The display substrate according to claim 14, wherein a length of the first vent hole along the first direction is greater than a length of a boundary of the second electrode of the third transistor close to the first scan signal line, and a length of the first vent hole along the second direction is greater than a length of the fifth via along the second direction;
an orthographic projection of the first vent hole on the base substrate is at least disposed surrounding at least one side of the orthographic projection of the first via on the base substrate; and
a distance between the orthographic projection of the first vent hole on the base substrate and the orthographic projection of the fifth via on the base substrate is smaller than a distance between an orthographic projection of the first scan signal line on the base substrate and the orthographic projection of the fifth via on the base substrate-;
or,
wherein a length of the second vent hole along the second direction is greater than a length of the sixth via along the second direction, and a length of the second vent hole along the first direction is less than a length of the sixth via along the first direction; and
the second vent hole and the sixth via are arranged along the second direction, and a distance between the orthographic projection of the sixth via on the base substrate and an orthographic projection of the first scan signal line on the base substrate is larger than a distance between the second vent hole and the sixth via.

16. (canceled)

17. The display substrate according to claim 13, wherein the fifth insulation layer is further provided with a third vent hole;
an orthographic projection of the third vent hole on the base substrate is partially overlapped with an orthographic projection of the first planarization layer on the base substrate and the first planarization layer is exposed; and
the orthographic projection of the third vent hole on the base substrate is located between an orthographic projection of the first scan signal line on the base substrate and an orthographic projection of the light emitting signal line on the base substrate, and there is no overlapping region between the orthographic projection of the third vent hole on the base substrate and orthographic projections of an active pattern, a gate electrode, a first electrode, and a second electrode of any transistor, and a reference signal line, a first scan signal line, a second scan signal line, a third scan signal line, an initial signal line, a first power supply line, and a light emitting signal line on the base substrate-;
or,
wherein the fifth insulation layer is further provided with at least one of a fourth vent hole and a fifth vent hole;
orthographic projections of the fourth vent hole and the fifth vent hole on the base substrate are partially overlapped with an orthographic projection of the first planarization layer on the base substrate and the first planarization layer is exposed;
an orthographic projection of the fourth vent hole on the base substrate is at least partially overlapped with the orthographic projection of the reference signal line on the base substrate, and there is no overlapping region between the orthographic projection of the fourth vent hole on the base substrate and orthographic projections of an active pattern, a gate electrode, a first electrode, and a second electrode of any transistor, and a first scan signal line, a second scan signal line, a third scan signal line, an initial signal line, a first power supply line, and a light emitting signal line on the base substrate; and
there is no overlapping region between an orthographic projection of one portion of the fifth vent hole on the base substrate and orthographic projections of an active pattern, a gate electrode, a first electrode, and a second electrode of any transistor, and a reference signal line, a first scan signal line, a second scan signal line, a third scan signal line, an initial signal line, a first power supply line, and a light emitting signal line on the base substrate, and an orthographic projection of the other portion of the fifth vent hole on the base substrate is at least partially overlapped with the orthographic projection of the first power supply line and there is no overlapping region between the orthographic projection of the other portion of the fifth vent hole on the base substrate and orthographic projections of an active pattern, a gate electrode, a first electrode, and a second electrode of any transistor, and a reference signal line, a first scan signal line, a second scan signal line, a third scan signal line, an initial signal line, and a light emitting signal line on the base substrate.

18-20. (canceled)

21. The display substrate according to claim 3- or 13, wherein the pixel drive circuit further comprises: a capacitor, and the capacitor comprises: a first electrode plate, a second electrode plate, and a third electrode plate, and the first electrode plate is electrically connected with the third electrode plate;
the semiconductor layer at least comprises: an active pattern of at least one transistor;
the first conductive layer at least comprises a gate electrode of at least one transistor and the first electrode plate of the capacitor;
the second conductive layer at least comprises the second electrode plate of the capacitor;
the third conductive layer at least comprises a first electrode and a second electrode of at least one transistor, a first scan signal line, a second scan signal line, a third scan signal line, a light emitting signal line, an initial signal line, a reference signal line, a first power supply line, and the third electrode plate of the capacitor; and
the fourth conductive layer at least comprises a data signal line.

22. The display substrate according to claim 21, wherein the first electrode plate of the capacitor comprises a first gate connection portion and a second gate connection portion; a second gate connection portion of a present column of sub-pixels is located on a side of a first gate connection portion close to a next column of sub-pixels, and a distance between a boundary of the first gate connection portion close to a gate electrode of the fifth transistor and the gate electrode of the fifth transistor is less than a distance between a boundary of the second gate connection portion close to the gate electrode of the fifth transistor and the gate electrode of the fifth transistor; a distance between a boundary of the first gate connection portion away from the gate electrode of the fifth transistor and the gate electrode of the fifth transistor is less than a distance between a boundary of the second gate connection portion away from the gate electrode of the fifth transistor and the gate electrode of the fifth transistor; and
a length of the first gate connection portion along the first direction is larger than a length of the second gate connection portion along the first direction, and a length of the first gate connection portion along the second direction is larger than a length of the second gate connection portion along the second direction.

23. The display substrate according to claim 22, wherein an orthographic projection of the second electrode plate of the capacitor on the base substrate is at least partially overlapped with an orthographic projection of the first electrode plate of the capacitor on the base substrate;
shapes and areas of second electrode plates of capacitors located in a same column of sub-pixels are the same, and an area of a second electrode plate of a capacitor of a (3k+1)-th column of sub-pixels is smaller than any one of an area of a second electrode plate of a capacitor of a (3k+2)-th column of sub-pixels and an area of a second electrode plate of a capacitor of a (3k+3)-th column of sub-pixels;
an area of an overlapping region between the second electrode plate of the capacitor and a first electrode plate of the capacitor of the (3k+1)-th column of sub-pixels is smaller than an area of an overlapping region between the second electrode plate of the capacitor and a first electrode plate of the capacitor of the (3k+2)-th column sub-pixels, and the area of the overlapping region between the second electrode plate of the capacitor and the first electrode plate of the capacitor of the (3k+2)-th column of sub-pixels is smaller than an area of an overlapping region between the second electrode plate of the capacitor and a first electrode plate of the capacitor of the (3k+3)-th column of sub-pixels;
an area of an overlapping region between the second electrode plate of the capacitor and a first gate connection portion of the (3k+1)-th column of sub-pixels is smaller than an area of an overlapping region between the second electrode plate of the capacitor and a first gate connection portion of the (3k+2)-th column of sub-pixels, and the area of the overlapping region between the second electrode plate of the capacitor and the first gate connection portion of the (3k+2)-th column of sub-pixels is smaller than an area of an overlapping region between the second electrode plate of the capacitor and a first gate connection portion of the (3k+3)-th column of sub-pixels; and
an area of an overlapping region between the second electrode plate of the capacitor and a second gate connection portion of the (3k+1)-th column of sub-pixels is smaller than an area of an overlapping region between the second electrode plate of the capacitor and a second gate connection portion of the (3k+2)-th column of sub-pixels, and an area of an overlapping region between the second electrode plate of the capacitor and a second gate connection portion of the (3k+3)-th column of sub-pixels is smaller than the area of the overlapping region between the second electrode plate of the capacitor and the second gate connection portion of the (3k+2)-th column of sub-pixels.

24-27. (canceled)

28. The display substrate according to claim 1, further comprising: a light emitting structure layer; the sub-pixel further comprises a light emitting device, the light emitting device comprises a first electrode, an organic emitting layer, and a second electrode, wherein the light emitting structure layer comprises a light emitting device, and the light emitting structure layer comprises a fifth conductive layer, a first pixel definition layer, a second pixel definition layer, a light emitting material layer, and a sixth conductive layer which are sequentially stacked on a side of the drive structure layer away from the base substrate;
the fifth conductive layer at least comprises the first electrode;
the light emitting material layer at least comprises the organic emitting layer;
the sixth conductive layer at least comprises the second electrode; and
a light transmittance of the first pixel definition layer is smaller than a light transmittance of the second pixel definition layer.

29. (canceled)

30. A display apparatus, comprising: a display substrate according to claim 1.
